(19) United States
(12) Patent Application Publication
(10) Pub. No.: US 2004/0009429 A1
(43) Pub. Date: Jan. 15, 2004

(54) Positive-working photosensitive composition

(75) Inventor: Kenichiro Sato, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/330,177

(22) Filed: Dec. 30, 2002

(30) Foreign Application Priority Data
Mar. 4, 2002 (JP) P.2002-57480
Jan. 10, 2002 (JP) P.2002-3703
Jan. 10, 2002 (JP) P.2002-3702

(51) Int. Cl. G03F 7/038

(52) U.S. Cl. 430/287.1; 430/270.1

(57) ABSTRACT

A positive-working photosensitive composition containing (A) at least one member selected from a compound having a phenacylsulfonium salt structure and a compound having a sulfonium salt structure not having an aromatic ring, each of which compounds generates an acid upon irradiation with actinic rays or radiations and (B) a resin having specific repeating units, which is decomposed by the action of an acid to increase its solubility in an alkaline developing solution; a positive-working photosensitive composition containing (A) a compound to generate an aromatic sulfonic acid substituted with at least one fluorine atom and/or a group having at least one fluorine atom, upon irradiation with actinic rays or radiations and (B) a resin having a repeating unit having a maleic anhydride structure in the main chain thereof, which is decomposed by the action of an acid to increase its solubility in an alkaline developing solution; and a positive-working photosensitive composition containing (A) a sulfonium salt to generate an acid upon irradiation with actinic rays or radiations, (B) a specific resin to increase its solubility in an alkaline developing solution, and (C) a mixed solvent containing at least one member selected from a solvent group A: propylene glycol monoalkyl ether alkoxylates and at least one member selected from a solvent group B: propylene glycol monoalkyl ethers, alkyl lactates, and alkyl alkoxypropionates, or a mixed solvent containing at least one member selected from the solvent group A and at least one member selected from a solvent group C: γ-butyrolactone, ethylene carbonate, and propylene carbonate.

### FIELD OF THE INVENTION

The present invention relates to a positive-working photosensitive composition that is used in the production step of semiconductors such as IC, the production of circuit boards of liquid crystals, thermal heads, etc., and other photo-fabrication steps.

### BACKGROUND OF THE INVENTION

A positive-working photoresist is applied in a thickness of from 0.5 to 2 μm on a substrate such as semiconductor wafers, glass, ceramics, and metals by spin coating or roller coating. Thereafter, the photoresist is heated, dried, and printed with a circuit pattern or the like through an exposure mask upon irradiation with ultraviolet rays or the like. After the exposure, the photoresist is baked, if desired and then developed to form a positive image. Further, by etching using this positive image as a mask, a pattern-like processing can be carried out on the substrate. Examples of representative application fields include the production step of semiconductors such as IC, the production of circuit boards of liquid crystals, thermal heads, etc., and other photo-fabrication steps.

Hitherto, in order to enhance a resolving power and obtain image reproduction with a good pattern shape, it is considered that the use of a resist having high contrast (γ value) is advantageous, and technologies for the development of resist compositions adapted to such purpose have been carried out. An extremely large number of publications disclose such technologies. Especially, with respect to resins as a major component of positive-working photoresists, many patents have been applied regarding the monomer compositions, molecular weight distributions, synthesis methods, etc., thereby realizing certain results. Further, with respect to photosensitive materials as another major component, compounds having a varied structure, which are seemed to be effective for revealing high contrast, are disclosed. When a positive-working photoresist is designed utilizing these technologies, it may be possible to develop resists having a super-high resolving power, which can resolve a pattern having a dimension equal to the wavelength of light.

However, in integrated circuits, the degree of integration increases more and more. In the production of semiconductor substrates of ULSI, etc., it has become necessary to undergo processing of hyperfine patterns having a line width of 0.5 μm or less.

On the other hand, there have been made various attempts to further increase the resolving power by a super resolution technology such as exposure technology and mask technology. In the super resolution technology, various resolution technologies are studied on light sources, masks, pupils, and images. As to the light sources, there is a technology for increasing the resolving power by using a light source having a shape different from the conventional circle, called modified illumination. As the masks, there is reported a technology for controlling even a phase shift using a phase shift mask, i.e., giving a phase shift to light transmitting through the mask and utilizing well its interference to obtain a high resolving power (for example, Tokuhisa Ito, Optics of Steppers (1) to (4): Optical Technology Contact, Vol. 27, No. 12, 762 (1988), Vol. 28, No. 1, 59 (1990), Vol. 28, No. 2, 108 (1990) and Vol. 28, No. 3, 165 (1990), JP-A-58-173744, JP-A-62-50811, JP-A-62-67514, JP-A-1-147458, JP-A-1-283925, and JP-A-2-211451 (The term “JP-A” as used herein means an “unexamined published Japanese Patent application”)).

Further, as disclosed in JP-A-8-15851, a resist exposure mode using a halftone mode phase shift mask is particularly watched as a practical technology for improving a space image and contrast of a projected image. However, in a light intensity distribution of the exposing light reaching the resist, not only a main peak but also a so-called sub-peak (side lobe light) are generated, and areas of the resist that should not be originally exposed are exposed. Especially, the higher the degree of coherence (σ), the larger the sub-peak is. When the sub-peak is thus generated, in the positive-working resists, irregularities caused by the sub-peak are formed in the exposed and developed resist, and hence, such is not preferred.

In the light of the above, in the projection optical system of optical lithography, various devices for attenuation are made, and combinations with various super resolution technologies are eagerly studied (for example, Halftone Type Phase Shift Mask and Annular Illumination: C. N. Ahn, et al., SPIE, Vol. 2440, 222 (1995), and T. Ogawa, et al., SPIE, Vol. 2726, 34 (1996)).

However, in the case where the super resolution technology is applied, in the conventional positive-working photoresists, there has already been reported the case where the resolving power is deteriorated, the exposure margin or exposure latitude is insufficient, or irregularities (film thickness reduction) are generated, whereby the resist performance is rather deteriorated. For example, C. L. Lin, et al. report that when the modified illumination is used, the pattern pitch dependency is deteriorated by the influence of the optical proximity effect (SPIE, Vol. 2726, 437 (1996)); and N. Samarakone, et al. and I. B. Hur, et al. point out a problem that when a contact hole pattern is formed using a halftone type phase shift mask, the surroundings of the hole pattern become irregular by the influence of a side lobe light (SPIE, Vol. 2440, 61 (1995) and SPIE, Vol. 2440, 278 (1995)). In order to reduce the influence of the side lobe light, there is made a device for surface-processing the exposed positive-working resist with an alkali (T. Yasuzato, et al., SPIE, Vol. 2440, 804 (1995)). However, there is still a problem that the process is complicated.

JP-A-11-109632 discloses that a resin containing a polar group-containing alicyclic functional group and an acid-decomposable group is used as a radiation-sensitive material.

Further, JP-A-9-73173, JP-A-9-90637, and JP-A-10-161313 disclose resist materials using an acid-sensitive compound containing an alkali-soluble group protected by an alicyclic group-containing structure and a structural unit in which the alkali-soluble group is released by an acid to make it alkali-soluble.

JP-A-10-130340 discloses a chemically amplified resist containing a terpolymer having a specific repeating structural unit having a norbornene structure in the main chain thereof.

Japanese Patent No. 3,042,618 discloses a photoresist composition containing a polymer obtained by copolymerizing a lactone structure-containing (meth)acrylate derivative with other polymerizable compound.

JP-A-2001-81139 proposes an improvement in resistance to dry etching by the use of a resin containing a repeating unit having a specific oxygen-containing alicyclic structure such as a lactone skeleton in the main chain thereof.

JP-A-11-305444 discloses a resin containing a repeating structural unit having an adamantane structure in the side chains thereof and maleic anhydride as a repeating structural unit.

JP-A-2001-13688 proposes a composition a repeating unit having a norbornene structure in the main chain thereof, a repeating unit having a maleic anhydride structure, and a repeating unit having a hydroxyl group in the side chains thereof for the purpose of providing radiation-sensitive resin compositions having superior transparency, resistance to dry etching, sensitivity, resolution, pattern shape, and preservability. JP-A-2001-209181 proposes a composition containing a resin containing a repeating unit having a norbornene structure in the main chain thereof and a repeating unit having a maleic anhydride structure.

JP-A-2001-200016 discloses a composition containing a copolymer of an alkyl vinyl ether monomer and maleic anhydride for the purpose of improving the adhesion to a lower film and resistance to dry etching.

JP-A-11-38628 discloses a composition containing a copolymer of a vinyl ether and a maleic ester for the purpose of improving the sensitivity, pattern profile, and adhesiveness to substrate.

However, even by using these conventional resist materials, it was difficult to realize the performance satisfactorily with respect to edge roughness and development defect.

Further, even by using these conventional resist materials, the resistance to side lobe light was not satisfactory during the formation a contact hole pattern using a halftone mode phase shift mask, and there was a problem in the pitch dependency (i.e., defocus latitude depended on line pitch). The pitch dependency as referred to herein means that the resolution properties are different between non-dense areas and dense areas.

### SUMMARY OF THE INVENTION

Accordingly, an object of the present invention is to solve the problems in performance-enhancing technologies of micro photo-fabrication using far ultraviolet rays, especially ArF excimer laser beams and to provide a positive-working photosensitive composition improved in edge roughness and development defect.

Another object of the present invention is to solve the problems in performance-enhancing technologies of micro photo-fabrication using far ultraviolet rays, especially ArF excimer laser beams and to provide a positive-working photosensitive composition having low pitch dependency and superior and broad side lobe margin.

A further object the present invention is to solve the problems in performance-enhancing technologies of micro photo-fabrication using far ultraviolet rays, especially ArF excimer laser beams and to provide a positive-working photosensitive composition having superior halftone phase shift mask aptitude (resistance to side lobe light) and improved in development defect and a positive-working photosensitive composition not only having the foregoing performance but also preventing pattern collapse and forming a good profile.

The foregoing objects of the present invention are achieved by positive-working photosensitive compositions having the following configurations.

(1) A positive-working photosensitive composition comprising:

(A) at least one compound of:

a compound to generate an acid upon irradiation with actinic rays or radiations, which is selected from a compound represented by the following general formula (A2I) and a compound represented by the following general formula (A2 II),

a compound to generate an aromatic sulfonic acid substituted with at least one fluorine atom and/or a group having at least one fluorine atom, upon irradiation with actinic rays or radiations, and

a compound to generate an acid upon irradiation with actinic rays or radiations, which is represented by the following general formula (SI); and

(B) a resin having a repeating unit represented by the following general formula (I) and a repeating unit represented by the following general formula (II), which is decomposed by the action of an acid to increase its solubility in an alkaline developing solution.

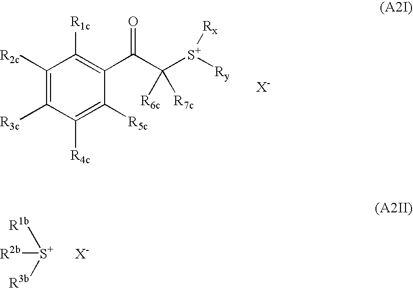

In the general formula (A2I), R_{1c} to R_{5c} each independently represents a hydrogen atom, an alkyl group, an alkoxy group, or a halogen atom; R_{6c} and R_{7c} each independently represents a hydrogen atom, an alkyl group, or an aryl group; Rₓ and R_{y} each independently represents an alkyl group, a 2-oxoalkyl group, an alkoxycarbonylmethyl group, an allyl group, or a vinyl group; and any two or more of R_{1c} to R_{7c}, and Rₓ and R_{y} may be taken together to form a ring structure, and the ring structure may contain an oxygen atom, a sulfur atom, an ester bond, or an amide group.

In the general formula (A2II), R^{1b} to R^{3b} each independently represents an alkyl group, and the alkyl group may be a 2-oxoalkyl group having >C═O at the 2-position thereof; and two of R^{1b} to R^{3b} may be taken together (i.e., may be bonded) to form a ring structure.

In the general formulae (A2I) and (A2II), X⁻ represents an anion.

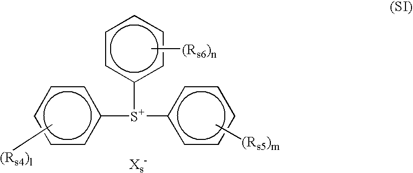

In the general formula (SI), Rₛ₄ to Rₛ₆ each independently represents an alkyl group, a cycloalkyl group, an alkoxy group, an alkoxycarbonyl group, an acyl group, an acyloxy group, a nitro group, a halogen atom, a hydroxyl group, or a carboxyl group; 1 represents from 1 to 5, m represents from 0 to 5, n represents from 0 to 5, and when (1+m+n)=1, then R₃₄ represents an alkyl group, a cycloalkyl group, an alkoxy group, an alkoxycarbonyl group, an acyl group, or an acyloxy group; Xₛ⁻ represents R—SO₃⁻; and R represents an aliphatic hydrocarbon group or an aromatic hydrocarbon group.

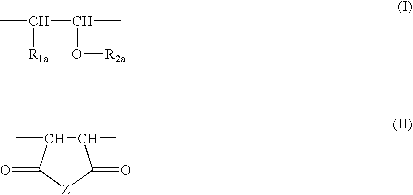

In the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring.

In the general formula (II), Z represents —O— or —N(R₃ₐ)—; R₃ₐ represents a hydrogen atom, a hydroxyl group, an alkyl group, a haloalkyl group, or —OSO₂—R₄ₐ; and R₄ₐ represents an alkyl group, a haloalkyl group, a cycloalkyl group, or a camphor residue.

(2) The positive-working photosensitive composition as set forth in (1) as above, further comprising (C) a mixed solvent containing at least one member selected from a solvent group A: propylene glycol monoalkyl ether alkoxylates and at least one member selected from a solvent group B: propylene glycol monoalkyl ethers, alkyl lactates, and alkyl alkoxypropionates, or a mixed solvent containing at least one member selected from the solvent group A and at least one member selected from a solvent group C: γ-butyrolactone, ethylene carbonate, and propylene carbonate.

(3) A positive-working photosensitive composition comprising (A) at least one compound to generate an acid upon irradiation with actinic rays or radiations, which is selected from a compound represented by the following general formula (A2I) and a compound represented by the following general formula (A2II); and (B) a resin having a repeating unit represented by the following general formula (I) and a repeating unit represented by the following general formula (II), which is decomposed by the action of an acid to increase its solubility in an alkaline developing solution.

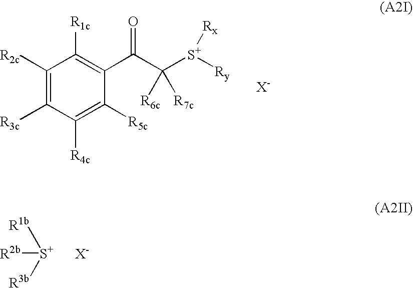

In the general formula (A2I), R_{1c} to R_{5c} each independently represents a hydrogen atom, an alkyl group, an alkoxy group, or a halogen atom; R_{6c} and R_{7c} each independently represents a hydrogen atom, an alkyl group, or an aryl group; Rₓ and R_{y} each independently represents an alkyl group, a 2-oxoalkyl group, an alkoxycarbonylmethyl group, an allyl group, or a vinyl group; and any two or more of R_{1c} to R_{7c} and Rₓ and R_{y} may be taken together to form a ring structure, and the ring structure may contain an oxygen atom, a sulfur atom, an ester bond, or an amide group.

In the general formula (A2II), R^{1b} to R^{3b} each independently represents an alkyl group, and the alkyl group may be a 2-oxoalkyl group having >C═O at the 2-position thereof; and two of R^{1b} to R^{3b} may be taken together to form a ring structure.

In the general formulae (A2I) and (A2II), X⁻ represents an anion.

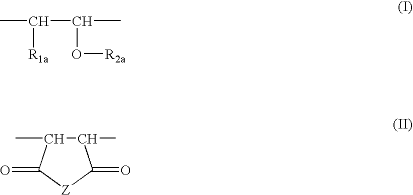

In the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring.

In the general formula (II), Z represents —O— or —N(R₃ₐ)—; R₃ₐ represents a hydrogen atom, a hydroxyl group, an alkyl group, a haloalkyl group, or —OSO₂—R₄ₐ; and R₄ₐ represents an alkyl group, a haloalkyl group, a cycloalkyl group, or a camphor residue.

In addition, the following configurations can be enumerated as preferred embodiments.

(4) The positive-working photosensitive composition as set forth in (1) as above, wherein the acid-decomposable resin contains a repeating unit having a group that is decomposed by the action of an acid, represented by any one of the following general formulae (pI) to (pV).

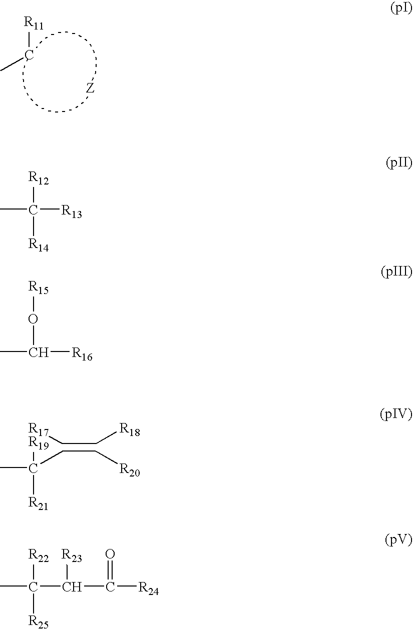

In the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a hydrogen atom or a linear or branched alkyl group or an alicyclic hydrocarbon group, each having from 1 to 4 carbon atoms, provided that at least one of R₁₇ to R₂₁ represents an alicyclic hydrocarbon atom and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

(5) The positive-working photosensitive composition as set forth in (3) or (4) as above, wherein the resin (B) further contains a repeating unit having a lactone residue or an alicyclic lactone reside.

(6) A positive-working photosensitive composition comprising (A) a compound to generate an aromatic sulfonic acid substituted with at least one fluorine atom and/or a group having at least one fluorine atom, upon irradiation with actinic rays or radiations; and (B) a resin (acid-decomposable resin) having a repeating unit represented by the following general formula (I) and a repeating unit represented by the following general formula (II), which is decomposed by the action of an acid to increase its solubility in an alkaline developing solution.

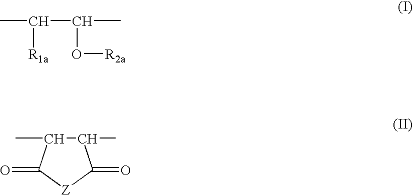

In the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring.

In the general formula (II), Z represents —O— or —N(R₃ₐ)—; R₃ₐ represents a hydrogen atom, a hydroxyl group, an alkyl group, a haloalkyl group, or OSO₂—R₄ₐ; and R₄ₐ represents an alkyl group, a haloalkyl group, a cycloalkyl group, or a camphor residue.

In addition, the following configurations can be enumerated as preferred embodiments.

(7) The positive-working photosensitive composition as set forth in (6) as above, wherein the acid-decomposable resin contains a repeating unit having a group that is decomposed by the action of an acid, represented by any one of the following general formulae (pI) to (pV).

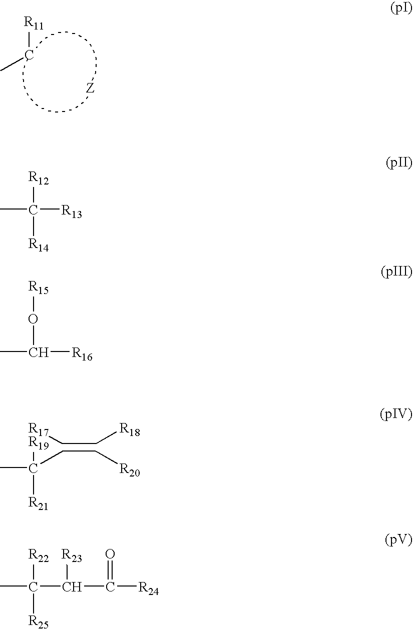

In the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a hydrogen atom or a linear or branched alkyl group or an alicyclic hydrocarbon group, each having from 1 to 4 carbon atoms, provided that at least one of R₁₇ to R₂₁ represents an alicyclic hydrocarbon group and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

(8) The positive-working photosensitive composition as set forth in (6) or (7) as above, wherein the resin (B) further contains a repeating unit having a lactone residue or an alicyclic lactone reside.

(9) The positive-working photosensitive composition as set forth in any one of (6) to (8) as above, wherein the compound (A) is a compound represented by any one of the following general formulae (A1I) to (A1III).

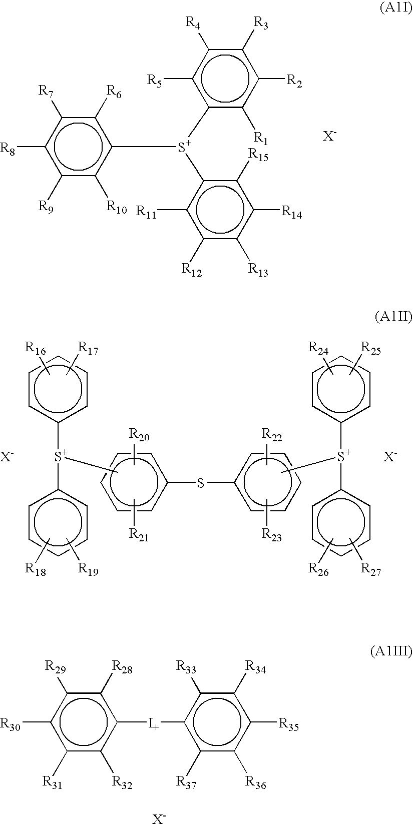

In the foregoing formulae, R₁ to R₃₇, which may be the same or different, each independently represents a hydrogen atom, a linear, branched or cyclic alkyl group, a linear, branched or cyclic alkoxy group, a hydroxyl group, a halogen atom, or an —S—R₃₈ group; R₃₈ represents a linear, branched or cyclic alkyl group or an aryl group; two or more of R₁ to R₁₅, R₁₆ to R₂₇, or R₂₈ to R₃₇ may be taken together to form a ring containing one or two or more members selected from a simple bond, carbon, oxygen, sulfur, and nitrogen; and X⁻ represents an anion of an aromatic sulfonic acid such as benzenesulfonic acid, naphthalenesulfonic acid, and anthracenesulfonic acid, having at least one member selected from at least one fluorine atom, a linear, branched or cyclic alkyl group substituted with at least one fluorine atom, a linear, branched or cyclic alkoxy group substituted with at least one fluorine atom, an acyl group substituted with at least one fluorine atom, an acyloxy group substituted with at least one fluorine atom, an alkyl- or arylsulfonyl group containing at least one fluorine atom, an alkyl- or arylsulfonyloxy group containing at least one fluorine atom, an alkyl- or arylsulfonylamino group containing at least one fluorine atom, an aryl group substituted with at least one fluorine atom, an aralkyl group substituted with at least one fluorine atom, and an alkoxycarbonyl group substituted with at least one fluorine atom.

(10) A positive-working photosensitive composition comprising (A) a compound to generate an acid upon irradiation with actinic rays or radiations, which is represented by the following general formula (SI); (B) a resin having a repeating unit represented by the following general formula (I) and a repeating unit represented by the following general formula (II), which is decomposed by the action of an acid to increase its solubility in an alkaline developing solution; and (C) a mixed solvent containing at least one member selected from a solvent group A: propylene glycol monoalkyl ether alkoxylates and at least one member selected from a solvent group B: propylene glycol monoalkyl ethers, alkyl lactates, and alkyl alkoxypropionates, or a mixed solvent containing at least one member selected from the solvent group A and at least one member selected from a solvent group C: γ-butyrolactone, ethylene carbonate, and propylene carbonate.

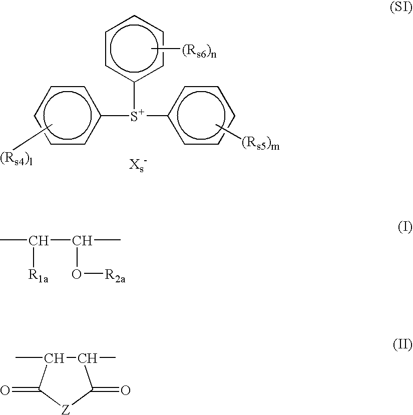

In the general formula (SI), Rₛ₄ to Rₛ₆ each independently represents an alkyl group, a cycloalkyl group, an alkoxy group, an alkoxycarbonyl group, an acyl group, an acyloxy group, a nitro group, a halogen atom, a hydroxyl group, or a carboxyl group; 1 represents from 1 to 5, m represents from 0 to 5, n represents from 0 to 5, and when (1+m+n)=1, then Rₛ₄ represents an alkyl group, a cycloalkyl group, an alkoxy group, an alkoxycarbonyl group, an acyl group, or an acyloxy group; Xₛ⁻ represents R—SO₃⁻; and R represents an aliphatic hydrocarbon group or an aromatic hydrocarbon group.

In the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring.

In the general formula (II), Z represents —O— or —N(R₃ₐ)—; R₃ₐ represents a hydrogen atom, a hydroxyl group, an alkyl group, a haloalkyl group, or —OSO₂—R₄ₐ; and R₄ₐ represents an alkyl group, a haloalkyl group, a cycloalkyl group, or a camphor residue.

(11) The positive-working photosensitive composition as set forth in (10) as above, further comprising (F) a fluorine-based surfactant and/or a silicon-based surfactant.

According to this embodiment set forth in (11) as above, the formation of a good profile is more ensured without causing pattern collapse.

In addition, the following configurations can be enumerated as preferred embodiments.

(12) The positive-working photosensitive composition as set forth in (10) or (11) as above, wherein the acid-decomposable resin contains a repeating unit having a group that is decomposed by the action of an acid, represented by any one of the following general formulae (pI) to (pV).

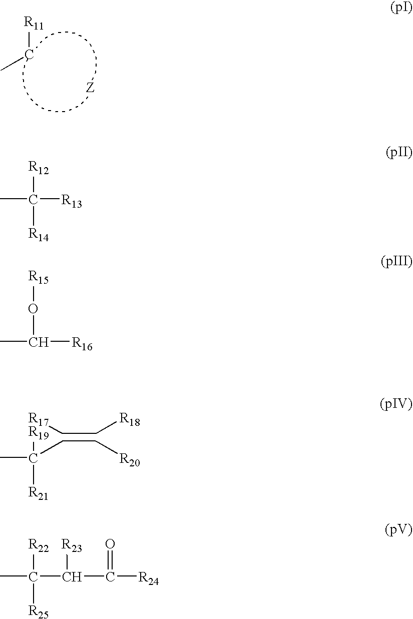

In the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a hydrogen atom or a linear or branched alkyl group or an alicyclic hydrocarbon group, each having from 1 to 4 carbon atoms, provided that at least one of R₁₇ to R₂₁ represents an alicyclic hydrocarbon atom and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

(13) The positive-working photosensitive composition as set forth in any one of (10) to (12) as above, wherein the resin (B) further contains a repeating unit having a lactone residue or an alicyclic lactone reside.

(14) The positive-working photosensitive composition as set forth in any one of (10) to (13) as above, wherein the mixed solvent (C) is a mixed solvent containing at least one member selected from the solvent group A, at least one member selected from the solvent group B, and at least one member selected from the solvent group C.

### DETAILED DESCRIPTION OF THE INVENTION

[1] (A) Compound to Generate an Acid Upon Irradiation with Actinic Rays or Radiations:

In the present invention, as the compound (A) to generate an acid upon irradiation with actinic rays or radiations (photo acid generator) is used at least one member selected from a compound having a phenacylsulfonium salt structure and a compound having a sulfonium salt structure not having an aromatic ring, each of which compounds generates an acid upon irradiation with actinic rays or radiations.

As the compound having a phenacylsulfonium salt structure, which generates an acid upon irradiation with actinic rays or radiations, can be enumerated a compound represented by the following general formula (A2I).

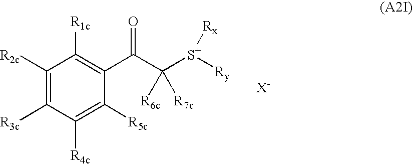

In the general formula (A2I), R_{1c} to R_{5c} each independently represents a hydrogen atom, an alkyl group, an alkoxy group, or a halogen atom; R_{6c} and R_{7c} each independently represents a hydrogen atom, an alkyl group, or an aryl group; Rₓ and R_{y} each independently represents an alkyl group, a 2-oxoalkyl group, an alkoxycarbonylmethyl group, an allyl group, or a vinyl group; any two or more of R_{1c} to R_{7c}, and Rₓ and R_{y} may be taken together to form a ring structure, and the ring structure may contain an oxygen atom, a sulfur atom, an ester bond, or an amide group; and X⁻ represents an anion (such as a sulfonic anion, carboxylic anion, and a sulfonylimide anion).

The alkyl group represented by R_{1c} to R_{5c} may be linear, branched or cyclic. Examples include an alkyl group having from 1 to 10 carbon atoms, and preferably a linear or branched alkyl group having from 1 to 5 carbon atoms (such as a methyl group, an ethyl group, a linear or branched propyl group, a linear or branched butyl group, and a linear or branched pentyl group,) or a cyclic alkyl group having from 3 to 8 carbon atoms (such as a cyclopentyl group and a cyclohexyl group).

The alkoxy group represented by R_{1c} to R_{5c} may be linear, branched or cyclic. Examples include an alkoxy group having from 1 to 10 carbon atoms, and preferably a linear or branched alkyl group having from 1 to 5 carbon atoms (such as a methox group, an ethoxy group, a linear or branched propoxy group, a linear or branched butoxy group, and a linear or branched pentoxy group,) or a cyclic alkoxy group having from 3 to 8 carbon atoms (such as a cyclopentyloxy group and a cyclohexyloxy group).

Preferably, any one of R_{1c} to R_{5c} represents a linear, branched or cyclic alkyl group or a linear, branched or cyclic alkoxy group, and more preferably, the total sum of carbon atoms of R_{1c} to R_{5c} is from 2 to 15. Thus, the solvent solubility is enhanced, whereby the generation of particles is inhibited during the preservation.

With respect to the alkyl group represented by R_{6c} and R_{7c}, the same alkyl groups as in R_{1c} to R_{5c} can be enumerated. Examples of the aryl group include an aryl group having from 6 to 14 carbon atoms (such as a phenyl group).

As the alkyl group represented by Rₓ and R_{y}, the same alkyl groups as in R_{1c} to R_{5c} can be enumerated.

As the 2-oxyalkyl group can be enumerated the alkyl groups as in R_{1c} to R_{5c}, in which, however, >C═O is present at the 2-position thereof.

With respect to the alkoxy group in the alkoxy-carbonylmethyl group, the same alkoxy groups as in R_{1c} to R_{5c} can be enumerated.

As the group formed when Rₓ and R_{y} are taken together can be enumerated a butylene group and a pentylene group.

In the compound represented by the general formula (A2I), the stereostructure is fixed by the formation of a ring, whereby the photo-decomposability is enhanced. With respect to the case where any two of R_{1c} to R_{7c} are taken together to form a ring structure, the case where any one of R_{1c} to R_{5c} and any one of R_{6c} and R_{7c} are taken together to become a simple bond or a connecting group, thereby forming a ring is preferred. Especially, the case where R_{5c} and R_{6c} or R_{7c} are taken together to become a simple bond or a connecting group, thereby forming a ring is preferred.

Examples of the connecting group include an optionally substituted alkylene group, an optionally substituted alkenylene group, —O—, —S—, —CO—, —CONR— (wherein R represents a hydrogen atom, an alkyl group, or an acyl group), and a group comprising a combination of two or more of these groups, with an optionally substituted alkylene group, an oxygen atom-containing alkylene group and a sulfur atom-containing alkylene group being preferred. Examples of the substituent include an alkyl group (preferably having from 1 to 5 carbon atoms), an aryl group (preferably from 6 to 10 carbon atoms, such as a phenyl group), and an acyl group (such as ones having from 2 to 11 carbon atoms).

Further, a connecting group for forming a from 5-membered to 7-membered ring, such as a methyl group, an ethylene group, a propylene group, —CH₂—O—, and —CH₂—S—, is preferred, with a connecting group for forming a 6-membered ring, such as an ethylene group, —CH₂—O—, and —CH₂—S—, being particularly preferred. By forming the 6-membered ring, a carbonyl plane becomes more perpendicular to the C—S +σ-bond, whereby the photo-decomposability is enhanced by the orbital interaction.

The compound may be a compound having two or more structures represented by the formula (A2I), bound to each other at any one of the positions of R_{1c} to R_{7c} and Rₓ and R_{y} via a simple bond or a connecting group.

X⁻ preferably represents a sulfonic anion, and more preferably an alkanesulfonic anion substituted with a fluorine atom at the 1-position thereof, or a benzenesulfonic acid substituted with an electron attractive group. The alkane moiety of the alkanesulfonic anion may be substituted with a substituent such as an alkoxy group (such as ones having from 1 to 8 carbon atoms) and a perfluoroalkoxy group (such as ones having 1 to 8 carbon atoms). Examples of the electron attractive group include a chlorine atom, a bromine atom, a nitro group, a cyano group, an alkoxycarbonyl group, an acyloxy group, and an acyl group.

More preferably, X⁻ represents a perfluoroalkanesulfonic anion having from 1 to 8 carbon atoms, particularly preferably a perfluorooctanesulfonic anion, and most preferably a perfluorobutanesulfonic anion or a trifluoromethanesulfonic anion. By using this compound, the decomposition rate of the acid-decomposable group is enhanced, the sensitivity is superior, and the diffusibility of the generated acid is controlled, whereby the resolving power is enhanced.

Illustrative Examples of the compound having a phenacylsulfonium salt structure, which can be used in the present invention, will be described below, but it should not be construed that the present invention is limited thereto.

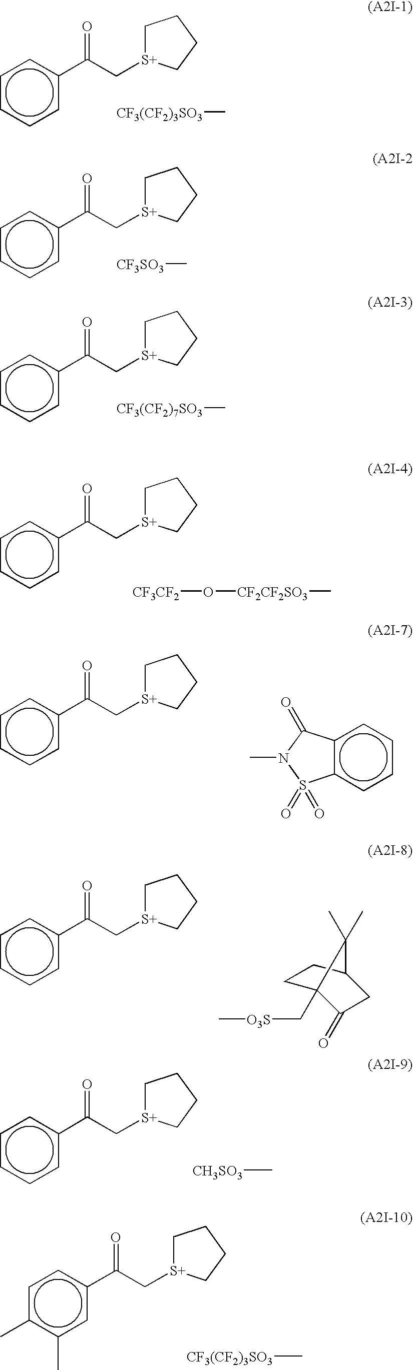

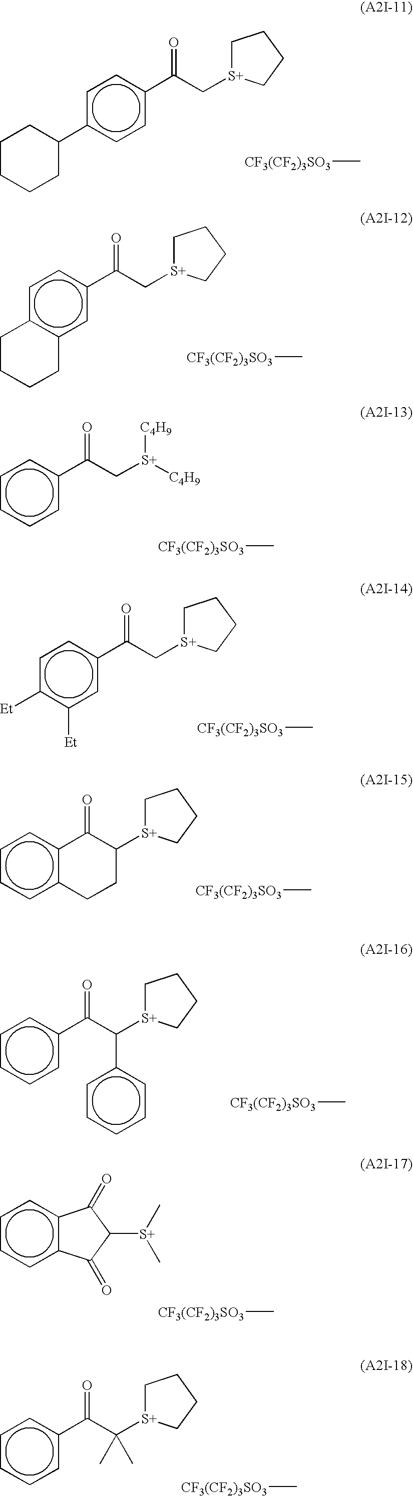

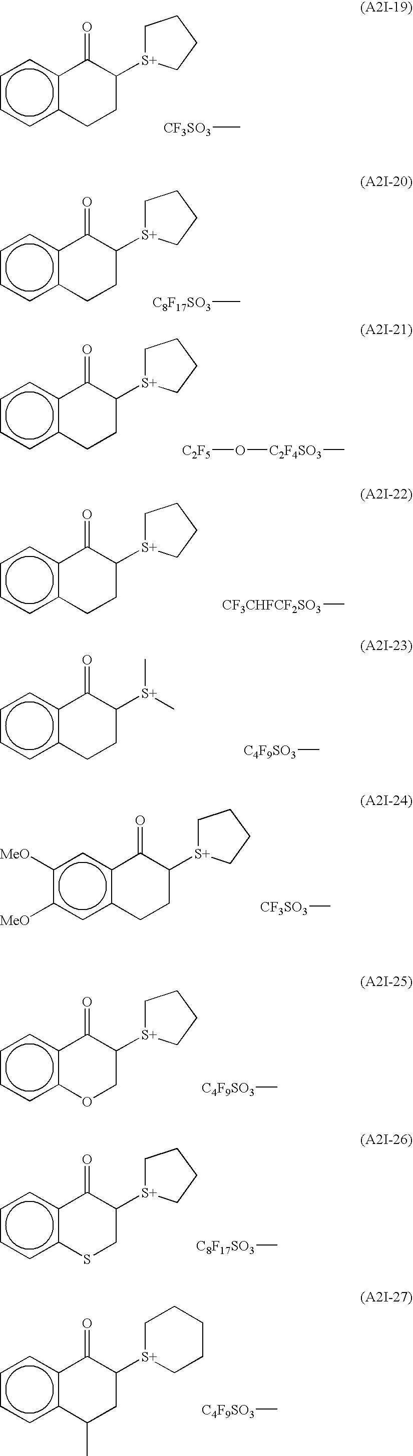

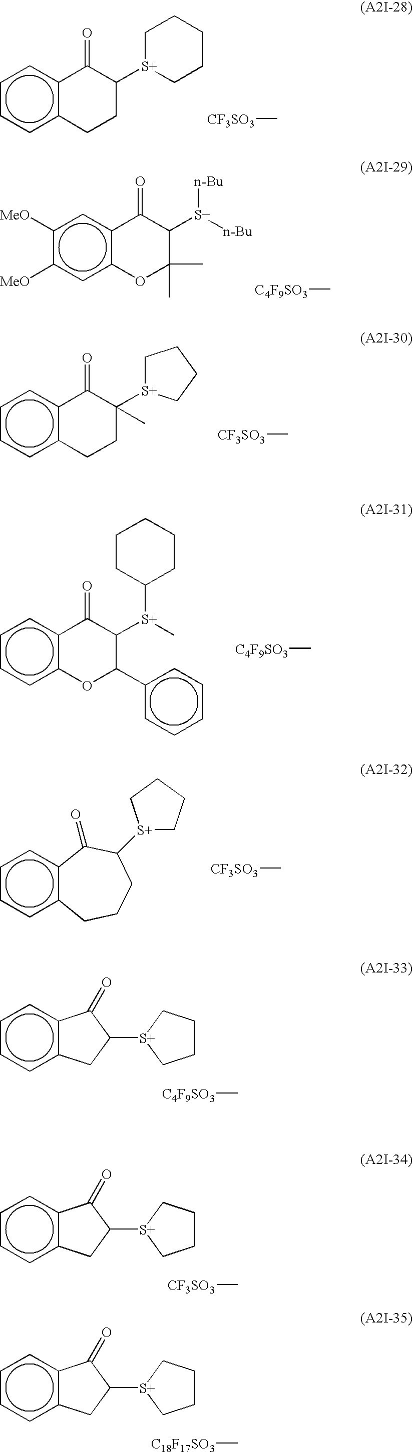

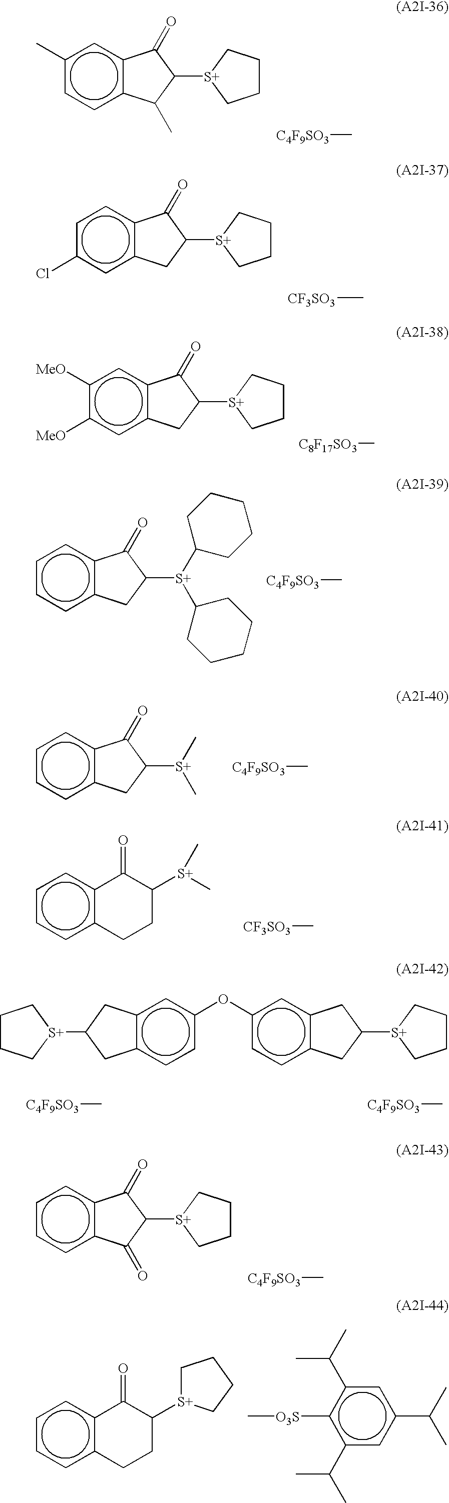

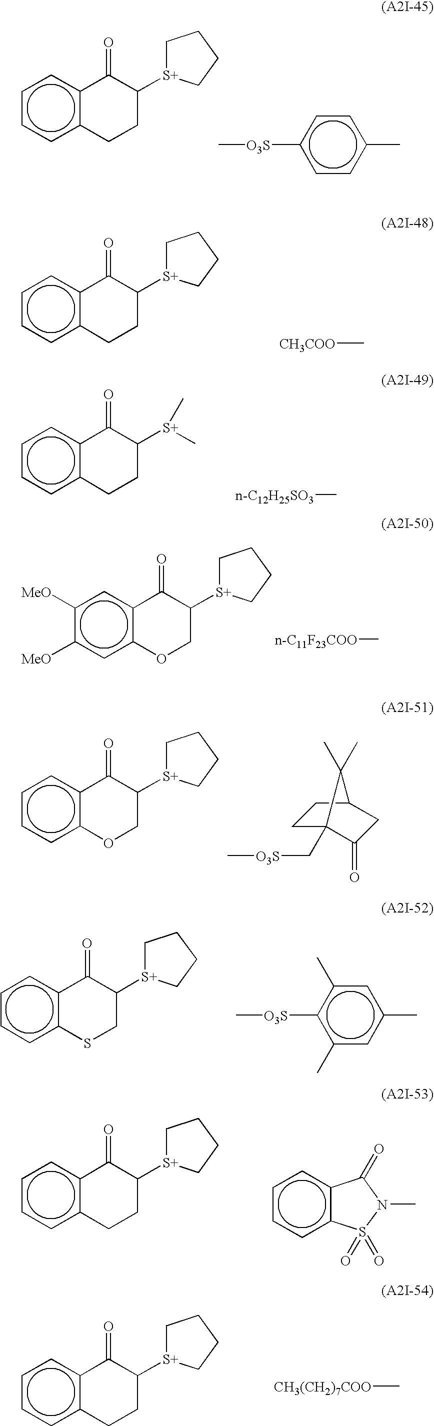

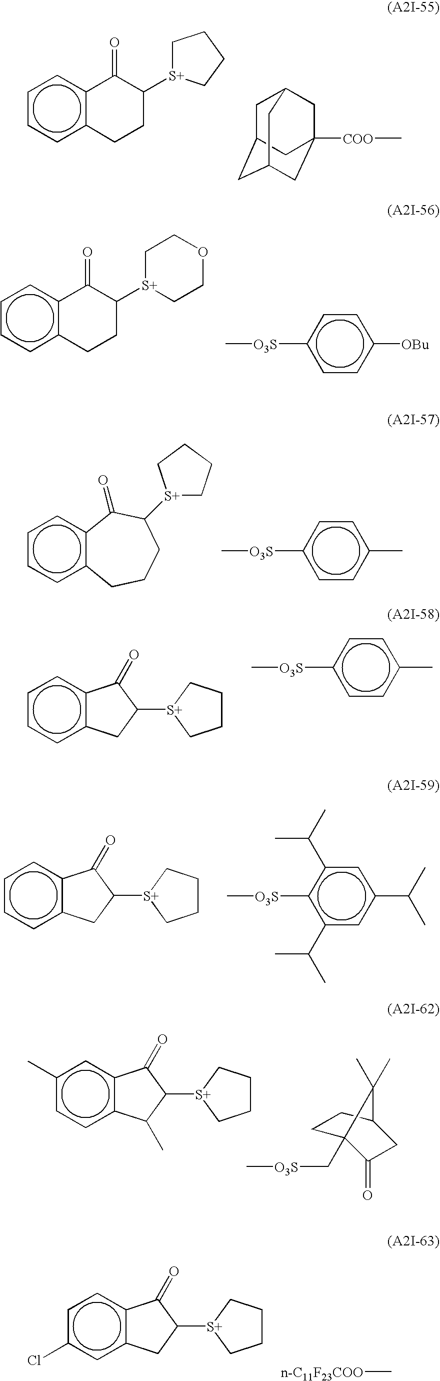

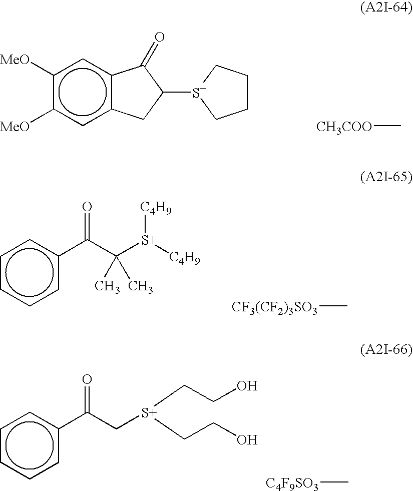

As the compound having a sulfonium salt structure not having an aromatic ring, which generates an acid upon irradiation with actinic rays or radiations, can be enumerated an alkylsulfonium salt compound represented by the following general formula (A2II).

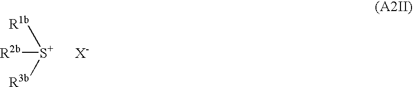

In the general formula (A2II), R^{1b} to R^{3b} each independently represents an alkyl group, and the alkyl group may be a 2-oxoalkyl group having >C═O at the 2-position thereof; two of R^{1b} to R^{3b} may be taken together to form a ring structure; and X⁻ represents an anion. The alkyl group represented by R^{1b} to R^{3b} may be linear, branched or cyclic. Preferred examples include a linear or branched alkyl group having from 1 to 10 carbon atoms (such as a methyl group, an ethyl group, a propyl group, a butyl group, and a pentyl group) and a cyclic alkyl group having from 3 to 10 carbon atoms (such as a cyclopentyl group, a cyclohexyl group, and a norbornyl group).

The 2-oxoalkyl group represented by R^{1b} to R^{3b} may be linear, branched or cyclic. Preferred examples the foregoing alkyl groups in which, however, >C═O is present at the 2-position thereof.

R^{1b} to R^{3b} may be further substituted with a halogen atom, an alkoxy group (such as ones having from 1 to 5 carbon atoms) a hydroxyl group, or a nitro group.

Two of R^{1b} to R^{3b} may be taken together to form a ring structure. The ring may contain an oxygen atom, a sulfur atom, an ester bond, an amide bond, or a carbonyl group therein. As the group formed when two R^{1b} to R^{3b} are taken together can be enumerated an alkylene group (such as a butylene group and a pentylene group).

From the viewpoint of photo reactivity, a group having a carbon-carbon double bond or a carbon-oxygen double bond may be present in the alkyl chain of any one of R^{1b} to R^{3b}.

For example, X⁻ represents a sulfonic anion, and preferably an alkanesulfonic anion substituted with a fluorine atom at the 1-position thereof, or a benzenesulfonic acid substituted with an electron attractive group. More preferably, X⁻ represents a perfluoroalkanesulfonic anion having from 1 to 8 carbon atoms, and most preferably a perfluorobutanesulfonic anion or a a perfluorooctaine sulfonic anion. By using this compound, the decomposition rate of the acid-decomposable group is enhanced, the sensitivity is superior, and the diffusibility of the generated acid is controlled, whereby the resolving power is enhanced.

Examples of the electron attractive group include a chlorine atom, a bromine atom, a nitro group, a cyano group, an alkoxycarbonyl group, an acyloxy group, and an acyl group.

At least one of R^{1b} to R^{3b} of the compound represented by the general formula (A2II) may take a structure bonding to at least one of R^{1b} to R^{3b} of other compound represented by the general formula (A2II).

Illustrative Examples of the compound having a alkylsulfonium salt structure, which can be used in the present invention, will be described below, but it should not be construed that the present invention is limited thereto.

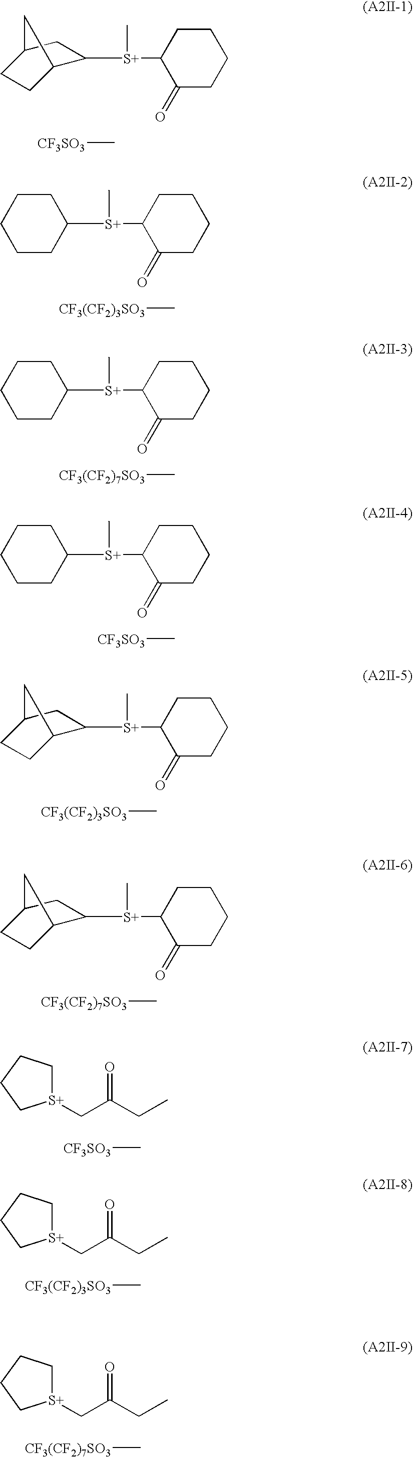

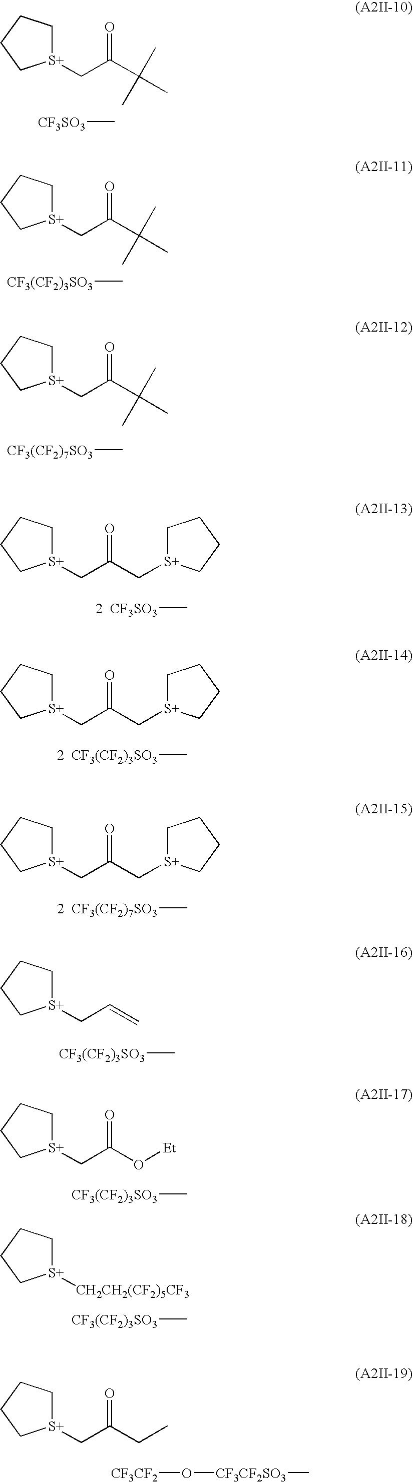

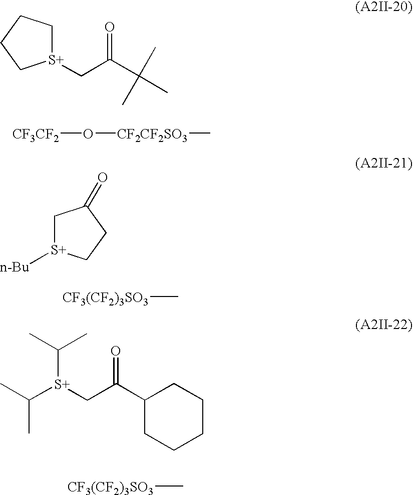

As the compound to generate an aromatic sulfonic acid substituted with at least one fluorine atom and/or a group having at least one fluorine atom, upon irradiation with actinic rays or radiations can be enumerated a compound to generate an aromatic sulfonic acid substituted with at least one fluorine atom, a compound to generate an aromatic sulfonic acid substituted with a group having at least one fluorine atom, and a compound to generate an aromatic sulfonic acid substituted with both of at least one fluorine atom and a group having at least one fluorine atom. Examples of the aromatic sulfonic acid include benzenesulfonic acid, naphthalene-sulfonic acid, and anthracenesulfonic acid.

As the component (A) are particularly preferable compounds represented by the following general formulae (A1I) to (A1III).

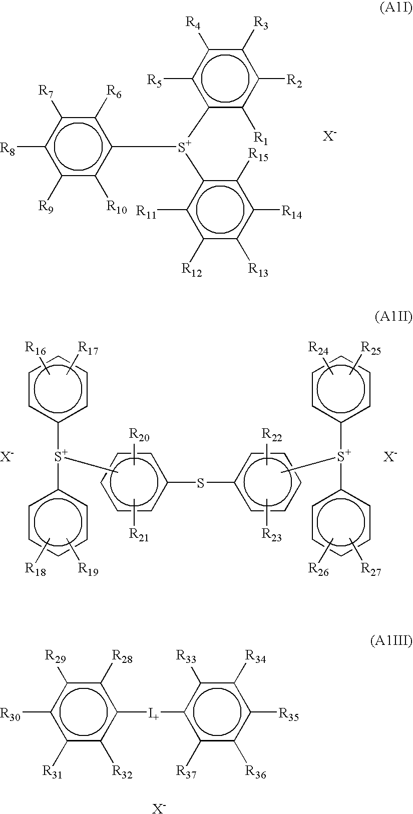

In the foregoing formulae, R₁ to R₃₇, which may be the same or different, each independently represents a hydrogen atom, a linear, branched or cyclic alkyl group, a linear, branched or cyclic alkoxy group, a hydroxyl group, a halogen atom, or an —S—R₃₈ group; R₃₈ represents a linear, branched or cyclic alkyl group or an aryl group; two or more of R₁ to R₁₅, R₁₆ to R₂₇, or R₂₈ to R₃₇ may be taken together to form a ring containing one or two or more members selected from a simple bond, carbon, oxygen, sulfur, and nitrogen; and X⁻ represents an anion of an aromatic sulfonic acid such as benzenesulfonic acid, naphthalenesulfonic acid, and anthracenesulfonic acid, having at least one member selected from at least one fluorine atom, a linear, branched or cyclic alkyl group substituted with at least one fluorine atom, a linear, branched or cyclic alkoxy group substituted with at least one fluorine atom, an acyl group substituted with at least one fluorine atom, an acyloxy group substituted with at least one fluorine atom, an alkyl- or arylsulfonyl group containing at least one fluorine atom, an alkyl- or arylsulfonyloxy group containing at least one fluorine atom, an alkyl- or arylsulfonylamino group containing at least one fluorine atom, an aryl group substituted with at least one fluorine atom, an aralkyl group substituted with at least one fluorine atom, and an alkoxycarbonyl group substituted with at least one fluorine atom.

In the general formulae (A1I) to (A1III), examples of the linear or branched alkyl group represented by R₁ to R₃₈ include ones having from 1 to 4 carbon atoms, which may be substituted, such as a methyl group, an ethyl group, a propyl group, n-butyl group, a sec-butyl group, and a t-butyl group. Examples of the cyclic alkyl group represented by R₁ to R₃₈ include ones having from 3 to 8 carbon atoms, which may be substituted, such as a cyclopropyl group, a cyclopentyl group, and a cyclohexyl group.

Examples of the linear or branched alkoxy group represented by R₁ to R₃₇ include ones having from 1 to 4 carbon atoms, such as a methoxy group, an ethoxy group, a hydroxyethoxy group, a propoxy group, an n-butoxy group, an isobutoxy group, a sec-butoxy group, and a t-butoxy group.

Examples of the cyclic alkoxy group represented by R₁ to R₃₇ include a cyclopropyloxy group, a cyclopentyloxy group, and a cyclohexyloxy group.

Examples of the halogen atom represented by R₁ to R₃₇ include a fluorine atom, a chlorine atom, a bromine atom, and an iodine atom.

Examples of the aryl group represented by R₃₈ include ones having from 6 to 14 carbon atoms, which may be substituted, such as a phenyl group, a tolyl group, a methoxyphenyl group, and a naphthyl group.

Examples of the substituent include an alkoxy group having from 1 to 4 carbon atoms, a halogen atom (such as a fluorine atom, a chlorine atom, and an iodine atom), an aryl group having from 6 to 10 carbon atoms, an alkenyl group having from 2 to 6 carbon atoms, a cyano group, a hydroxyl group, a carboxy group, an alkoxycarbonyl group, and a nitro group.

Examples of the ring containing one or two or more members selected from a simple bond, carbon, oxygen, sulfur, and nitrogen, which is formed when two or more of R₁ to R₁₅, R₁₆ to R₂₇, or R₂₈ to R₃₇ are taken together, include a furan ring, a dihydrofuran ring, a pyran ring, a trihydropyran ring, a thiophene ring, and a pyrrole ring.

In the general formulae (A1I) to (A1III), X⁻ represents an anion of an aromatic sulfonic acid such as benzenesulfonic acid, naphthalenesulfonic acid, and anthracenesulfonic acid, having at least one member selected from at least one fluorine atom, a linear, branched or cyclic alkyl group substituted with at least one fluorine atom, a linear, branched or cyclic alkoxy group substituted with at least one fluorine atom, an acyl group substituted with at least one fluorine atom, an acyloxy group substituted with at least one fluorine atom, an alkyl- or arylsulfonyl group containing at least one fluorine atom, an alkyl- or arylsulfonyloxy group containing at least one fluorine atom, an alkyl- or arylsulfonylamino group containing at least one fluorine atom, an aryl group substituted with at least one fluorine atom, an aralkyl group substituted with at least one fluorine atom, and an alkoxycarbonyl group substituted with at least one fluorine atom.

As the linear, branched or cyclic alkyl group represented by X⁻ are preferable ones having from 1 to 12 carbon atoms, which are substituted with from 1 to 25 fluorine atoms. Specific examples include a fluoromethyl group, a difluoromethyl group, a trifluoromethyl group, a pentafluoroethyl group, a 2,2,2-trifluoroethyl group, a heptafluoropropyl group, a heptafluoroisopropyl group, a perfluorobutyl group, a perfluorooctyl group, a perfluorododecyl group, and a perfluorocyclohexyl group. Of these is preferable a perfluoroalkyl group having from 1 to 4 carbon atoms, all hydrogen atoms of which are substituted with a fluorine atom.

As the linear, branched or cyclic alkoxy group represented by X⁻ are preferable ones having from 1 to 12 carbon atoms, which are substituted with from 1 to 25 fluorine atoms. Specific examples include a trifluoromethoxy group, a pentafluoroethoxy group, a pentafluoroisopropyloxy group, a perfluorobutoxy group, a perfluorooctyloxy group, a perfluorododecyloxy group, and a perfluorocyclohexyloxy group. Of these is preferable a perfluoroalkoxy group having from 1 to 4 carbon atoms, all hydrogen atoms of which are substituted with a fluorine atom.

As the acyl group represented by X⁻ are preferable ones having from 2 to 12 carbon atoms, which are substituted with from 1 to 23 fluorine atoms. Specific examples include a trifluoroacetyl group, a fluoroacetyl group, a pentafluoropropionyl group, and a pentafluorobenzoyl group.

As the acyloxy group represented by X are preferable ones having from 2 to 12 carbon atoms, which are substituted with from 1 to 23 fluorine atoms. Specific examples include a trifluoroacetoxy group, a fluoroacetoxy group, a pentafluoropropionyloxy group, and a pentafluorobenzoyloxy group.

As the alkyl- or arylsulfonyl group represented by X⁻ are preferable ones having from 1 to 12 carbon atoms, which contain from 1 to 25 fluorine atoms. Specific examples include a trifluoromethanesulfonyl group, a pentafluoroethanesulfonyl group, a perfluorobutanesulfonyl group, a perfluorooctanesulfonyl group, a pentafluorobenzenesulfonyl group, and a 4-trifluoromethylbenzenesulfonyl group.

As the alkyl- or arylsulfonyloxy group represented by X⁻ are preferable ones having from 1 to 12 carbon atoms, which contain from 1 to 25 fluorine atoms. Specific examples include a trifluoromethanesulfonyloxy group, a perfluorobutanesulfonyloxy group, and a 4-trifluoromethylbenzenesulfonyloxy group.

As the alkyl- or arylsulfonylamino group represented by X⁻ are preferable ones having from 1 to 12 carbon atoms, which contain from 1 to 25 fluorine atoms. Specific examples include a trifluoromethanesulfonylamino group, perfluorobutanesulfonylamino group, a perfluorooctanesulfonylamino group, and a pentafluorobenzenesulfonylamino group.

As the aryl group represented by X⁻ are preferable ones having from 6 to 14 carbon atoms, which are substituted with from 1 to 9 fluorine atoms. Specific examples include a pentafluorophenyl group, a 4-trifluoromethylphenyl group, a pentafluoronaphthyl group, a nonafluoroanthranyl group, a 4-fluorophenyl group, and a 2,4-difluorophenyl group.

As the aralkyl group represented by X⁻ are preferable ones having from 7 to 10 carbon atoms, which are substituted with from 1 to 15 fluorine atoms. Specific examples include a pentafluorophenylmethyl group, a pentafluorophenylethyl group, a perfluorobenzyl group, and a perfluorophenethyl group.

As the alkoxycarbonyl group represented by X⁻ are preferable ones having from 2 to 13 carbon atoms, which are substituted with from 1 to 25 fluorine atoms. Specific examples include a trifluoromethoxycarbonyl group, a pentafluoroethoxycarbonyl group, a pentafluorophenoxycarbonyl group, a perfluorobutoxycarbonyl group, and a perfluorooctyloxycarbonyl group.

Most preferred examples of X⁻ include a benzenesulfonic anion substituted with a fluorine atom and a benzenesulfonic anion substituted with a trifluoromethyl group. Of these are particularly preferable a pentafluorobenzenesulfonic anion, a 2-, 3- or 4-trifluoromethylbenzenesulfonic anion, and a 3,5-bistrifluoromethylbenzenesulfonic anion.

The aromatic sulfonic acid having a fluorine-containing substituent may be further substituted with, for example, a linear, branched or cyclic alkoxy group, an acyl group, an acyloxy group, a sulfonyl group, a sulfonyloxy group, a sulfonylamino group, an aryl group, an aralkyl group, an alkoxycarbonyl group (the range of carbon atoms of these groups is the same as defined above), a halogen atom (excluding a fluorine atom), a hydroxyl group, or a nitro group.

Preferred Illustrative Examples of the component (A) represented by the general formula (A1I) will be described below.

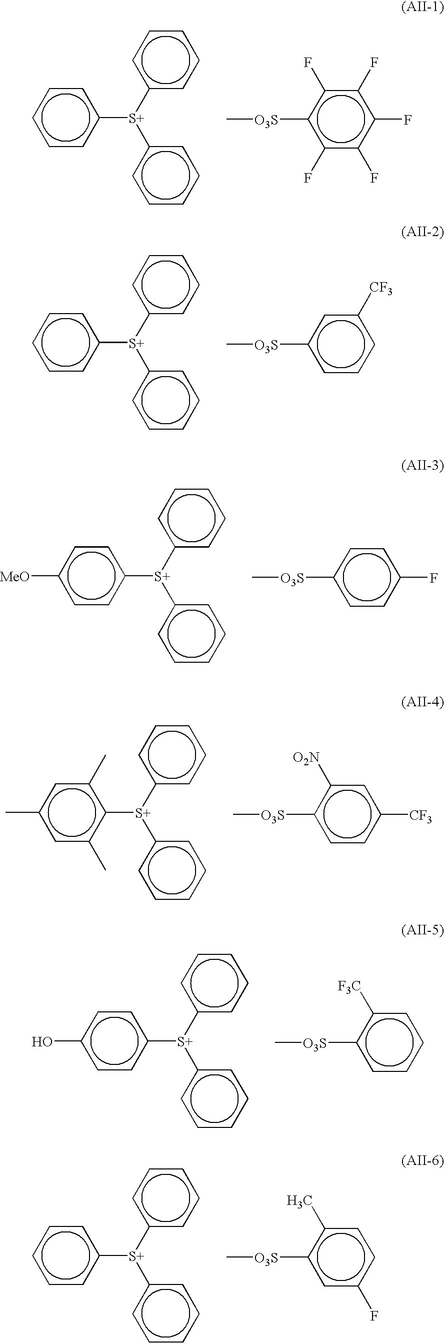

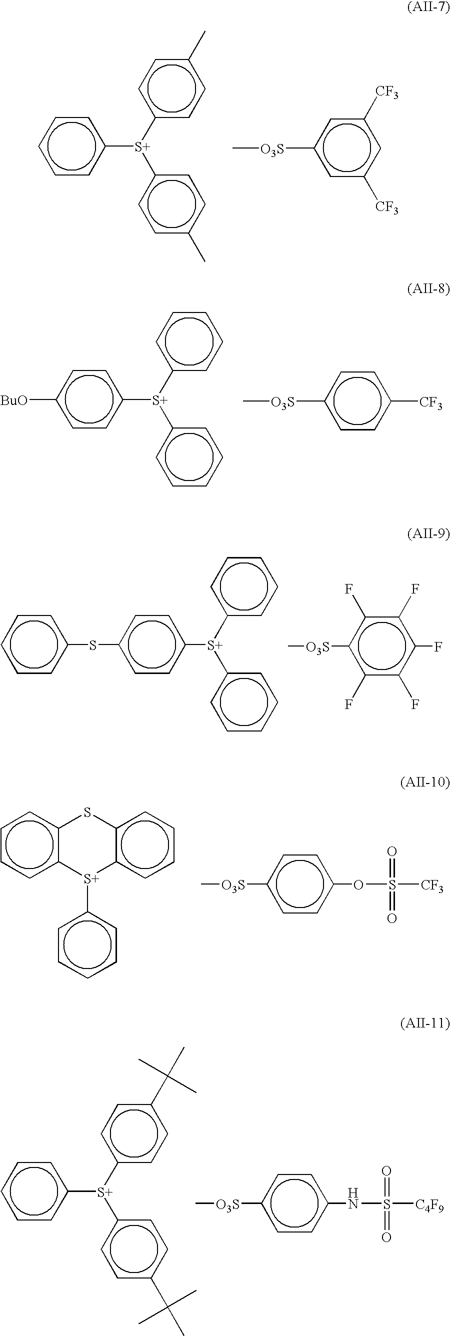

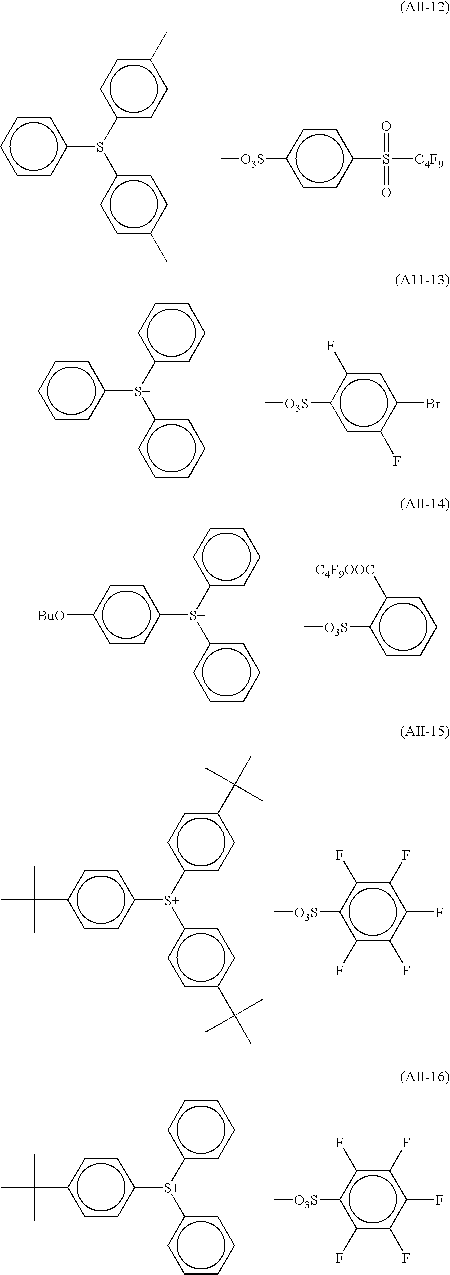

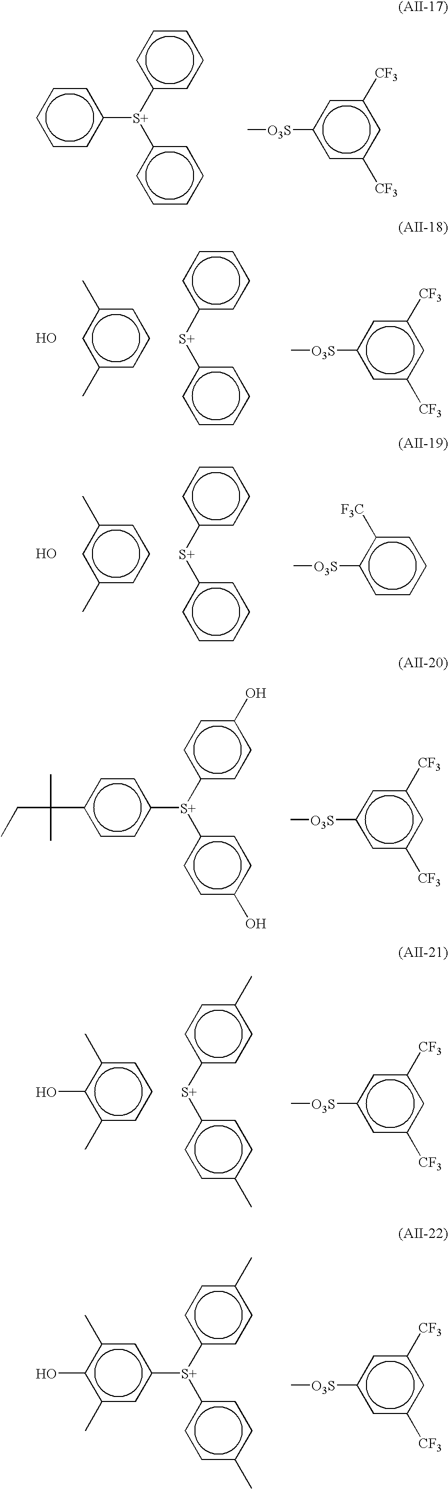

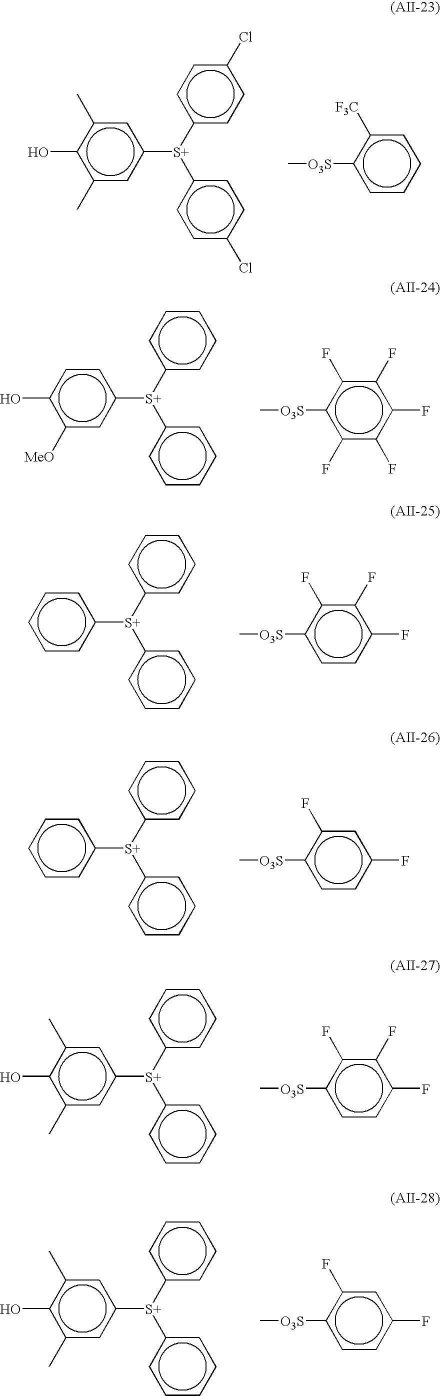

Preferred Illustrative Examples of the component (A) represented by the general formula (A1II) will be described below.

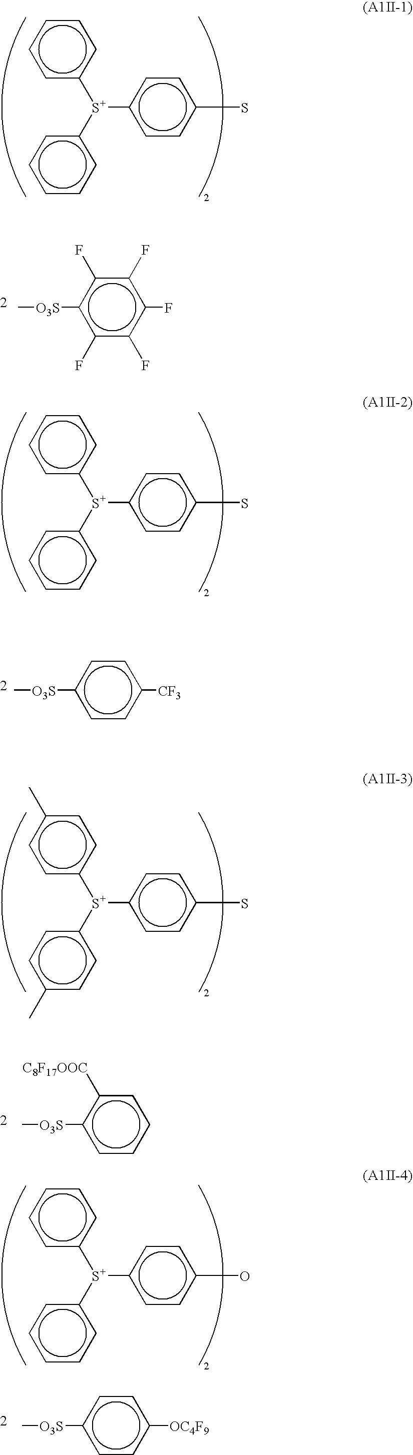

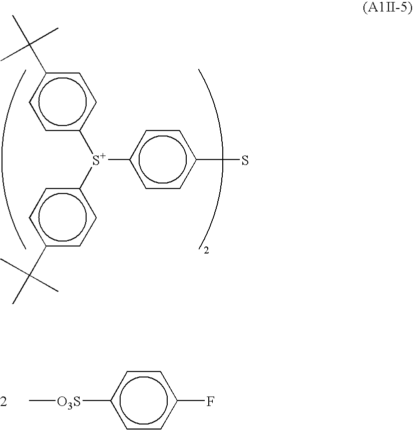

Preferred Illustrative Examples of the component (A) represented by the general formula (A1III) will be described below.

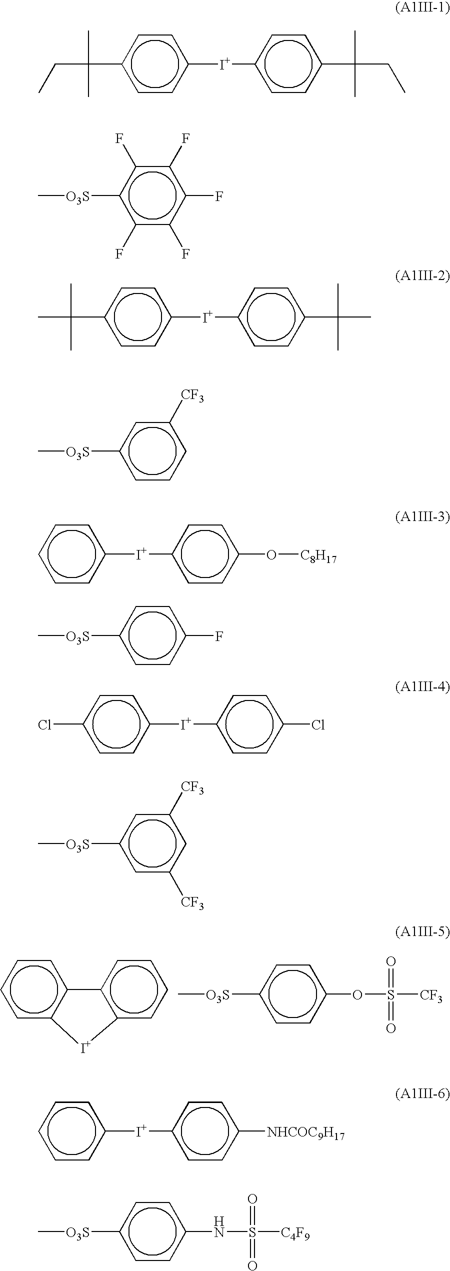

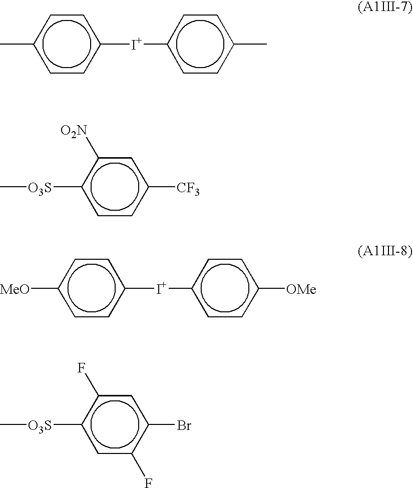

Compounds represented by the following general formulae (A1IV) to (A1VII) are also preferred as the component (A) of the present invention.

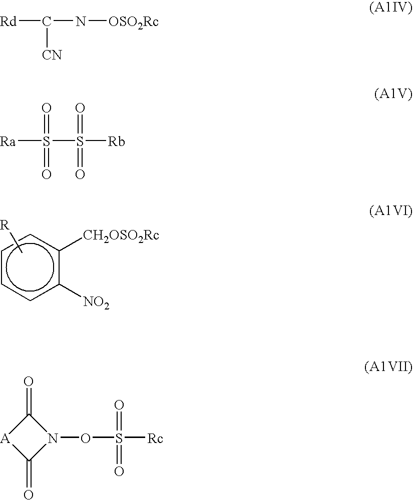

In the general formulae (A1IV) to (A1VII), Ra and Rb, which may be the same or different, each independently represents an optionally substituted linear, branched or cyclic alkyl group, an optionally substituted aryl group, an optionally heteroaryl group, or an optionally substituted aralkyl group, provided that at least one of Ra and Rb represents a phenyl group, a naphthalene group, or an anthracene group, each of which is substituted with at least one fluorine atom and/or a group having at least one fluorine atom; Rc represents a phenyl group, a naphthalene group, or an anthracene group, each of which is substituted with at least one fluorine atom and/or a group having at least one fluorine atom; Rd represents an optionally substituted linear, branched or cyclic alkyl group, an optionally substituted aryl group, an optionally heteroaryl group, or an optionally substituted aralkyl group; R represents a hydrogen atom, an optionally substituted linear, branched or cyclic alkyl group, a nitro group, or an alkoxy group; and A represents a substituted or unsubstituted alkylene group, arylene group or alkenylene group.

Preferred Illustrative Examples of the component (A) represented by the general formulae (A1IV) to (A1VII) will be described below.

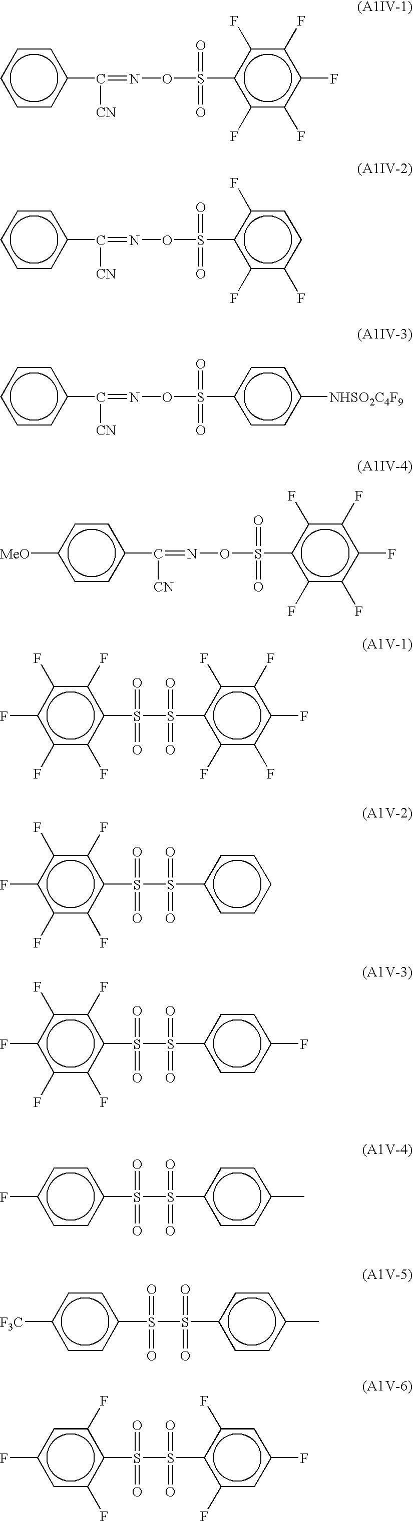

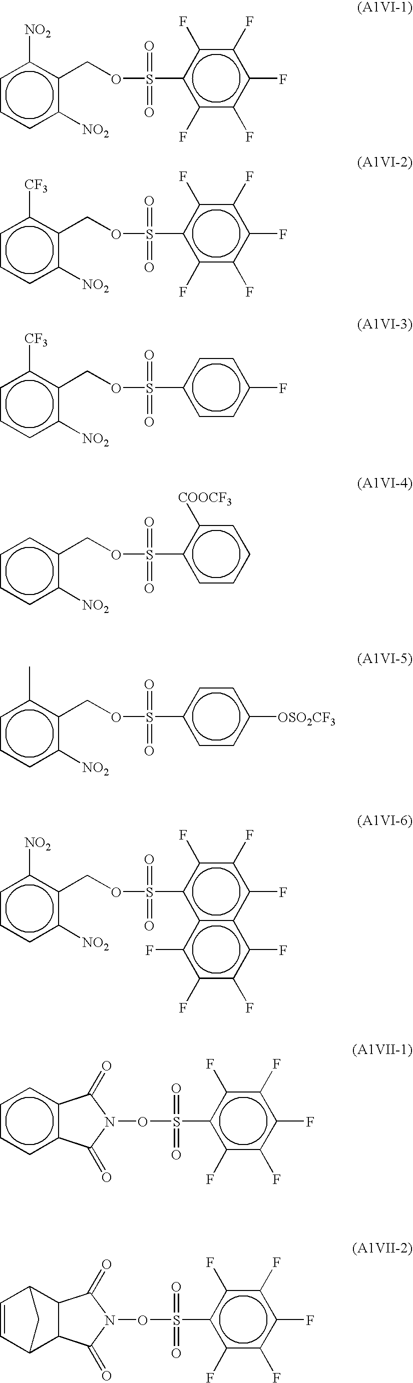

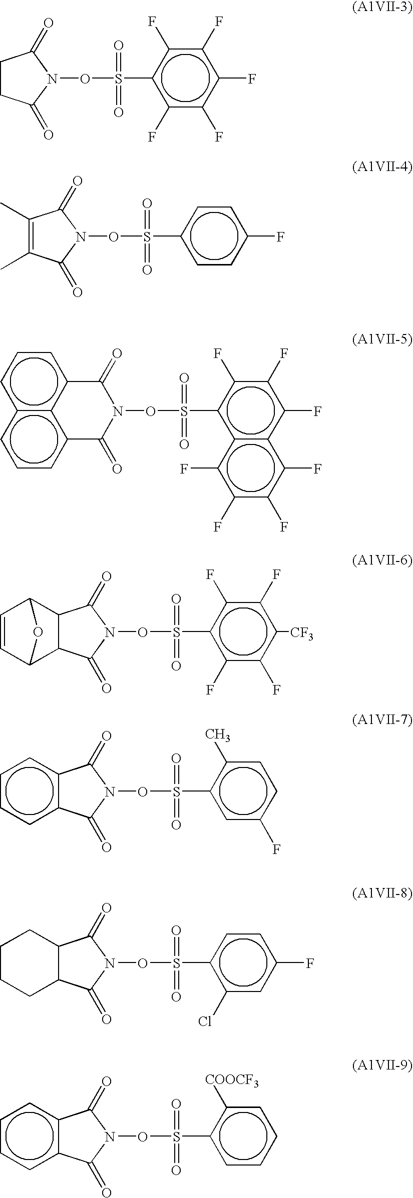

A compound represented by the following general formula (A1VIII) is also preferred as the component (A) of the present invention.

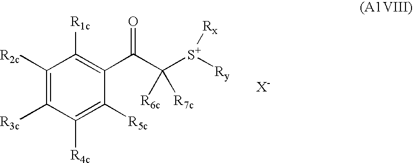

In the general formula (A1VIII), R_{1c} to R_{7c}, Rₓ, and R_{y} are respectively synonymous with R_{1c} to R_{7c}, Rₓ, and R_{y} in the general formula (A2I) as described later.

In the general formula (A1VIII), X⁻ is synonymous with X⁻ in the foregoing general formulae (A1I) to (A1III).

Preferred Illustrative Examples of the component (A) represented by the general formula (A1VIII) will be described below.

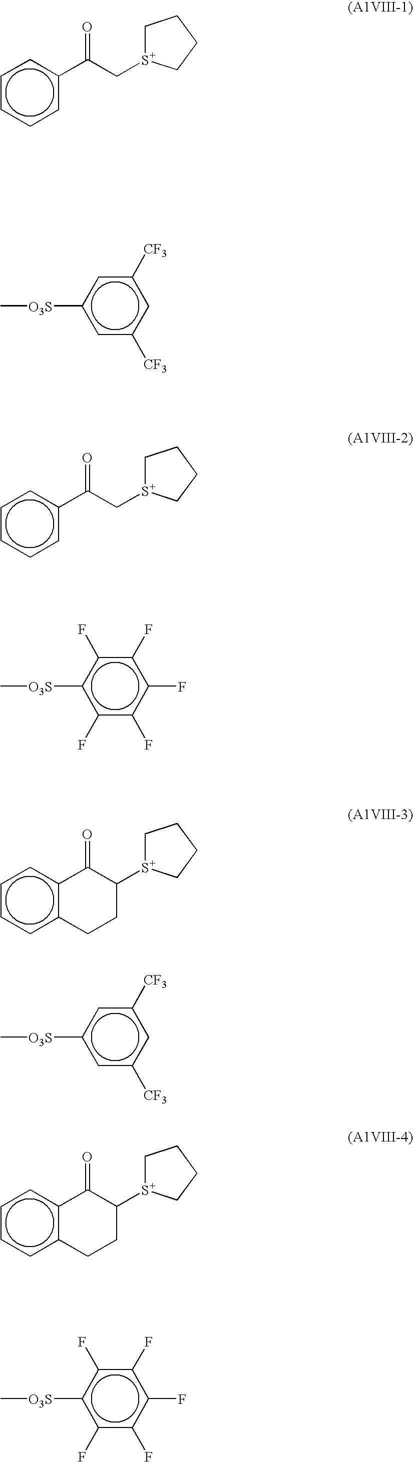

Synthesis examples of representative photo acid generators will be described below. Other photo acid generators can be synthesized in the same manner as in these synthesis examples.

(Synthesis of Tetramethylammonium Pentafluorobenzenesulfonate)

Pentafluorobenzenesulfonyl chloride (25 g) was dissolved in 100 mL of methanol under ice cooling, and 100 g of a 25% tetramethylammonium hydroxide aqueous solution was gradually added to the solution. The mixture was stirred at room temperature for 3 hours to obtain a solution of tetramethylammonium pentafluorobenzenesulfonate. This solution was used for salt exchange with a sulfonium salt and an iodonium salt.

(Synthesis of Triphenylsulfonium Pentafluorobenzenesulfonate: Synthesis of Illustrative Example (A1I-1))

Diphenyl sulfoxide (50 g) was dissolved in 800 mL of benzene, 200 g of aluminum chloride was added to the solution, and the mixture was refluxed for 24 hours. The reaction mixture was gradually poured into 2 L of water, 400 mL of concentrated hydrochloric acid was added thereto, and the mixture was heated at 70° C. for 10 minutes. The resulting aqueous solution was rinsed with 500 mL of ethyl acetate, and after filtration, 200 g of ammonium iodide dissolved in 400 mL of water was added thereto.

A deposited powder was collected by filtration, rinsed successively with water and ethyl acetate, and then dried to obtain 70 g of triphenylsulfonium iodide.

Triphenylsulfonium iodide (30.5 g) was dissolved in 1,000 mL of methanol, 19.1 g of silver oxide was added to the solution, and the mixture was stirred at room temperature for 4 hours. The resulting solution was filtered, and an excessive amount of the tetramethylammonium pentafluorobenzenesulfonate as synthesized above was added thereto. The reaction mixture was concentrated and dissolved in 500 mL of dichloroethane. The solution was rinsed successively with a 5% tetramethylammonium hydroxide aqueous solution and water. An organic phase was dried over anhydrous sodium sulfate and concentrated to obtain triphenylsulfonium pentafluorobenzenesulfonate.

(Synthesis of Triarylsulfonium Pentafluorobenzenesulfonates: Synthesis of mixture of Illustrative Examples (A1I-9) and (A1II-1))

In 500 mL of water was dissolved 50 g of a triarylsulfonium chloride (50% triphenylsulfonium chloride aqueous solution, made by Fluka), and an excessive amount of a solution of tetramethylammonium pentafluorobenzenesufonate was added to the solution to deposit an oily substance. A supernatant was removed by decantation, and the obtained oily substance was rinsed with water and dried to obtain a triarylsulfonium pentafluorobenzenesulfonate (containing Illustrative Examples (A1I-9) and (A1II-1) as major components)

(Synthesis of di(4-t-amylphenyl)iodonium Pentafluorobenzenesulfonate: Synthesis of Illustrative Example (A1III-1))

To a mixture of 60 g of t-amylbenzene, 39.5 g of potassium iodide, 81 g of acetic anhydride, and 170 mL of dichloromethane was gradually added dropwise 66.8 g of concentrated sulfuric acid under ice cooling. After stirring under ice cooling for 2 hours, the mixture was further stirred at room temperature for 10 hours. To the reaction mixture was added 500 mL of water under ice cooling, and the mixture was extracted with dichloromethane. An organic phase was rinsed successively with sodium hydrogencarbonate and water and then concentrated to obtain di(4-t-amylphenyl)iodonium sulfate. This sulfate was added to an excessive amount of a solution of tetramethylammonium pentafluorobenzenesulfonate. To this solution was added 500 mL of water, and the mixture was extracted with dichloromethane. An organic phase was rinsed successively with a 5% tetramethylammonium hydroxide aqueous solution and water and then concentrated to obtain di(4-t-amylphenyl)iodonium pentafluorobenzenesulfonate.

The compound (photo acid generator) to generate an acid upon irradiation with actinic rays or radiations, as represented by the following general formula (SI), which is contained in the composition of the present invention, will be described below.

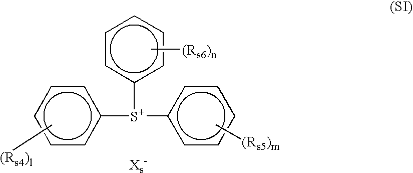

In the general formula (SI), examples of the alkyl group represented by Rₛ₄ to Rₛ₆ include ones having from 1 to 25 carbon atoms, which may be substituted, such as a methyl group, an ethyl group, a propyl group, n-butyl group, an isopropyl group, a sec-butyl group, a t-butyl group, a pentyl group, a hexyl group, a heptyl group, an octyl group, a t-amyl group, a decanyl group, a dodecanyl group, and a hexadecanyl group. Examples of the cycloalkyl group represented by Rₛ₄ to Rₛ₆ include ones having from 3 to 25 carbon atoms, which may be substituted, such as a cyclopropyl group, a cyclopentyl group, a cyclohexyl group, a cyclooctyl group, a cyclododecanyl group, and a cyclohexadecanyl group. Examples of the alkoxy group represented by Rₛ₄ to Rₛ₆ include ones having from 1 to 25 carbon atoms, which may be substituted, such as a methoxy group, an ethoxy group, a propoxy group, an isopropoxy group, an n-butoxy group, an isobutoxy group, a sec-butoxy group, a t-butoxy group, a pentyloxy group, a t-amyloxy group, an n-hexyloxy group, an n-octyloxy group, and an n-dodecaneoxy group.

Examples of the alkoxycarbonyl group represented by Rₛ₄ to Rₛ₆ include ones having from 2 to 25 carbon atoms, which may be substituted, such as a methoxycarbonyl group, an ethoxycarbonyl group, a propoxycarbonyl group, an isopropoxycarbonyl group, an n-butoxycarbonyl group, an isobutoxycarbonyl group, a sec-butoxycarbonyl group, a t-butoxycarbonyl group, a pentyloxycarbonyl group, a t-amyloxycarbonyl group, an n-hexyloxycarbonyl group, an n-octyloxycarbonyl group, and an n-dodecaneoxycarbonyl group. Examples of the acyl group represented by Rₛ₄ to Rₛ₆ include ones having from 1 to 25 carbon atoms, which may be substituted, such as a formyl group, an acetyl group, a butyryl group, a valeryl group, a hexanoyl group, an octanoyl group, a t-butylcarbonyl group, and a t-amylcarbonyl group. Examples of the acyloxy group represented by Rₛ₄ to Rₛ₆ include ones having from 2 to 25 carbon atoms, which may be substituted, such as an acetoxy group, an ethylyloxy group, a butyryloxy group, a t-butyryloxy group, a t-amylyloxy group, an n-hexanecarbonyloxy group, an n-octanecarbonyloxy group, an n-dodecanecarbonyloxy group, and an n-hexadecanecarbonyloxy group. Examples of the halogen atom represented by Rₛ₄ to Rₛ₆ include a fluorine atom, a chlorine atom, a bromine atom, and an iodine atom.

Examples of the substituent on these groups include an alkoxy group having from 1 to 4 carbon atoms, a halogen atom (such as a fluorine atom, a chlorine atom, a bromine atom, and an iodine atom), an acyl group having from 2 to 5 carbon atoms, an acyloxy group having from 2 to 5 carbon atoms, a cyano group, a hydroxyl group, a carboxy group, an alkoxycarbonyl group having from 2 to 5 carbon atoms, and a nitro group.

When (1+m+n)=1, then R₃₄ represents an optionally substituted alkyl group, an optionally substituted cycloalkyl group, an optionally substituted alkoxy group, an optionally substituted alkoxycarbonyl group, an optionally substituted acyl group, or an optionally substituted acyloxy group. In this case, Rₛ₄ preferably has 2 or more carbon atoms, and more preferably 4 or more carbon atoms.

Among them, as the alkyl group represented by Rₛ₄ to Rₛ₆ are preferable a methyl group, an ethyl group, a propyl group, an isopropyl group, a butyl group, a t-butyl group, an n-pentyl group, a t-amyl group, an n-hexyl group, an n-octyl group, and a decanyl group, each of which may be substituted; as the cycloalkyl group represented by Rₛ₄ to Rₛ₆ are preferable a cyclohexyl group, a cyclooctyl group, and a cyclododecanyl group, each of which may be substituted; as the alkoxy group represented by Rₛ₄ to Rₛ₆ are preferable a methoxy group, an ethoxy group, an isopropoxy group, an n-butoxy group, a sec-butoxy group, a t-butoxy group, a pentyloxy group, a t-amyloxy group, an n-hexyloxy group, an n-octyloxy group, and an n-dodecaneoxy group, each of which may be substituted; as the alkxoycarbonyl group represented by Rₛ₄ to Rₛ₆ are preferable a methoxycarbonyl group, an ethoxycarbonyl group, an isopropoxycarbonyl group, an n-butoxycarbonyl group, a sec-butoxycarbonyl group, a t-butoxycarbonyl group, a pentyloxycarbonyl group, a t-amyloxycarbonyl group, an n-hexyloxycarbonyl group, an n-octyloxycarbonyl group, and an n-dodecaneoxycarbonyl group, each of which may be substituted; as the acyl group represented by Rₛ₄ to Rₛ₆ are preferable a formyl group, an acetyl group, a butyryl group, a valeryl group, a hexanoyl group, an octanoyl group, a t-butylcarbonyl group, and a t-amylcarbonyl group, each of which may be substituted; and as the acyloxy group represented by Rₛ₄ to Rₛ₆ are preferable an acetoxy group, an ethylyloxy group, a butyryloxy group, a t-butyryloxy group, a t-amylyloxy group, an n-hexanecarbonyloxy group, and an n-octanecarbonyloxy group, each of which may be substituted.

More preferably, specific examples of the substituents Rₛ₄ to Rₛ₆ include a methyl group, an ethyl group, a propyl group, an isopropyl group, an n-butyl group, a t-butyl group, an n-pentyl group, a t-amyl group, an n-hexyl group, an n-octyl group, a cyclohexyl group, a methoxy group, an ethoxy group, an isopropoxy group, an n-butoxy group, a t-butoxy group, a pentyloxy group, a t-amyloxy group, a hexyloxy group, an n-octyloxy group, a methoxycarbonyl group, an ethoxycarbonyl group, an n-butoxycarbonyl group, a t-butoxycarbonyl group, a t-amyloxycarbonyl group, a hexyloxycarbonyl group, an n-octyloxycarbonyl group, a formyl group, an acetyl group, a butyryl group, a hexanoyl group, an octanoyl group, a t-butylcarbonyl group, a t-amylcarbonyl group, an acetoxy group, an ethylyloxy group, a butyryloxy group, a t-butyryloxy group, a t-amylyloxy group, an n-hexanecarbonyloxy group, an n-octanecarbonyloxy group, a hydroxyl group, a chlorine atom, a bromine atom, and a nitro group.

These groups may be substituted. Preferred examples of the substituent include a methoxy group, an ethoxy group, a t-butoxy group, a chlorine atom, a bromine atom, a cyano group, a hydroxyl group, a methoxycarbonyl group, an ethoxycarbonyl group, a t-butoxycarbonyl group, and a t-amyloxycarbonyl group.

l, m and n each presents from 1 to 3.

In the sulfonium compound represented by the general formula (SI) to be used in the present invention, a sulfonic acid having a specific structure, R—SO₃⁻ as described above is used as a counter anion, X⁻. As the aliphatic hydrocarbon group represented by R are preferable an optionally substituted linear or branched alkyl group and an optionally substituted cyclic alkyl group, each having from 1 to 20 carbon atoms. As the aromatic hydrocarbon group represented by R is preferable an optionally substituted aromatic group having from 6 to 14 carbon atoms.

Examples of the alkyl group represented by R include a methyl group, an ethyl group, a propyl group, an n-butyl group, an n-pentyl group, an n-hexyl group, an n-octyl group, a 2-ethylhexyl group, a decyl group, and a dodecyl group, each of which may be substituted; and examples of the cyclic alkyl group represented by R include a cyclopentyl group, a cylohexyl group, a cyclooctyl group, a cyclododecyl group, an adamantyl group, a norbornyl group, a camphor group, a tricyclodecanyl group, and menthyl group, each of which may be substituted. Examples of the aromatic group include a phenyl group and a naphthyl group, each of which may be substituted.

As the substituent are preferable an alkyl group, an alkoxy group, and an alkoxycarbonyl group, each having from 1 to 15 carbon atoms, and a halogen atom. Specific examples include a methyl group, t-butyl group, a methoxy group, an ethoxy group, a t-butoxy group, a chlorine atom, a bromine atom, a cyano group, a hydroxyl group, a methoxycarbonyl group, an ethoxycarbonyl group, a t-butoxycarbonyl group, and a t-amyloxycarbonyl group.

Specific examples of R include a methyl group, a trilfuoromethyl group, an ethyl group, a pentafluoroethyl group, a 2,2,2-trifluoroethyl group, an n-propyl group, an n-butyl group, a nonafluorobutyl group, an n-pentyl group, an n-hexyl group, an n-octyl group, a heptadecafluorooctyl group, a 2-ethylhexyl group, a decyl group, a dodecyl group, a cyclopentyl group, a cyclohexyl group, a camphor group, a phenyl group, a naphthyl group, a pentafluorophenyl group, a p-toluyl group, a p-fluorophenyl group, a p-chlorophenyl group, a p-hydroxyphenyl group, a p-methoxyphenyl group, a dodecylphenyl group, a mesityl group, a triisopropylphenyl group, a 4-hydroxy-1-naphthyl group, and a 6-hydroxy-2-naphthyl group.

More preferably, specific examples of R include a methyl group, a trilfuoromethyl group, an ethyl group, a pentafluoroethyl group, a 2,2,2-trifluoroethyl group, an n-butyl group, a nonafluorobutyl group, an n-hexyl group, an n-octyl group, a heptadecafluorooctyl group, a 2-ethylhexyl group, a camphor group, a phenyl group, a naphthyl group, a pentafluorophenyl group, a p-toluyl group, a p-fluorophenyl group, a p-chlorophenyl group, a p-methoxyphenyl group, a dodecylphenyl group, a mesityl group, a triisopropylphenyl group, a 4-hydroxy-1-naphthyl group, and a 6-hydroxy-2-naphthyl group.

The total sum of carbon atoms of the acid as generated is preferably from 1 to 30, more preferably from 1 to 28, and further preferably from 1 to 25. When the total sum of carbon atoms of the acid is less than 1, the pattern formation may possibly be hindered such that the acid becomes in a t-top shape, whereas when it exceeds 30, the development residue is possibly generated, and hence, such is not preferred.

Illustrative Examples of the compound represented by the general formula (SI) will be described below, but it should not be construed that the present invention is limited thereto. These compounds may be used singly or in admixture of two or more thereof.

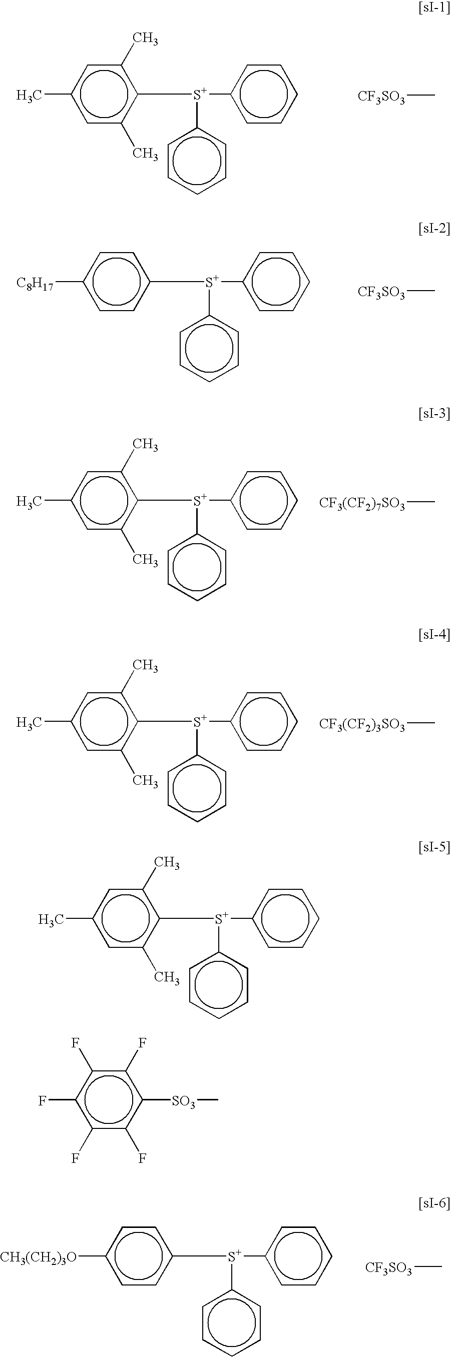

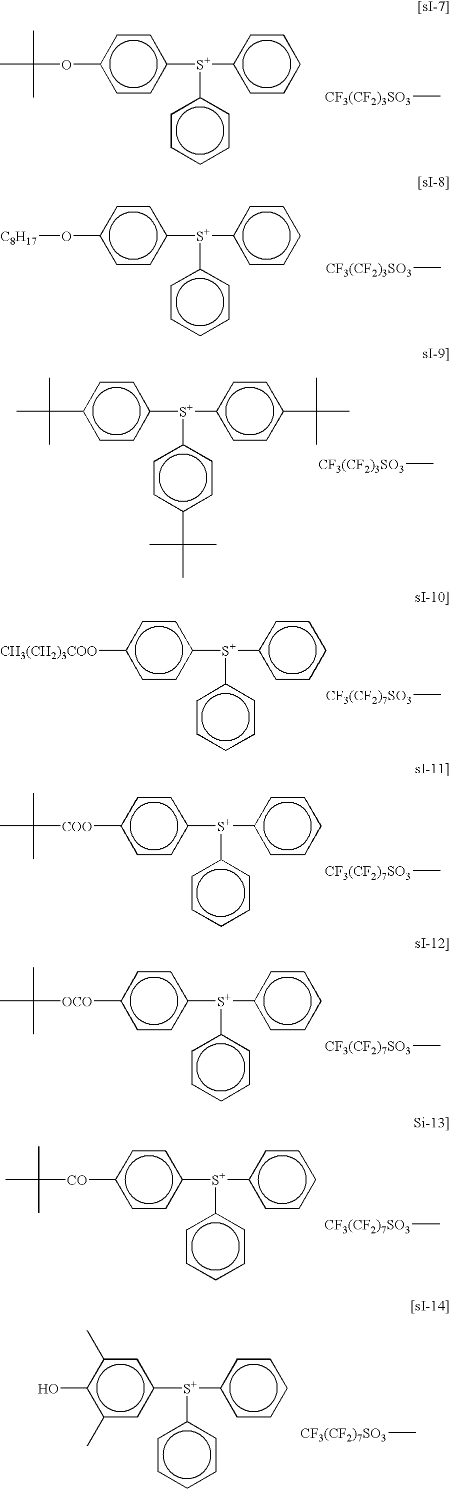

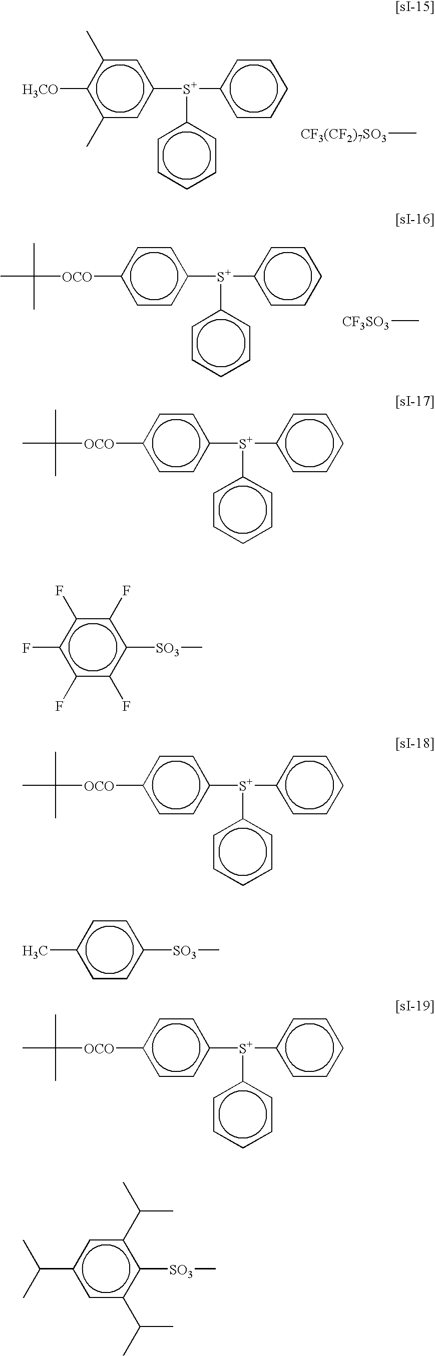

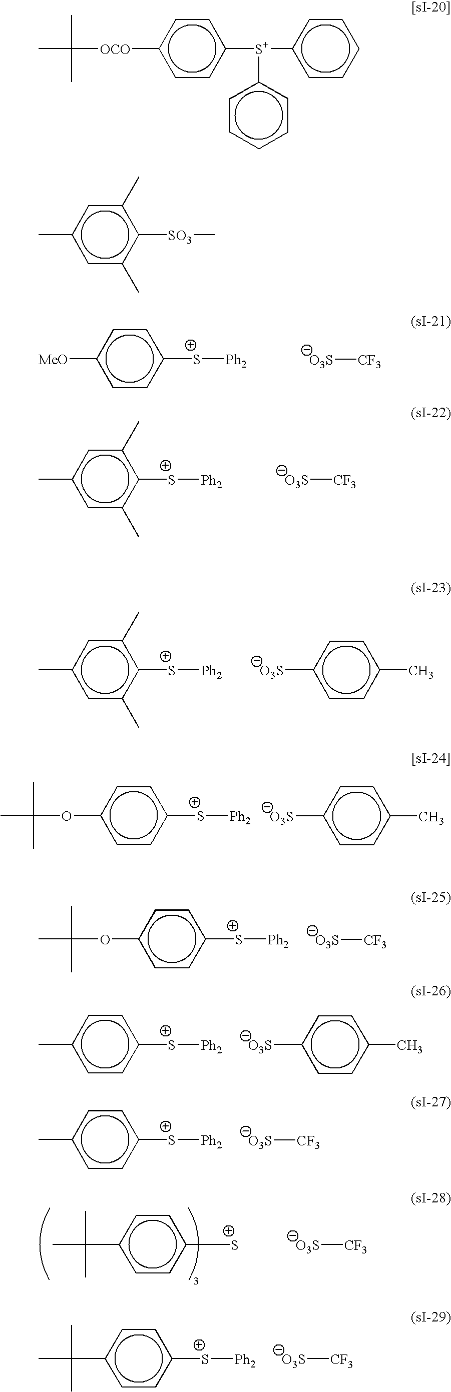

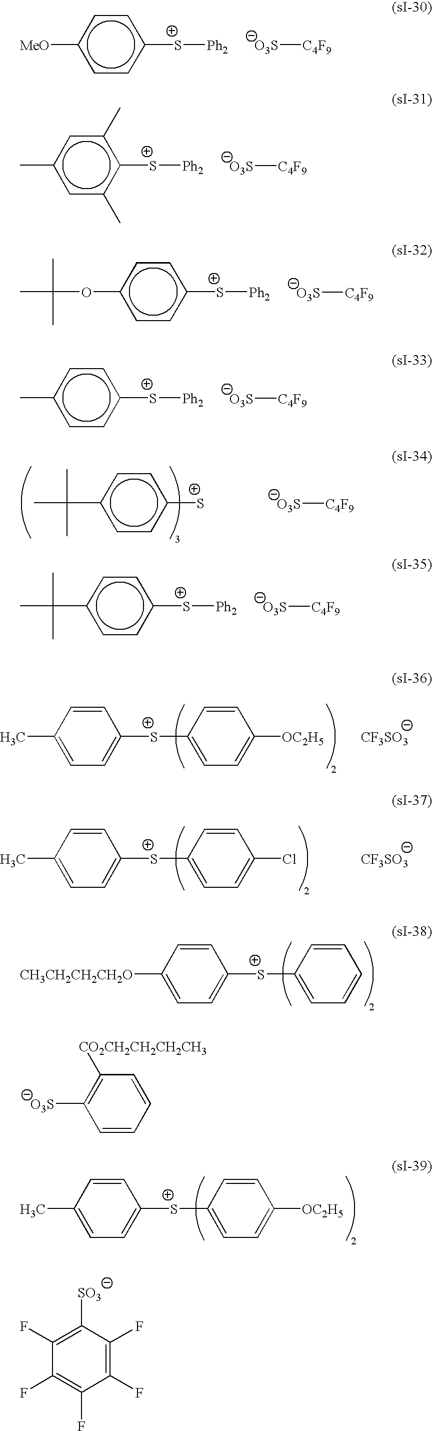

An addition amount of the photo acid generator represented by the general formula (SI) is usually in the range of from 0.001 to 20% by weight, preferably from 0.01 to 15% by weight, and more preferably from 0.1 to 10% by weight on a basis of the solids content in the composition. When the addition amount of the photo acid generator is less than 0.001% by weight, the sensitivity becomes low, whereby the pattern formation is liable to become difficult. On the other hand, when it exceeds 20% by weight, the light absorption of the resist becomes too high, whereby the profile is liable to become worse, or the process (especially, baking) margin or exposure margin is liable to become narrow.

The compound represented by the general formula (SI) can be synthesized by, for example, a method in which a substituted or unsubstituted phenyl sulfoxide is reacted with an aryl Grignard reagent such as an aryl magnesium bromide, and the obtained triarylsulfonium halide is subjected to salt exchange with a corresponding sulfonic acid.

Further, the compound represented by the general formula (SI) can be synthesized by, for example, a method in which a substituted or unsubstituted phenyl sulfoxide is condensed and subjected to salt exchange with a corresponding aromatic compound in the presence of an acid catalyst such as methanesulfonic acid/diphosphorus pentoxide and aluminum chloride, or a method in which a diaryliodonium salt and a diaryl sulfide are condensed and subjected to salt exchange in the presence of a catalyst such as copper acetate.

The salt exchange can be carried out by a method in which a halide is first introduced and then exchanged to a sulfonate using a silver reagent such as silver oxide, or by using an ion exchange resin. As the sulfonic acid or sulfonate that is used for the salt exchange, commercially available materials can be used. Alternatively, it can be obtained by hydrolysis of a commercially available sulfonic halide.

The foregoing component (A) may be used singly or in admixture of two or more thereof.

The total amount of the component (A) is usually from 0.1 to 20% by weight, preferably from 0.3 to 15% by weight, and more preferably from 0.5 to 10% by weight on a basis of the solids content of the positive-working photosensitive composition according to the present invention.

Especially, in the case where the component (A) is a combination of at least one of the compound (phenacylsulfonium salt) represented by the general formula (A2I) and the compound (sulfonium salt not having an aromatic ring) represented by the general formula (A2II) with the aromatic sulfonic acid substituted with at least one fluorine atom and/or a group having at least one fluorine atom, the edge roughness and development defect are improved.

A weight ratio of the both to be added is usually from 1/99 to 99/1, preferably from 5/95 to 95/5, and more preferably from 10/90 to 90/10.

When the compound (photo acid generator) to generate an acid upon irradiation with actinic rays or radiations, which is represented by the general formula (SI), is used as the component (A), an addition amount of other photo acid generator than the component (A), which may be used in combination, is usually 1,000% by weight or less, preferably 700% by weight or less, and more preferably 500% by weight or less on a basis of the photo acid generator represented by the general formula (SI).

In the present invention, a compound other than the foregoing specific component (A), which is decomposed upon irradiation with actinic rays or radiations to generate an acid, may be used in combination.

An amount of the photo acid generator that may be used in combination is usually from 100/0 to 5/95, preferably from 95/5 to 7/93, and more preferably from 90/10 to 10/90 in terms of molar ratio of the total amount of the component (A) to other acid generator.

As the photo acid generator other than the component (A), which can be used in combination, can be properly selected and usedphoto initiators of photo cationic polymerization, photo initiators of photo radical polymerization, light decoloring agents of dyes, light discoloring agents, and compounds to generate an acid by known lights used for microresists (such as ultraviolet rays of from 400 to 200 nm and far ultraviolet rays, and particularly preferably g-rays, h-ryas, i-rays, and KrF excimer laser beams), ArF excimer laser beams, electron beams, X rays, molecular rays, or ion beams, or mixtures thereof.

For example, there can be enumerated onium salts such as diazonium salts, ammonium salts, phosphonium salts, iodonium salts, sulfonium salts, selenonium salts, and arsonium salts, organic halides, organic metal/organic halides, photo acid generators having an o-nitrobenzyl type protective group, compounds that are photo-decomposed to generate a sulfonic acid, represented by iminosulfonate, disulfone compounds, diazoketo sulfones, and diazodisulfone compounds.

Further, polymer compounds in which a group or compound to generate an acid by light is introduced in the main chain or side chains thereof can be used.

In addition, the compounds to generate an acid by light, as described in, for example, V. N. R. Pillai, Synthesis, (1), 1 (1980), A. Abad, et al., Tetrahedron Lett., (47), 4555 (1971), D. H. R. Barton, et al., J. Chem. Soc., (C), 329 (1970), U.S. Pat. No. 3,779,778, and European Patent No. 126,712 can be used.

Among the compounds that are decomposed upon irradiation with actinic rays or radiations to generate an acid, other photo acid generators that are particularly effectively used will be described below.

(1) Oxazole derivative represented by the following general formula (PAG1) or S-triazine derivative represented by the following general formula (PAG2), each of which is substituted with a trihalomethyl group:

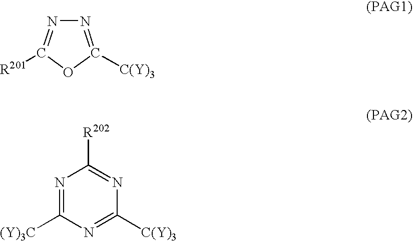

In the general formulae, R²⁰¹ represents a substituted or unsubstituted aryl group or alkenyl group; R²⁰² represents a substituted or unsubstituted aryl group, alkenyl group or alkyl group, or —C(Y)₃; and Y represents a chlorine atom or a bromine atom.

(2) Iodonium salt represented by the following general formula (PAG3) or sulfonium salt represented by the following general formula (PAG4):

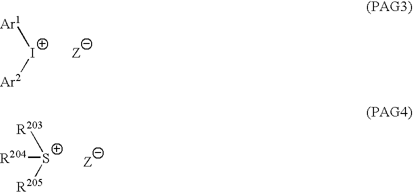

In the general formulae, Ar¹ and Ar² each independently represents a substituted or unsubstituted aryl group; and R²⁰³ R²⁰⁴, and R²⁰⁵ each independently represents a substituted or unsubstituted alkyl group or aryl group.

Z⁻ represents a counter anion. Examples of the counter anion represented by Z⁻ include perfluoroalkanesulfonic anions such as BF₄⁻, AsF₆⁻, PF₆⁻, SbF₆⁻, SiF₆⁻, ClO₄⁻, and CF₃SO₃—; a pentafluorobenzenesulfonic anion; condensed polynucleic aromatic sulfonic anions such as a naphthalene-1-sulfonic anion; an anthraquinonesulfonic anion; and a sulfonic group-containing dyes. But, it should not be construed that the present invention is limited thereto.

Two of R²⁰³, R²⁰⁴, and R²⁰⁵, and Ar¹ and Ar² may be each taken together via a simple bond or a substituent.

Illustrative Examples of these other photo acid generators will be described below, but it should not be construed that the present invention is limited thereto.

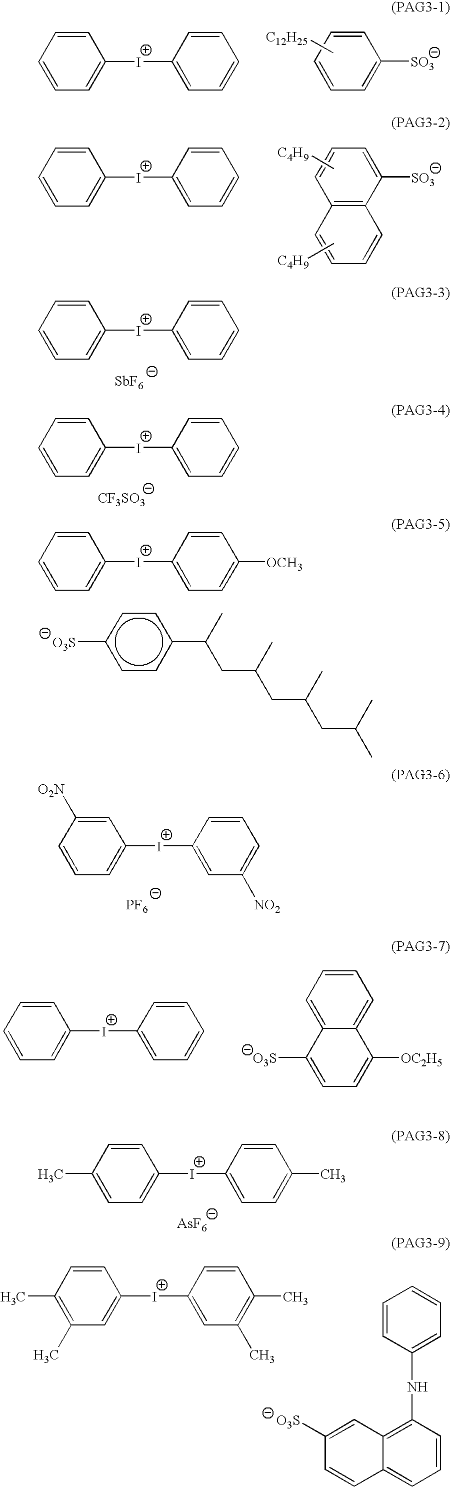

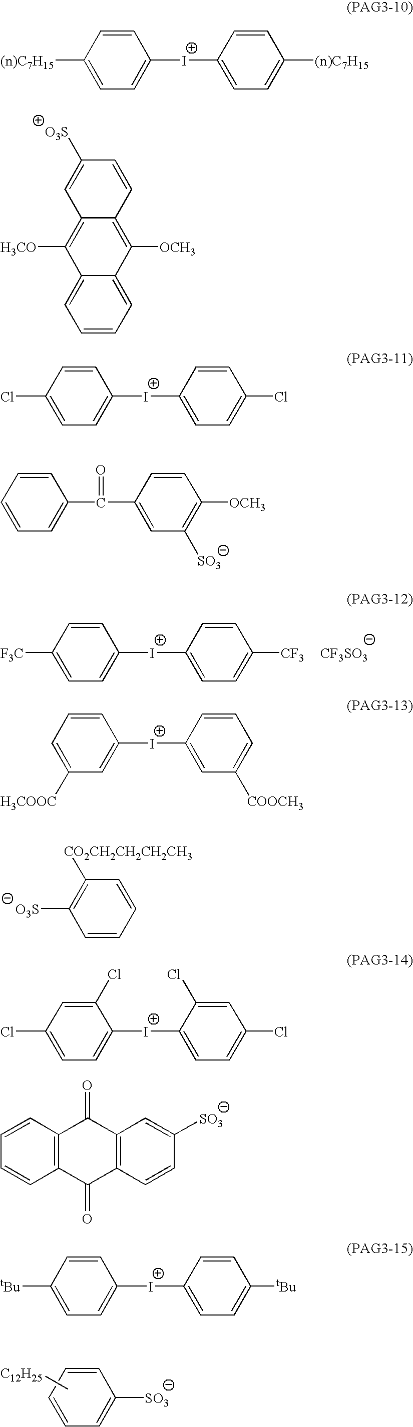

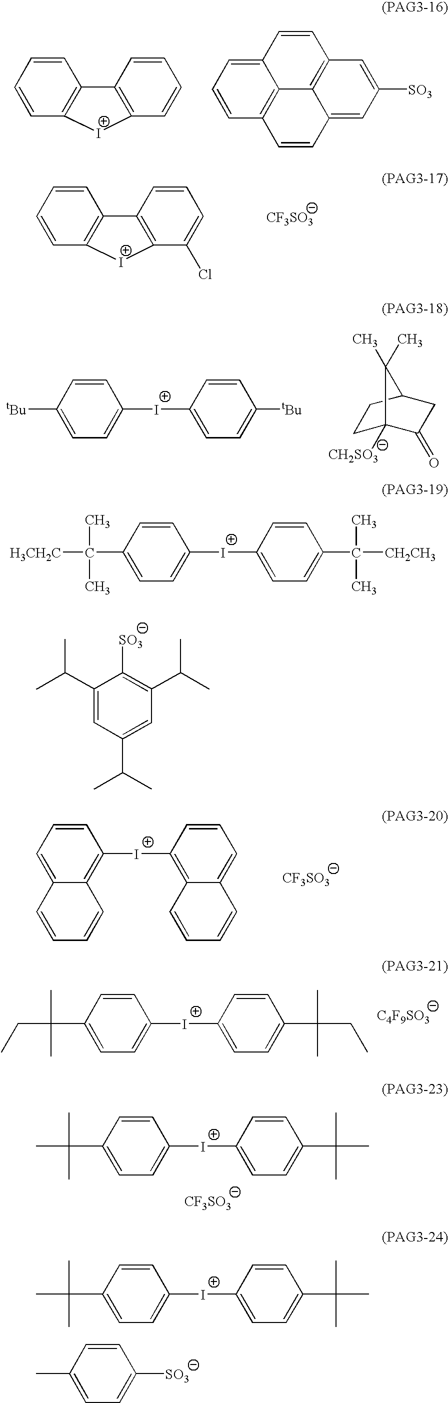

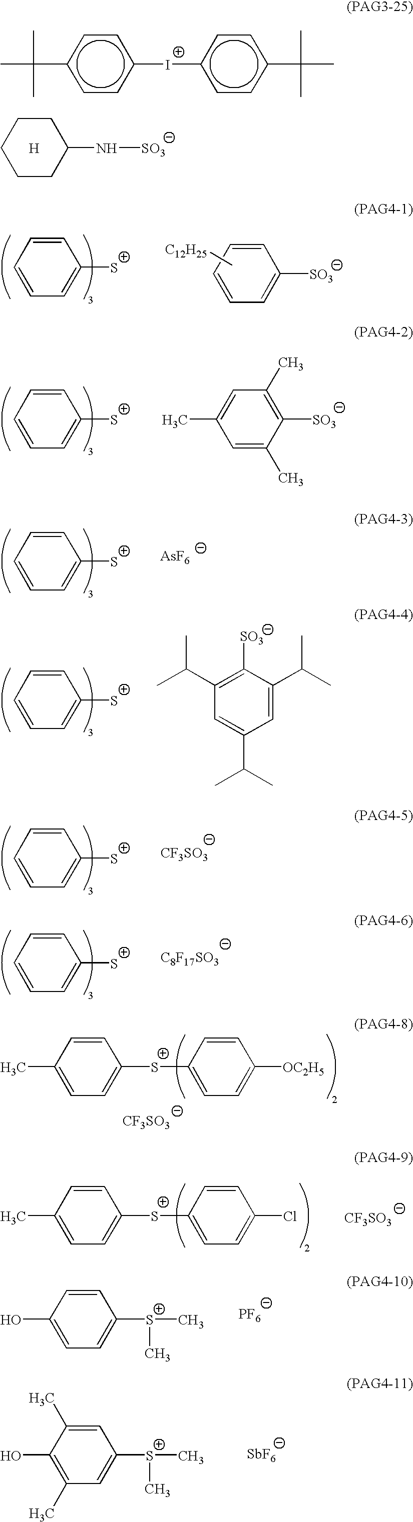

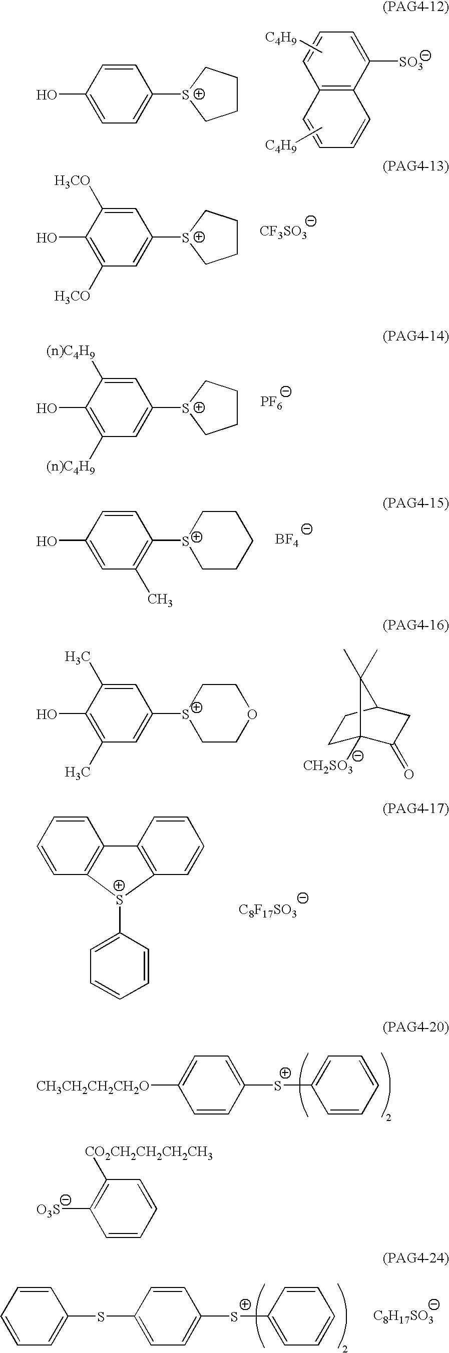

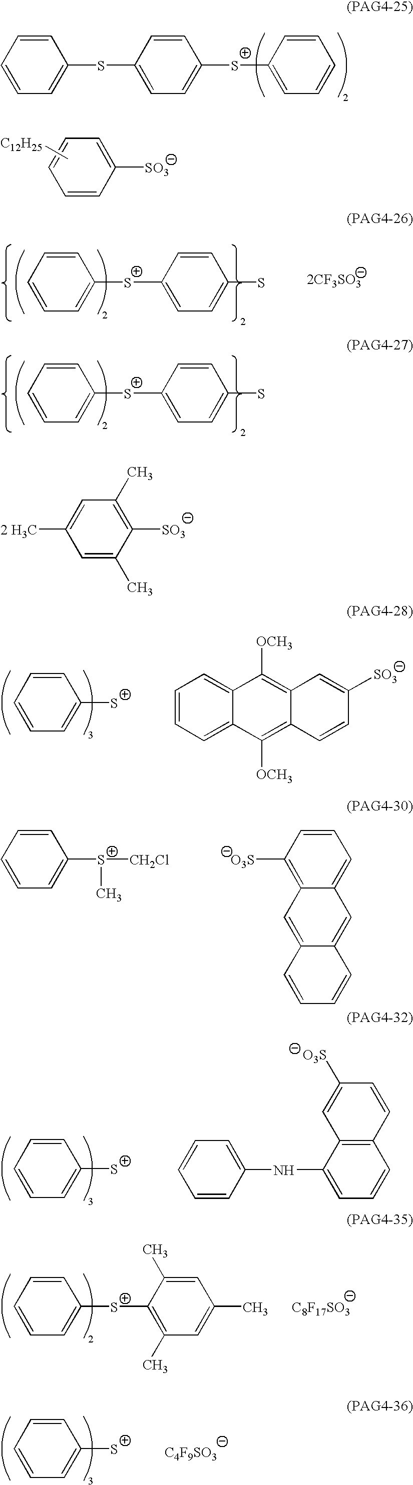

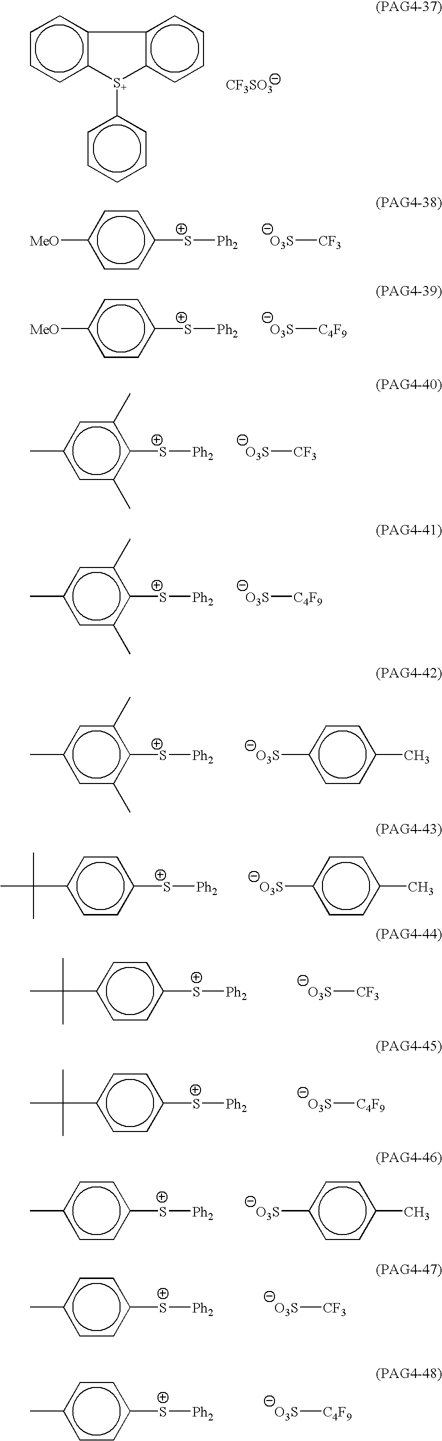

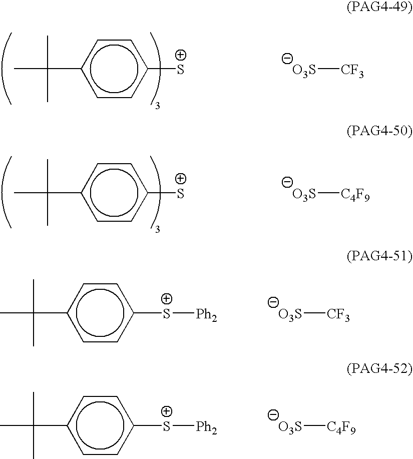

In the foregoing formulae, Ph represents a phenyl group.

The onium salts represented by the general formulae (PAG3) and (PAG4) are known and can be synthesized by the methods as described in, for example, U.S. Pat. Nos. 2,807,648 and 4,247,473 and JP-A-53-101,331.

(3) Disulfone derivative represented by the following general formula (PAG5) or iminosulfonate derivative represented by the following general formula (PAG6):

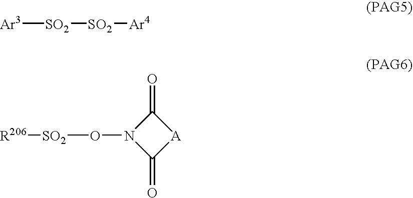

In the general formulae, Ar³ and Ar⁴ each independently represents a substituted or unsubstituted aryl group; R²⁰⁶ represents a substituted or unsubstituted alkyl group or aryl group; and A represents a substituted or unsubstituted alkylene group, alkenylene group or arylene group.

Illustrative Examples of these other photo acid generators will be described below, but it should not be construed that the present invention is limited thereto.

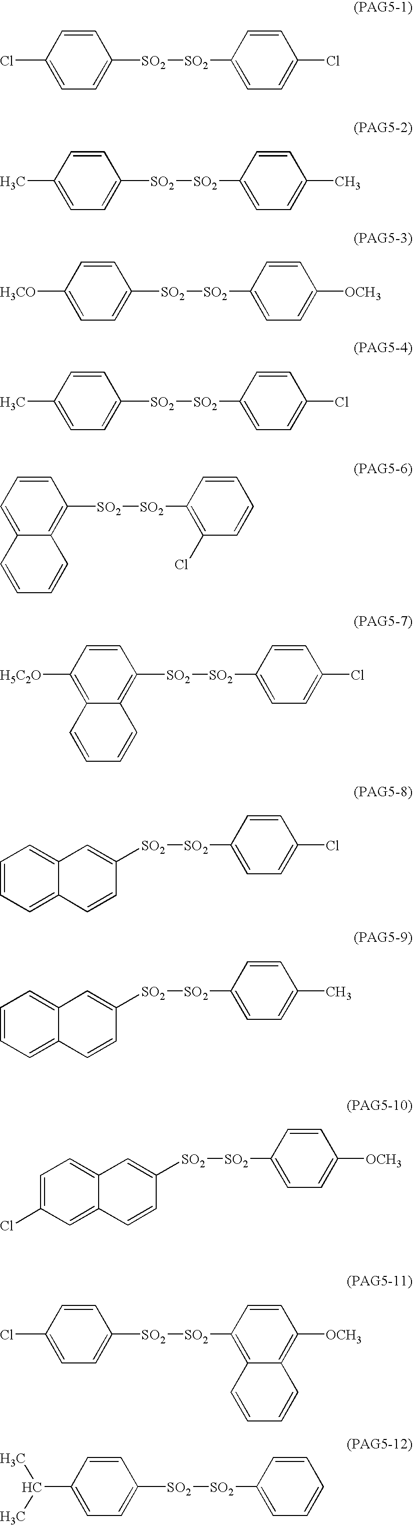

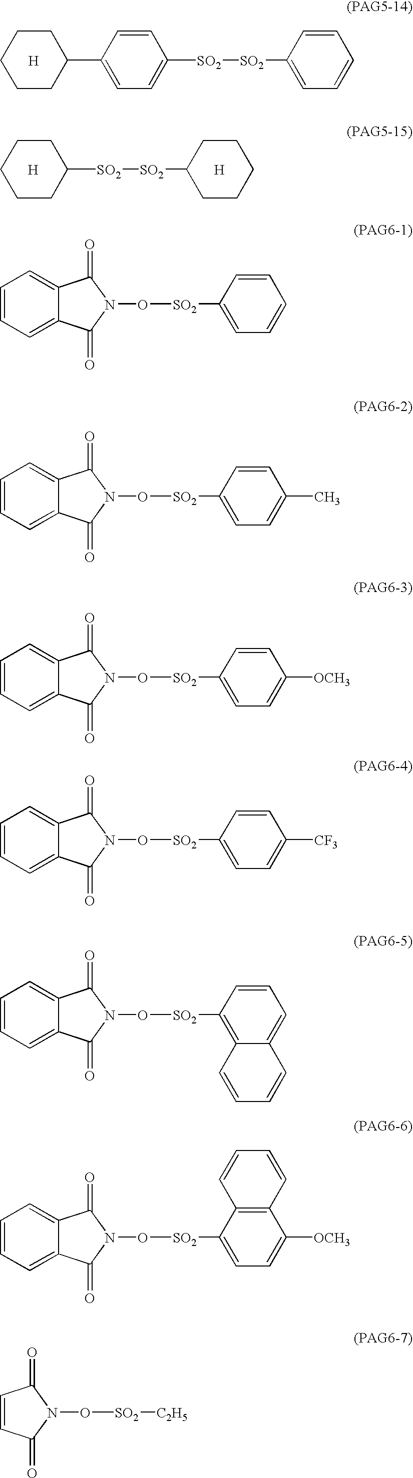

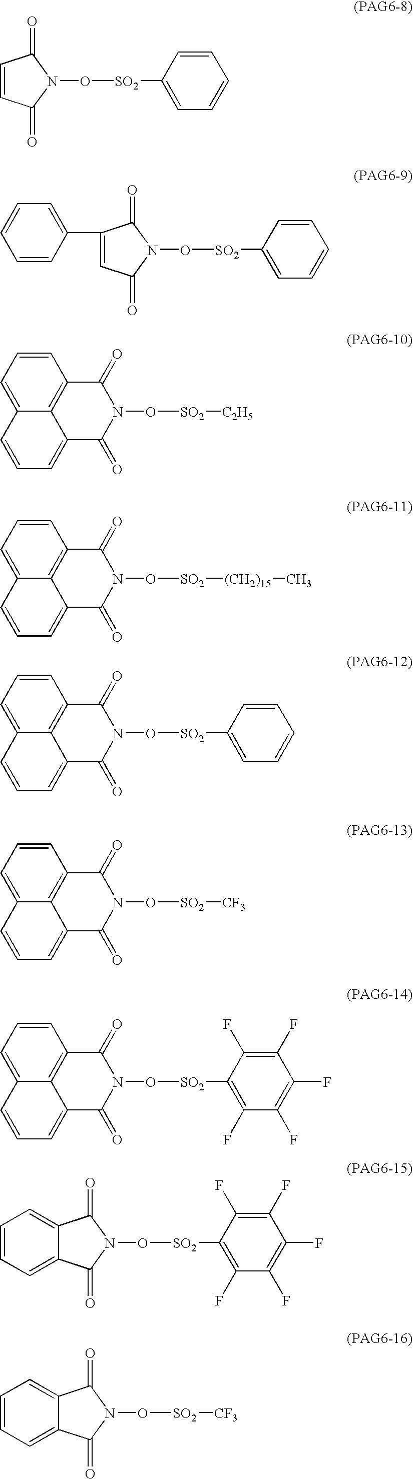

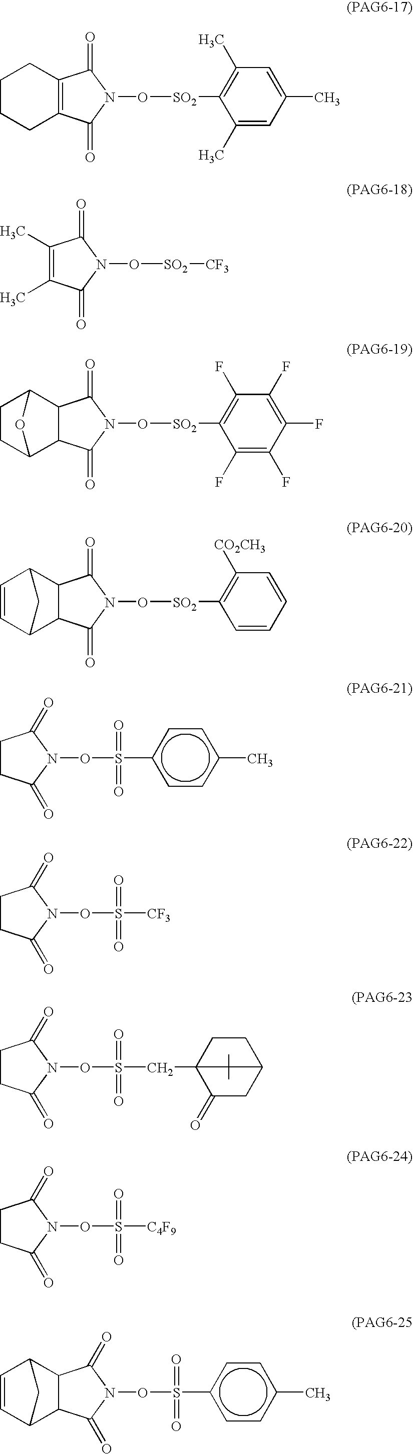

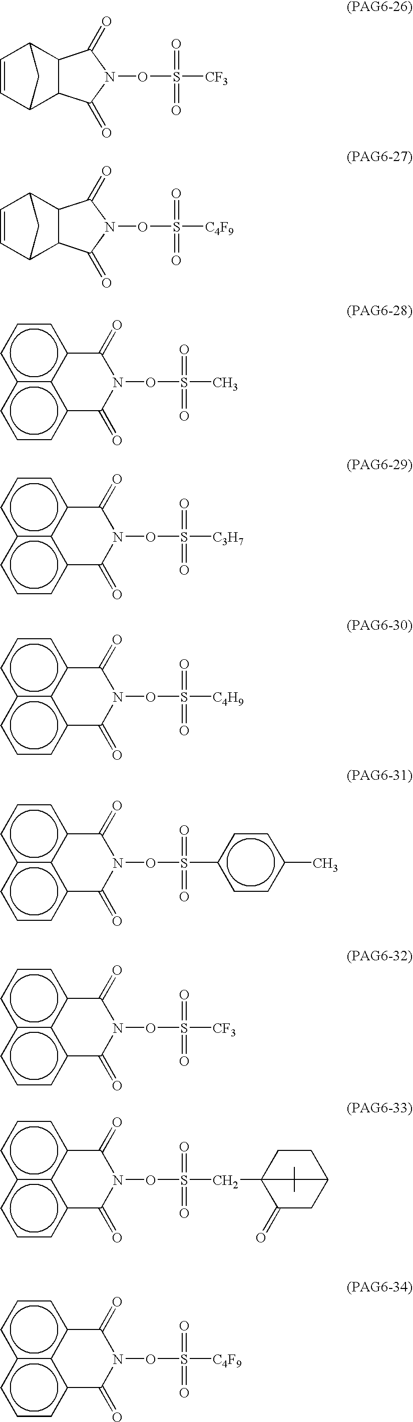

(4) Diazodisulfone derivative represented by the following general formula (PAG7):

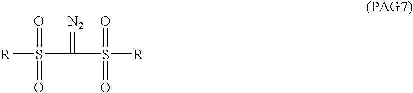

In general formula, R represents a linear, branched or cyclic alkyl group or an optionally substituted aryl group.

Illustrative Examples of these other photo acid generators will be described below, but it should not be construed that the present invention is limited thereto.

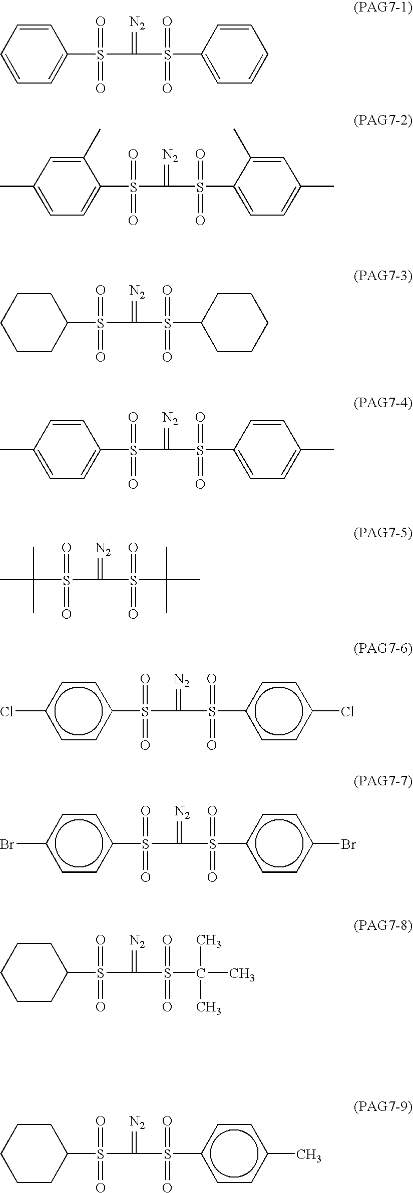

<Synthesis Examples of Photo Acid Generator>

The synthesis examples of representative photo acid generators will be described below. Other photo acid generators can be synthesized in the same manner as in these synthesis examples.

(Synthesis of Tetramethylammonium Pentafluorobenzenesulfonate)

Pentafluorobenzenesulfonyl chloride (25 g) was dissolved in 100 mL of methanol under ice cooling, and 100 g of a 25% tetramethylammonium hydroxide aqueous solution was gradually added to the solution. The mixture was stirred at room temperature for 3 hours to obtain a solution of tetramethylammonium pentafluorobenzenesulfonate. This solution was used for salt exchange with a sulfonium salt and an iodonium salt.

(Synthesis of Phenacyltetrahydrothiophenium Perfluorobutanesulfonate: Synthesis of Illustrative Example (A2I-1))

In 400 mL of acetonitrile was dissolved 53.2 g of tetrahydrothiophene. To this solution was gradually added a solution of 100 g of phenacyl bromide dissolved in 300 mL of acetonitrile. The mixture was stirred at room temperature for 3 hours to deposit a powder. The reaction mixture was poured into 1,500 mL of ethyl acetate, and the powder was collected by filtration and dried to obtain 137 g of phenacyltetrahydrothiophenium bromide.

Potassium perfluorobutanesulfonate (60 g) was dissolved in a mixed solvent of 200 mL of water and 200 mL of methanol. To this solution was added a solution of 49.5 g of phenacyltetrahydrothiophenium bromide dissolved in 300 mL of water. This aqueous solution was extracted twice with 200 mL of chloroform, and an organic phase was rinsed with water and concentrated to obtain a crude product, to which was then added 300 mL of distilled water. The mixture was heated at 100° C. for 30 minutes and then cooled to deposit a solid. The solid was collected by filtration and re-slurried with diisopropyl ether to obtain 77 g of phenacyltetrahydrothiophenium perfluorobutanesulfonate.

(Synthesis of Phenacyltetrahydrothiophenium Perfluorooctanesulfonate: Synthesis of Illustrative Example (A2I-3))

Phenacyltetrahydrothiophenium bromide was subjected to salt exchange with perfluorooctanesulfonic acid in the same manner as described above.

(Synthesis of Phenacyltetrahydrothiophenium Trifluoromethanesulfonate: Synthesis of Illustrative Example (A2I-2))

Phenacyltetrahydrothiophenium bromide was subjected to salt exchange with trifluoromethanesulfonic acid in the same manner as described above.

(Synthesis of Illustrative Example (A2II-11))

In 100 mL of acetonitrile was dissolved 11.8 g of tetrahydrothiophene. To this solution was gradually added 20 g of 1-bromo-3,3-dimethyl-2-butanone. The mixture was stirred at room temperature for 2 days to deposit a powder. To the reaction mixture was 100 mL of ethyl acetate, and the powder was collected by filtration and rinsed with ethyl acetate, followed by drying to obtain 24 g of 2-oxo-3,3-dimethylbutyltetrahydrothiophenium bromide.

Potassium perfluorobutanesulfonate (10 g) was dissolved in a mixed solvent of 500 mL of water and 100 mL of methanol. To this solution was added a solution of 7.75 g of 2-oxo-3,3-dimethylbutyltetrahydrothiophenium bromide dissolved in 50 mL of methanol. This aqueous solution was extracted twice with 100 mL of chloroform, and an organic phase was rinsed with water and concentrated to obtain an oily material. To this oily material was added ethyl acetate for re-concentration, to obtain a solid. The solid was collected by filtration and re-slurried with diisopropyl ether to obtain 9 g of 2-oxo-3,3-dimethylbutyltetrahydrothiophenium perfluorobutanesulfonate.

2-Oxocyclohexylmethyl(2-norbornyl)sulfonium trifluoromethanesulfonate (A2II-1) can be synthesized according to Synthesis Example 1 of JP-A-8-27102.

[2] Acid-Decomposable Resin (Component (B)):

The resin (component (B)) that is used in the present invention is a resin having a repeating unit represented by the following general formula (I) and a repeating unit represented by the following general formula (II), which is decomposed by the action of an acid to increase its solubility in an alkaline developing solution (this resin will be hereunder abbreviated as “acid-decomposable resin”).

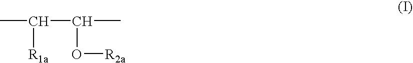

In the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring.

The hydrocarbon group represented by R₁ₐ preferably has from 1 to 10 carbon atoms, and particularly preferably from 1 to 5 carbon atoms, and examples thereof include an alkyl group (preferably a methyl group). R₁ₐ preferably represents a hydrogen atom or a methyl group.

The hydrocarbon group represented by R₂ₐ preferably has from 1 to 20 carbon atoms, and particularly preferably from 1 to 10 carbon atoms, and examples thereof include an alkyl group and a cycloalkyl group.

The hydrocarbon group represented by R₁ₐ and R₂ₐ may be substituted. The substituent preferably has from 1 to 30 carbon atoms. Examples of the substituent include a hydroxyl group, a halogen atom, an alkoxy group, an acyl group, an acylcarbonyl group, and an acyloxy group.

The ring structure in these substituents may contain a hetero atom or may have a substituent such as a hydroxyl group, an alkyl group (preferably one having from 1 to 5 carbon atoms) and an alkoxy group (preferably one having from 1 to 5 carbon atoms).

Examples of the ring formed when R₁ₐ and R₂ₐ are taken together include from 4- to 8-membered rings such as a tetrahydrofuran ring and a tetrahydropyran ring. This ring structure may have a substituent as described above.

Specific examples of the repeating unit represented by the general formula (I) will be described below, but it should not be construed that the present invention is limited thereto.

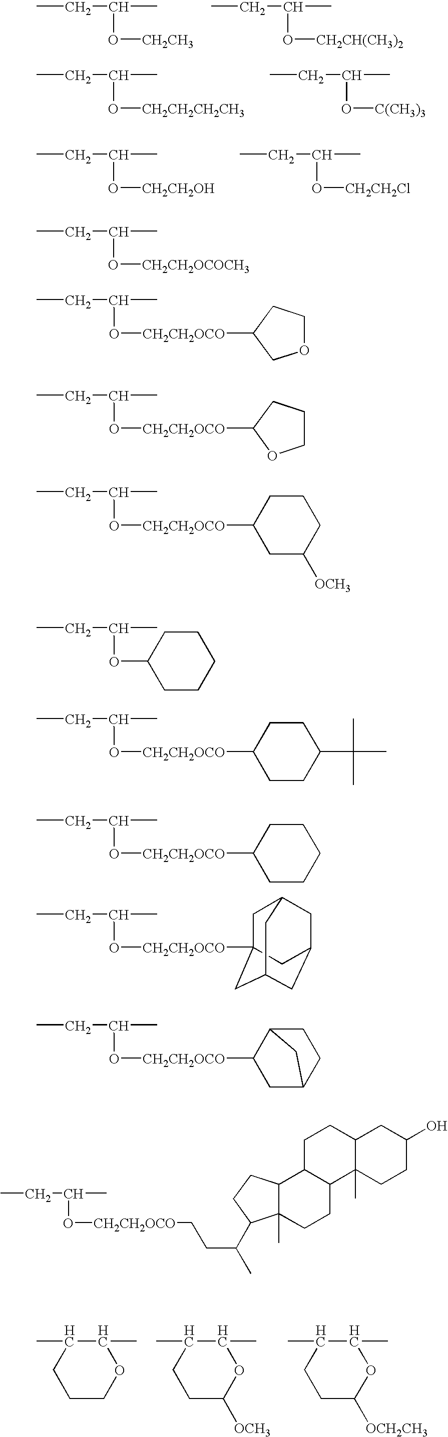

The acid-decomposable resin of the present invention further contains a repeating unit represented by the following general formula (II).

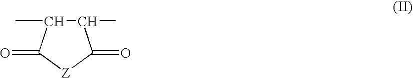

In the general formula (II), Z represents —O— or —N(R₃ₐ)—; R₃ₐ represents a hydrogen atom, a hydroxyl group, an alkyl group, a haloalkyl group, or —OSO₂—R₄ₐ; and R₄ₐ represents an alkyl group, a haloalkyl group, a cycloalkyl group, or a camphor residue.

The alkyl group represented by R₃ₐ and R₄ₐ is preferably a linear or branched alkyl group having from 1 to 10 carbon atoms, more preferably a linear or branched alkyl group having from 1 to 6 carbon atoms, and further preferably a methyl group, an ethyl group, a propyl group, an isopropyl group, an n-butyl group, an isobutyl group, a sec-butyl group, or a t-butyl group.

Examples of the haloalkyl group represented by R₃ₐ and R₄ₐ include a trifluoromethyl group, a nanofluorobutyl group, a pentadecafluorooctyl group, and a trichloromethyl group. Examples of the cycloalkyl group represented by R₄ₐ include a cyclopentyl group, a cyclohexyl group, and a cylooctyl group.

The alkyl group and haloalkyl group represented by R₃ₐ and R₄ₐ and the cycloalkyl group and camphor residue represented by R₄ₐ may be each substituted. Examples of the substituent include a hydroxyl group, a carboxyl group, a cyano group, a halogen atom (such as a chlorine atom, a bromine atom, a fluorine atom, and an iodine atom), an alkoxy group (preferably one having from 1 to 4 carbon atoms, such as a methoxy group, an ethoxy group, a propoxy group, and a butoxy group), an acyl group (preferably one having from 2 to 5 carbon atoms, such as a formyl group and an acetyl group), an acyloxy group (preferably one having from 2 to 5 carbon atoms, such as an acetoxy group), and an aryl group (preferably one having from 6 to 14 carbon atoms, such as a phenyl group).

Specific exmples of the repeating unit represented by the general formula (II) will be described below, but it should not be construed that the present invention is limited thereto.

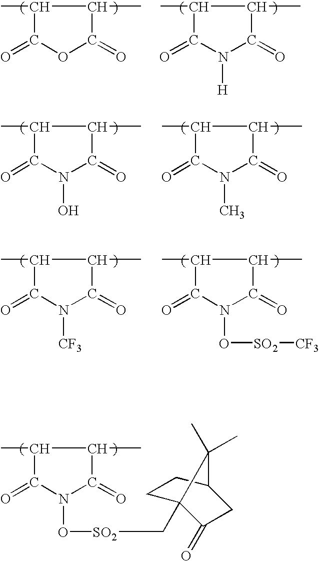

In the acid-decomposable resin of the present invention, a group that is decomposed by the action of an acid to become alkali-soluble may be contained in the repeating unit represented by the foregoing general formula (I) or (II) or in other repeating unit.

Examples of the group that is decomposed by the action of an acid include groups represented by —COOA⁰ and —O—B⁰. Further, examples of the group containing the same include —R⁰—COOA⁰ and —Ar—O—B⁰.

Here, A⁰ represents —C(R⁰¹) (R⁰²) (R⁰³), —Si(R⁰¹) (R⁰²) (R⁰³) —C(R⁰⁴) (R⁰⁵)—O—R⁰⁶, or a lactone group; and B⁰ represents -A⁰ or —CO—O-A⁰.

R⁰¹, R⁰², R⁰³, R⁰⁴, and R⁰⁵, may be the same or different, each independently represents a hydrogen atom, an alkyl group, a cycloalkyl group, an alkenyl group, an aralkyl group, or an aryl group; and R⁰⁶ represents an alkyl group, a cyclic alkyl group, or an aryl group, provided that at least two of R⁰¹ to R⁰³ represent a group other than a hydrogen atom and that two groups of R⁰¹ to R⁰³, and R⁰⁴ to R⁰⁶ may be taken together to form a ring. R⁰ represents a simple bond or an optionally substituted aliphatic or aromatic hydrocarbon group having a valence of 2 or more; and —Ar— represents an aromatic group having a valence of 2 or more, which may be substituted with a monocyclic or polycyclic substituent.

Here, as the alkyl group is preferable one having from 1 to 4 carbon atoms, such as a methyl group, an ethyl group, a propyl group, an n-butyl group, a sec-butyl group, and a t-butyl group; as the cycloalkyl group is preferable one having from 3 to 30 carbon atoms, such as a cyclopropyl group, a cyclobutyl group, a cylohexyl group, and an adamantyl group; as the alkenyl group is preferable one having from 2 to 4 carbon atoms, such as a vinyl group, a propenyl group, an allyl group, and a butenyl group; and as the aryl group is preferable one having from 6 to 14 carbon atoms, such as a phenyl group, a xylyl group, a toluyl group, a cumenyl group, a naphthyl group, and an anthracenyl group. As the cyclic alkyl group is enumerated one having from 3 to 30 carbon atoms, and specific examples thereof include a cyclopropyl group, a cyclopentyl group, a cyclohexyl group, an adamantyl group, a norbornyl group, a bornyl group, a tricyclodecanyl group, a dicyclopentenyl group, a norbornane epoxy group, menthyl group, an isomenthyl group, a neomenthyl group, a tetracyclododecanyl group, and a steroid residue. As the aralkyl group is enumerated one having from 7 to 20 carbon atoms, which may be substituted, and specific examples thereof include a benzyl group, a phenethyl group, and a cumyl group.

Examples of the substituent include a hydroxyl group, a halogen atom (such as fluorine, chlorine, bromine, and iodine), a nitro group, a cyano group, the above-described alkyl group, an alkoxy group (such as a methoxy group, an ethoxy group, a hydroxyethoxy group, a propoxy group, a hydroxypropoxy group, an n-butoxy group, an isobutoxy group, a sec-butoxy group, and a t-butoxy group), an alkoxycarbonyl group (such as a methoxycarbonyl group and an ethoxycarbonyl group), an aralkyl group (such as a benzyl group, a phenethyl group, and a cumyl group), an aralkyloxy group, an acyl group (such as a formyl group, an acetyl group, a butyryl group, a benzoyl group, a cyanamyl group, and a valeryl group), an acyloxy group (such as a butyryloxy group), the above-described alkenyl group, an alkenyloxy group (such as a vinyloxy group, a propenyloxy group, an allyloxy group, and a butenyloxy group), the above-described aryl group, an aryloxy group (such as a phenoxy group), and an aryloxycarbonyl group (such as a benzoyloxy group).

As the lactone group are enumerated the following structures.

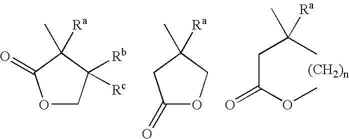

In the formulae, R^{a}, R^{b}, and R^{c} each independently represents a hydrogen atom or an alkyl group having from 1 to 4 carbon atoms, and n represents an integer of from 2 to 4.

In the case where ArF excimer laser beams are used as the exposure source, it is preferred to use a group represented by —C (═O)—X₁—R₀ as the group that is decomposed by the action of an acid. Here, examples of R₀ include a tertiary alkyl group (such as a t-butyl group and a t-amyl group), an isobornyl group, a 1-alkoxyethyl group (such as a 1-ethoxyethyl group, a 1-butoxyethyl group, a 1-isobutoxyethyl group, and a 1-cyclohexyloxyethyl group), an alkoxymethyl group (such as a 1-methoxymethyl group and a 1-ethoxymethyl group), a tetrahydropyranyl group, a tetrahydrofuranyl group, a trialkylsilyl-group, a 3-oxocyclohexyl group, and the above-described lactone group. X₁ represents an oxygen atom or a sulfur atom, and preferably an oxygen atom.

Especially, it is preferred that the acid-decomposable resin contains a repeating unit having an acid-decomposable group represented by any one of the following general formulae (pI) to (pV). By containing this repeating unit, the image forming properties and the resistance to dry etching are enhanced.

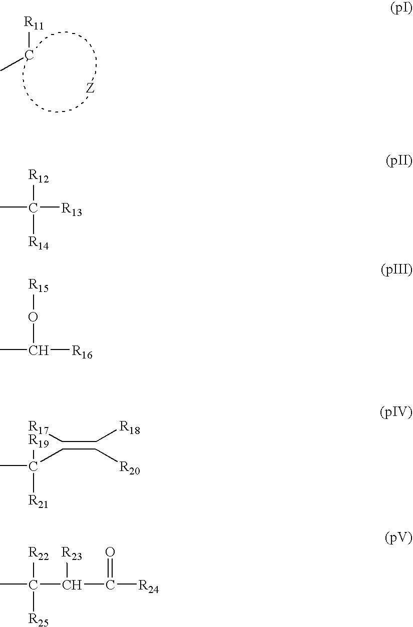

In the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a linear or branched alkyl group or an alicyclic hydrocarbon group, each having from 1 to 4 carbon atoms, provided that at least one of R₁₇ to R₂₁ represents an alicyclic hydrocarbon atom and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

In the general formulae (pI) to (pV), the alkyl group represented by R₁₂ to R₂₅ is a linear, branched alkyl group having from 1 to 4 carbon atoms, which may be substituted or unsubstituted. Examples of the alkyl group include a methyl group, an ethyl group, an n-propyl group, an isopropyl group, an n-butyl group, an isobutyl group, a sec-butyl group, and a t-butyl group.

Examples of the substituent of the alkyl group include an alkoxy group having from 1 to 4 carbon atoms, a halogen atom (such as a fluorine atom, a chlorine atom, a bromine atom, and an iodine atom), an acyl group, an acyloxy group, a cyano group, a hydroxyl group, a carboxy group, an alkoxycarbonyl group, and a nitro group.

The alicyclic hydrocarbon group represented by R₁₁ to R₂₅ and the alicyclic hydrocarbon group formed by Z together with the carbon atoms may be monocyclic or polycyclic. Specifically, the alicyclic hydrocarbon group is a group having a monocyclic, bicyclic, tricyclic or tetracyclic structure having 5 or more carbon atoms, preferably one having from 6 to 30 carbon atoms, and particularly preferably one having from 7 to 25 carbon atoms. The alicyclic hydrocarbon group may be substituted.

Examples of the structure of the alicyclic moiety of the alicyclic hydrocarbon group will be described below.

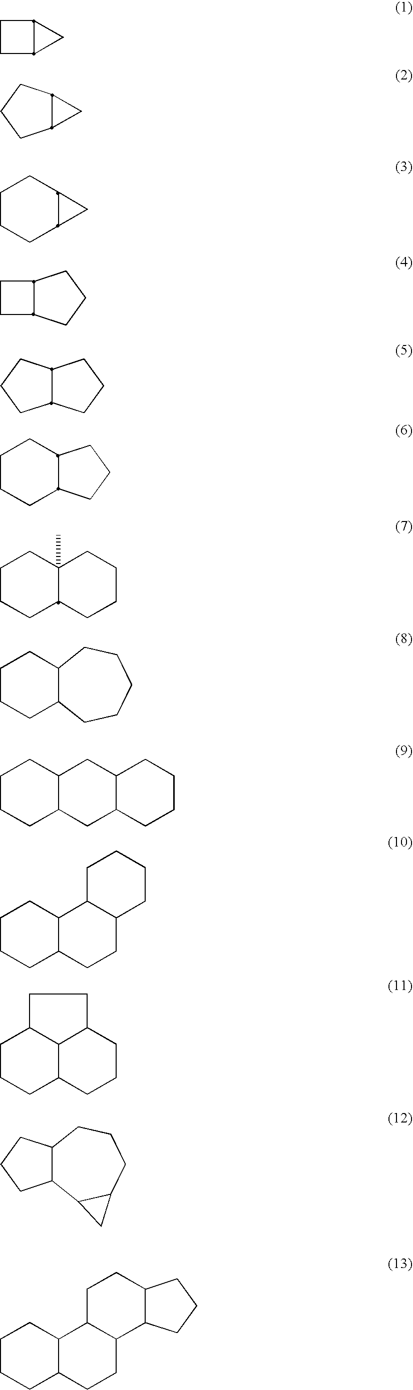

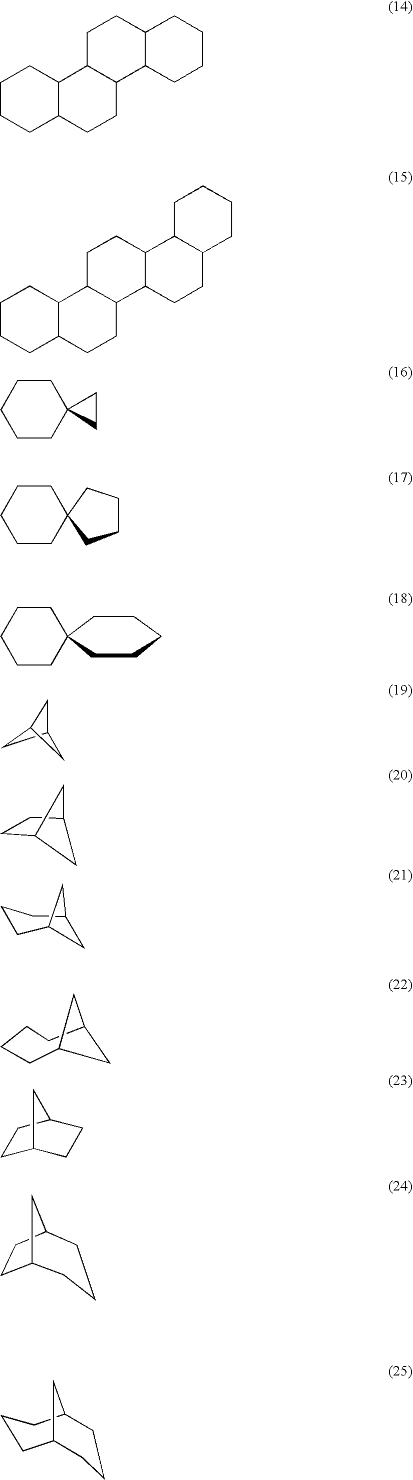

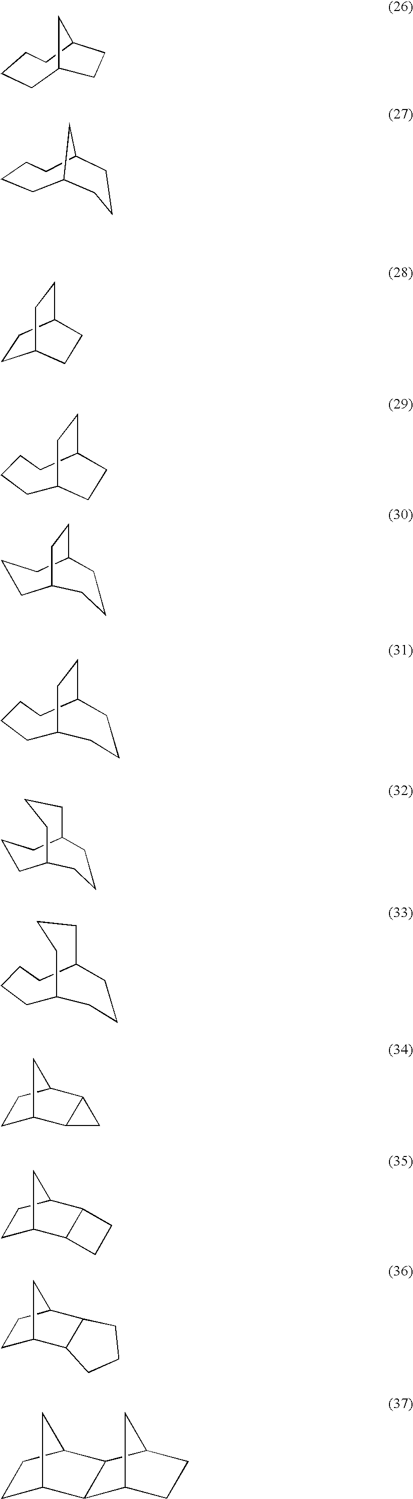

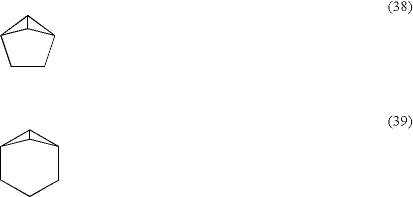

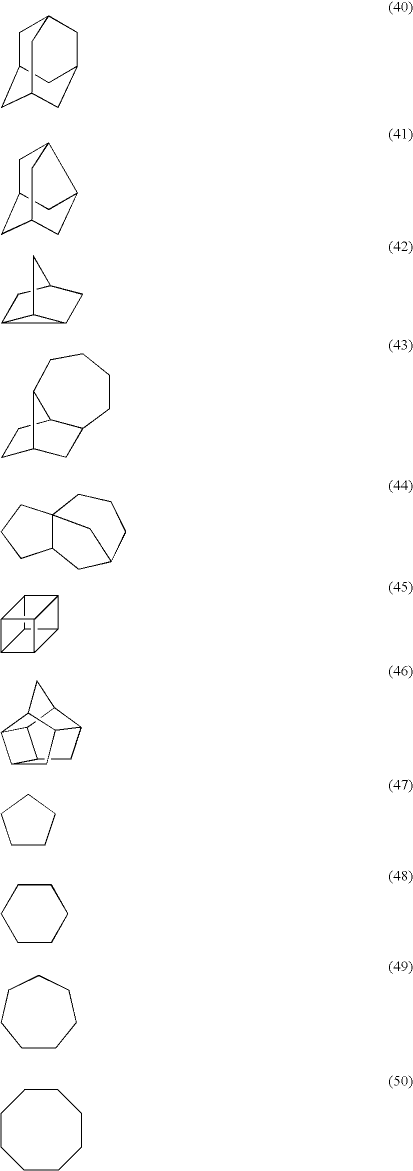

In the present invention, preferred examples of the alicyclic moiety include an adamntyl group, a noradamntyl group, a decalin residue, a tricyclodecanyl group, a tetracyclododecanyl group, a norbornyl group, a cedrol group, a cyclohexyl group, a cycloheptyl group, a cyclooctyl group, a cyclodecanyl group, and a cyclododecanyl group, with an admantyl group, a decalin residue, a norbonyl group, a cedrol group, a cyclohexyl group, a cycloheptyl group, a cyclooctyl group, a cyclodecanyl group, a cyclododecanyl group, and a tricyclodecanyl group being more preferred.

Examples of the alicyclic hydrocarbon group include an alkyl group, a substituted alkyl group, a halogen atom, a hydroxyl group, an alkoxy group, a carboxyl group, and an alkoxycarbonyl group.

Examples of the alkyl group include a lower alkyl group such as a methyl group, an ethyl group, a propyl group, an isopropyl group, and a butyl group, with a methyl group, an ethyl group, a propyl group, and an isopropyl group being more preferred.

Examples of the substituent of the substituted alkyl group include a hydroxyl group, a halogen atom, and an alkoxy group.

Examples of the alkoxy group include ones having from 1 to 4 carbon atoms such as a methoxy group, an ethoxy group, a propoxy group, and a butoxy group.

Specific examples of the monomer having a repeating unit represented by any one of the foregoing general formulae (pI) to (pV) will be described below.

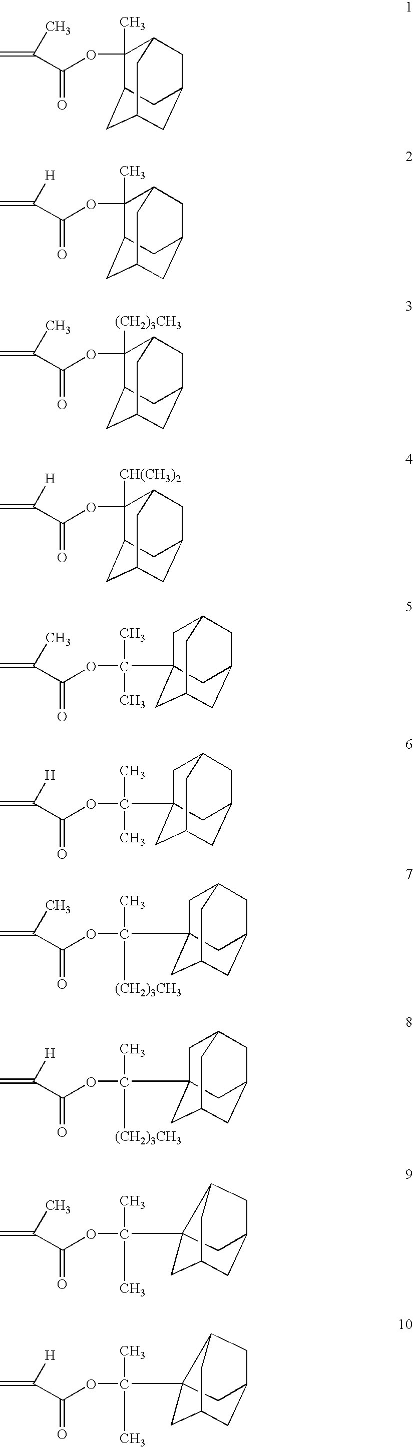

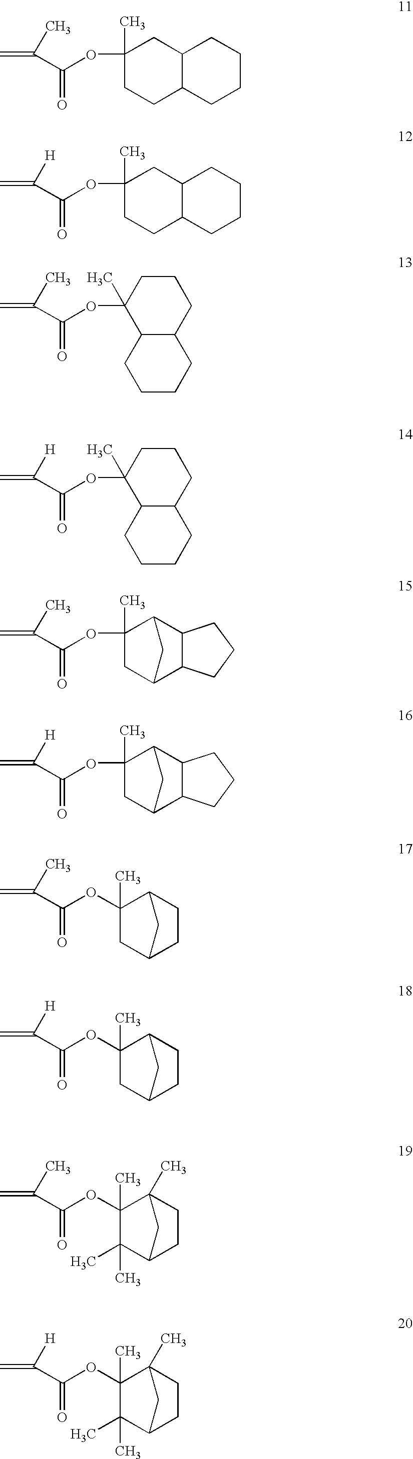

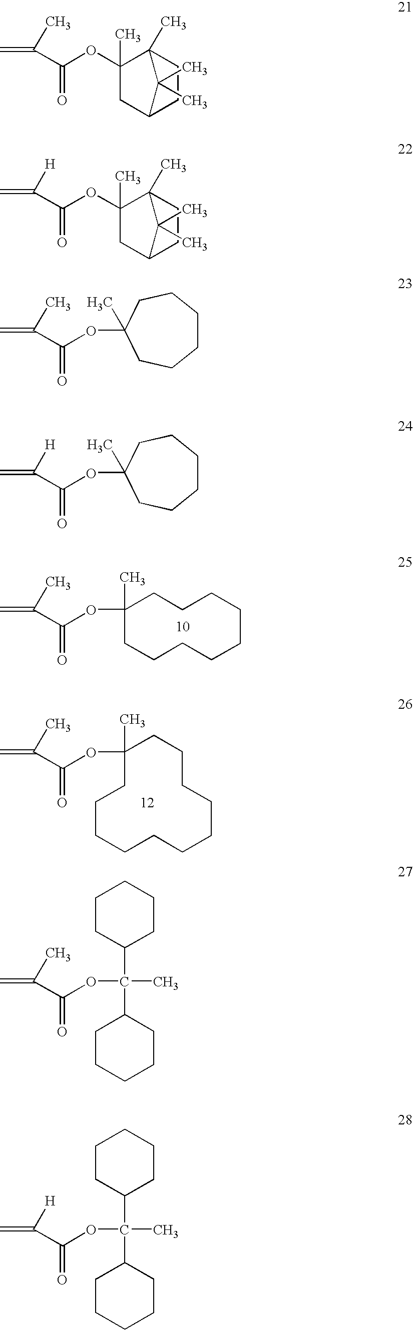

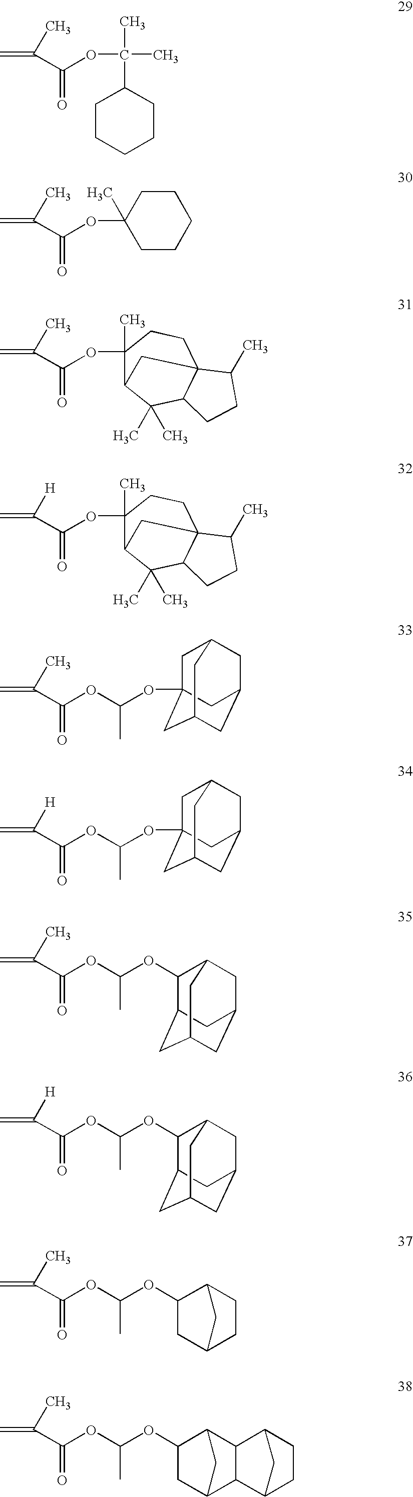

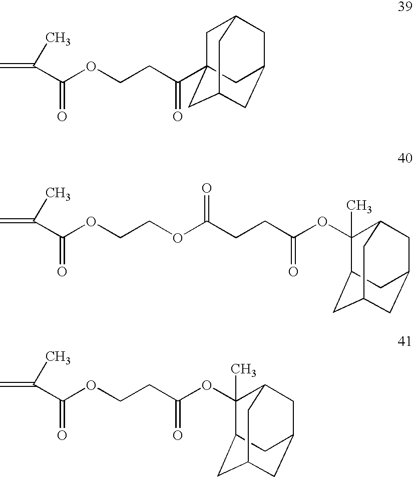

From the standpoint of enhancing the contact hole resolution and the defocus latitude, it is preferred to contain a repeating unit having a lactone residue. From the standpoint of reducing the development defect, it is preferred to contain a repeating unit having an alicyclic lactone residue.

The alicyclic lactone as referred to herein means a structure in which a cyclic hydrocarbon group is condensed with a lactone ring, or a structure in which one of cycloalkane rings of a polycyclic hydrocarbon group (cyclic hydrocarbon ring comprising a combination of two or more cycloalkane rings) is substituted with a lactone ring.

As the lactone residue is enumerated (a1) butyrolactone; and as the alicyclic lactone are enumerated (a2) norbornane lactone, (a3) cyclohexane lactone, and (a4) adamantane lactone.

As the repeating unit (a1) having a lactone residue can be enumerated a repeating unit represented by the following general formula (BL).

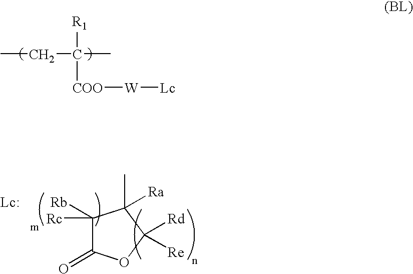

In the general formula (BL), R₁ represents a hydrogen atom or a methyl group; W represents a single group or a combination of two or more groups selected from the group consisting of a simple bond, an alkylene group, an ether group, a thioether group, a carbonyl group, and an ester group; Ra, Rb, Rc, Rd, and Re each independently represents a hydrogen atom or an alkyl group having from 1 to 4 carbon atoms; m and n each independently represents an integer of from 0 to 3; and (m+n) is from 2 to 6.

In the general formula (BL), examples of the alkyl group having from 1 to 4 carbon atoms, represented by Ra to Re, include a methyl group, an ethyl group, a propyl group, an isopropyl group, an n-butyl group, an isobutyl group, a sec-butyl group, and a t-butyl group.

As the alkylene group represented by W is enumerated a group represented by the following general formula.

—[C(Rf)(Rg)]ᵣ—

In the formula, Rf and Rg, which may be the same or different, each independently represents a hydrogen atom, an alkyl group, a substituted alkyl group, a halogen atom, a hydroxyl group, or an alkoxy group. As the alkyl group is preferable a lower alkyl group such as a methyl group, an ethyl group, a propyl group, an isopropyl group, and a butyl group, with a methyl group, an ethyl group, a propyl group, and an isopropyl group being more preferred. Examples of the substituent of the substituted alkyl group include a hydroxyl group, a halogen atom, and an alkoxy group. Examples of the alkoxy group include ones having from 1 to 4 carbon atoms, such as a methoxy group, an ethoxy group, a propoxy group, and a butoxy group. Examples of the halogen atom include a chlorine atom, a bromine atom, a fluorine atom, and an iodine atom. r represents an integer of from 1 to 10.

Examples of the substituent of the alkyl group include a carboxyl group, an acyloxy group, a cyano group, an alkyl group, a substituted alkyl group, a halogen atom, a hydroxyl group, an alkoxy group, a substituted alkoxy group, an acetylamide group, an alkoxycarbonyl group, and an acyl group.

Examples of the alkyl group include a lower alkyl group such as a methyl group, an ethyl group, a propyl group, an isopropyl group, a butyl group, a cyclopropyl group, a cyclobutyl group, and a cyclopentyl group. Examples of the substituent of the substituted alkyl group include a hydroxyl group, a halogen atom, and an alkoxy group. Examples of the substituent of the substituted alkoxy group include an alkoxy group. Examples of the alkoxy group include ones having from 1 to 4 carbon atoms, such as a methoxy group, an ethoxy group, a propoxy group, and a butoxy group. Examples of the acyloxy group include an acetoxy group. Examples of the halogen atom include a chlorine atom, a bromine atom, a fluorine atom, and an iodine atom.

Specific examples of the monomer having the repeating unit represented by the general formula (BL) will be described below, but it should not be construed that the present invention is limited thereto.

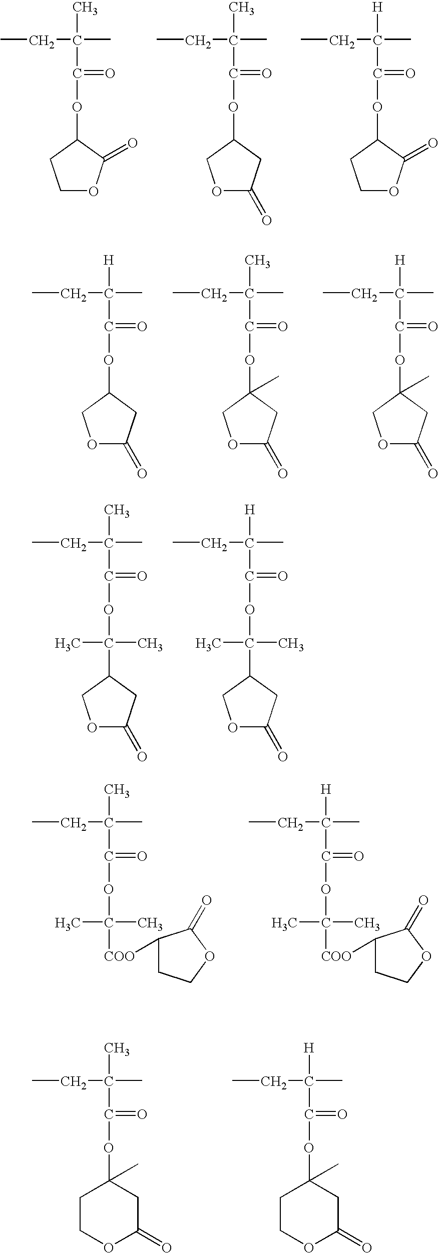

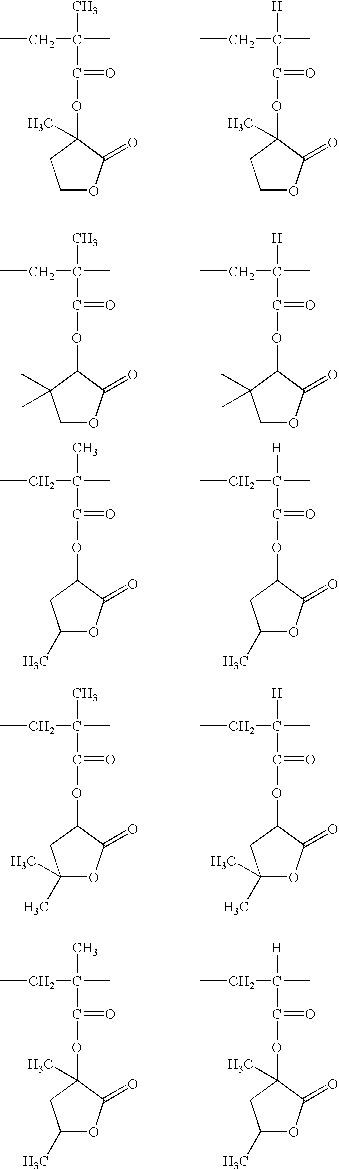

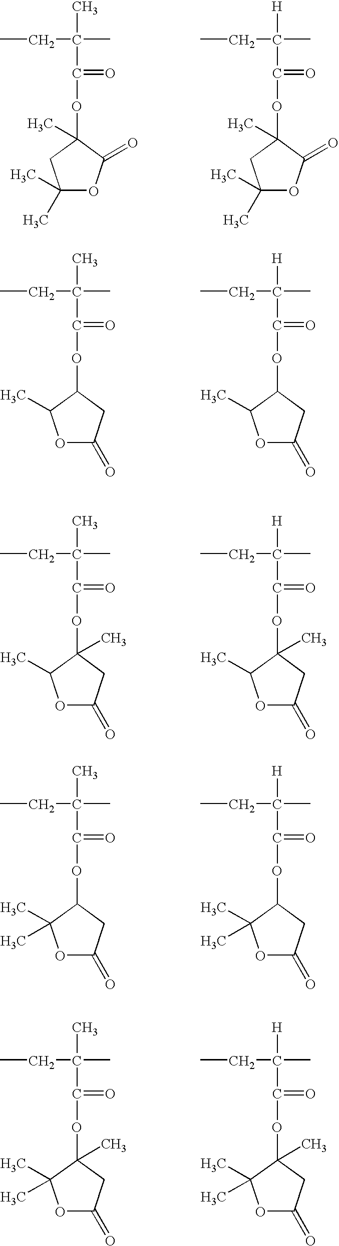

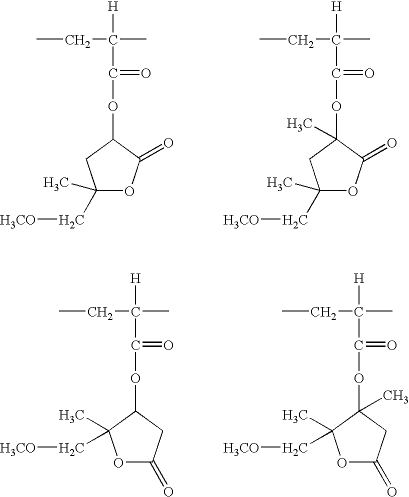

In the acid-decomposable resin of the present invention, as the monomer of norbornane lactone (a2) and the monomer of cyclohexane lactone (a3) are preferable those having a repeating unit having each of groups represented by the following general formulae (V-1) to (V-2) and (V-3) to (V-4).

As the repeating unit having the norbornane lactone (a2) are enumerated repeating units having a group represented by the following general formula (V-1) or (V-2).

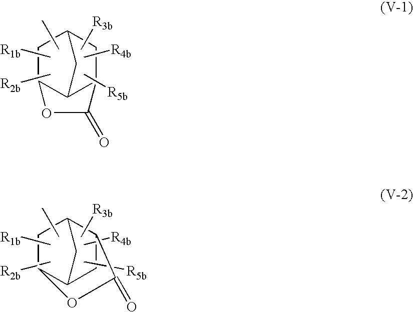

In the general formulae (V-1) to (V-2), R_{1b} to R_{5b} each independently represents a hydrogen atom, an optionally substituted alkyl group, an optionally substituted cycloalkyl group, or an optionally substituted alkenyl group; and two of R_{1b} to R_{5b} may be taken together to form a ring.

As the repeating unit having the norbornane lactone (a3) are enumerated repeating units having a group represented by the following general formula (V-3) or (V-4).

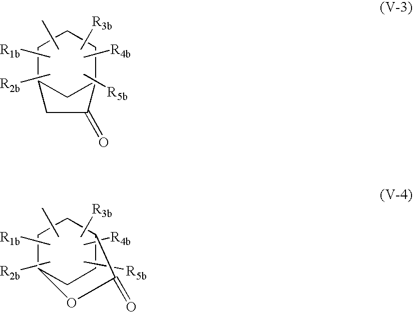

In the general formulae (V-3) to (V-4), R_{1b} to R_{5b} each independently represents a hydrogen atom, an optionally substituted alkyl group, an optionally substituted cycloalkyl group, or an optionally substituted alkenyl group; and two of R_{1b} to R_{5b} may be taken together to form a ring.

In the general formulae (V-1) to (V-4), examples of the alkyl group represented by R_{1b} to R_{5b} include a linear or branched alkyl group, which may be substituted.

The linear or branched alkyl group is preferably a linear or branched alkyl group having from 1 to 12 carbon atoms, and more preferably a linear or branched alkyl group having from 1 to 10 carbon atoms, with a methyl group, an ethyl group, a propyl group, an isopropyl group, an n-butyl group, an isobutyl group, a sec-butyl group, a t-butyl group, a pentyl group, a hexyl group, a heptyl group, an octyl group, a nonyl group, and a decyl group being most preferred.

As the cycloalkyl group represented by R_{1b} to R_{5b} are preferable ones having from 3 to 8 carbon atoms, such as a cyclopropyl group, a cyclopentyl group, a cyclohexyl group, a cycloheptyl group, and a cyclooctyl group.

As the alkenyl group represented by R_{1b} to R_{5b} are preferable ones having from 2 to 6 carbon atoms, such as a vinyl group, a propenyl group, a butenyl group, and a hexenyl group.

As the ring formed when two of R_{1b} to R_{5b} are taken together are enumerated from 3- to 8-membered rings such as a cyclopropane ring, a cyclobutane ring, a cyclopentane ring, a cyclohexane ring, and a cyclooctane ring.

In the general formulae (V-1) to (V-4), R_{1b} to R_{5b} may be each connected to any of the carbon atoms constituting the cyclic skeleton.

Examples of the substituent, with which the foregoing alkyl group, cycloalkyl group or alkenyl group may be substituted, include an alkoxy group having from 1 to 4 carbon atoms, a halogen atom (such as a fluorine atom, a chlorine atom, a bromine atom, and an iodine atom), an acyl group having from 2 to 5 carbon atoms, an acyloxy group having from 2 to 5 carbon atoms, a cyano group, a hydroxyl group, a carboxy group, an alkoxycarbonyl group having from 2 to 5 carbon atoms, and a nitro group.

As the repeating unit having each of the groups represented by the general formulae (V-1) to (V-4) can be enumerated a repeating unit represented by the following general formula (AI).

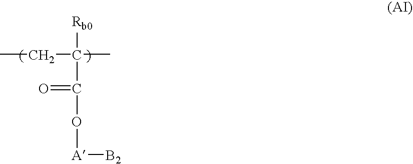

In the general formula (AI), R_{b0} represents a hydrogen atom, a halogen atom, or a substituted or unsubstituted alkyl group having from 1 to 4 carbon atoms. As the preferred substituent, with which the alkyl group represented by R_{b0} may be substituted, are enumerated those enumerated above as the preferred substituent, with which the alkyl group represented by R_{1b} in the general formulae (V-1) to (V-4) may be substituted.

Examples of the halogen atom represented by R_{b0} include a fluorine atom, a chlorine atom, a bromine atom, and an iodine atom. R_{b0} preferably represents a hydrogen atom.

A′ represents a simple bond, an ether group, an ester group, a carbonyl group, an alkylene group, or a divalent group comprising a combination of these groups.

B₂ represents a group represented by any one of the general formulae (V-1) to (V-4). In A′, examples of the divalent group comprising a combination are as follows.

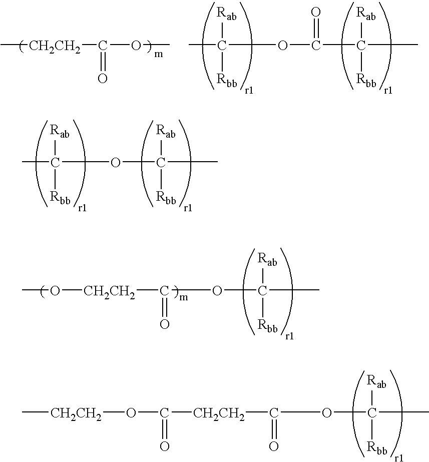

In the above formulae, R_{ab} and R_{bb}, which may be the same or different, each independently represents a hydrogen atom, an alkyl group, a substituted alkyl group, a halogen atom, a hydroxyl group, or an alkoxy group.

As the alkyl group is preferable a lower alkyl group such as a methyl group, an ethyl group, a propyl group, an isopropyl group, and a butyl group, with a methyl group, an ethyl group, a propyl group, and an isopropyl group being more preferred. Examples of the substituent of the substituted alkyl group include a hydroxyl group, a halogen atom, and an alkoxy group having from 1 to 4 carbon atoms.

As the alkoxy group can be enumerated ones having from 1 to 4 carbon atoms, such as a methoxy group, an ethoxy group, a propoxy group, and a butoxy group. Examples of the halogen atom include a chlorine atom, a bromine atom, a fluorine atom, and an iodine atom. r represents an integer of from 1 to 10, and preferably from 1 to 4. m represents an integer of from 1 to 3, and preferably 1 or 2.

Specific examples of the repeating unit represented by the general formula (AI) will be described below, but it should not be construed that the present invention is limited thereto.

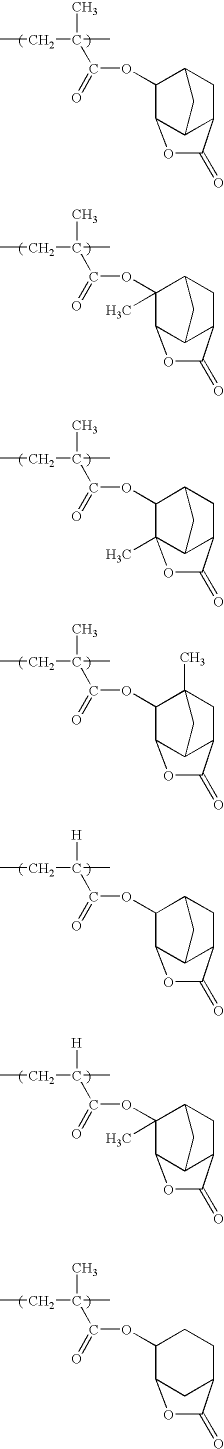

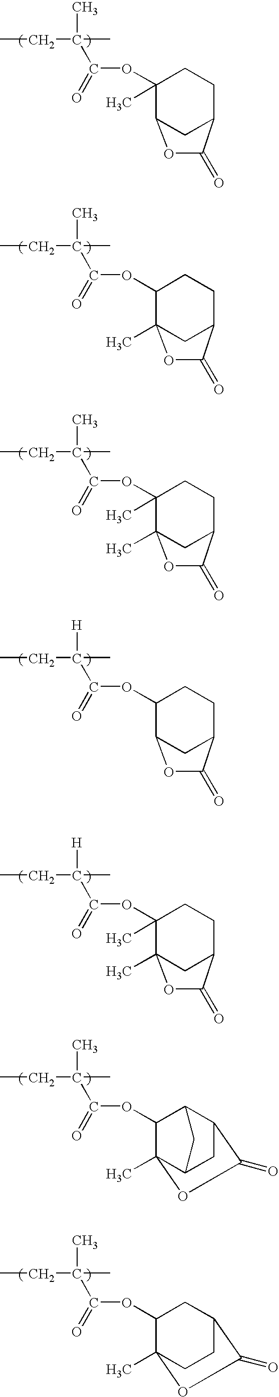

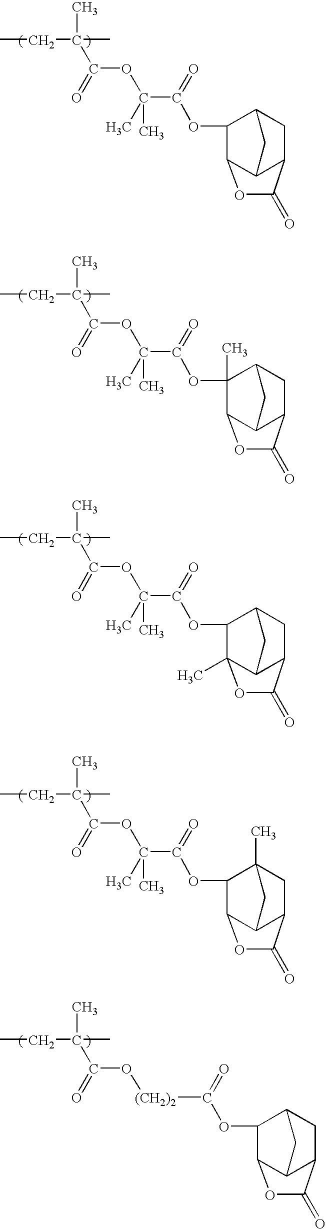

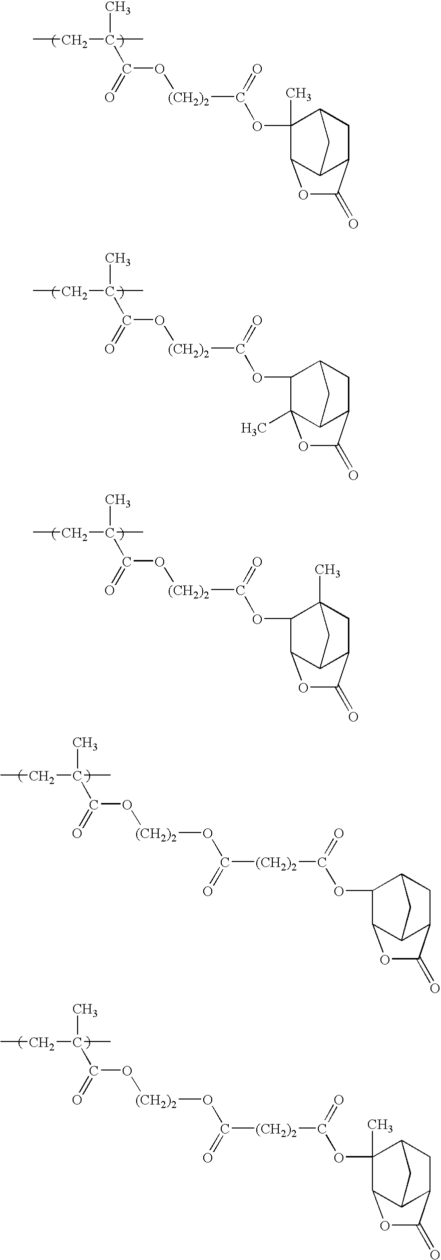

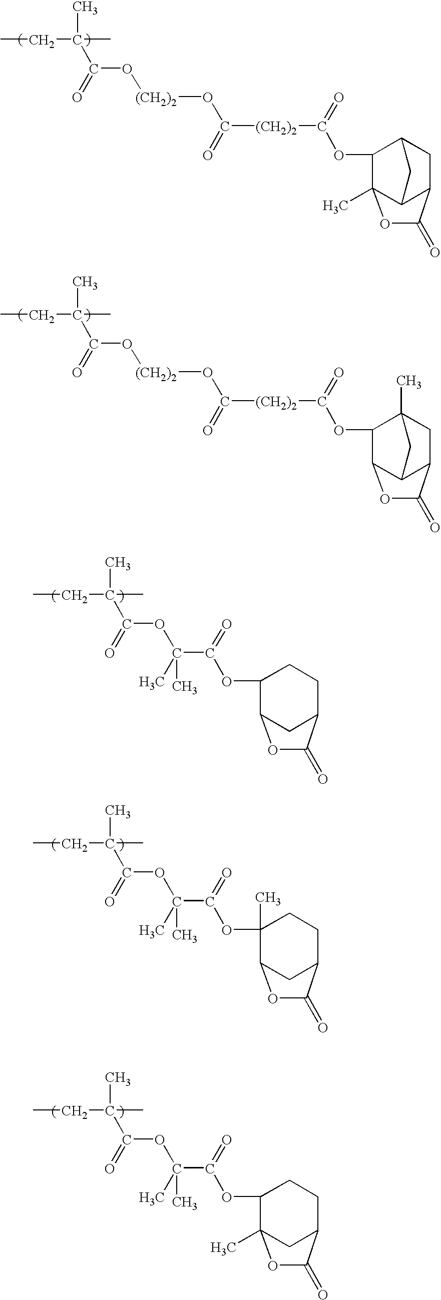

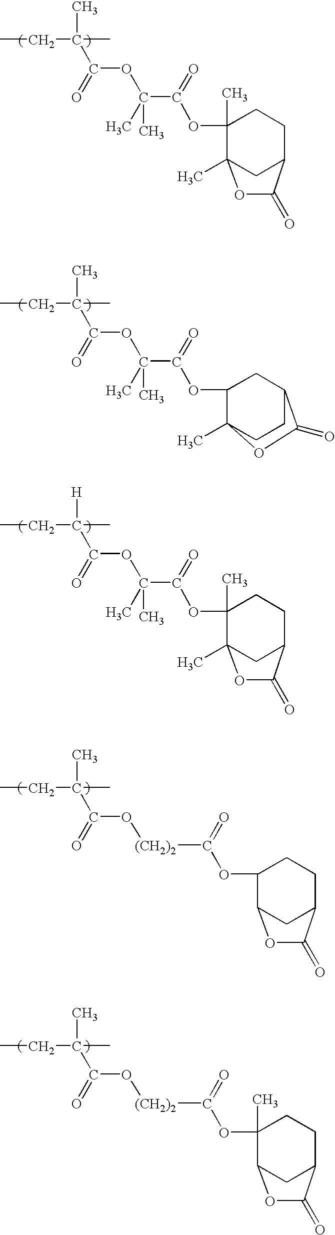

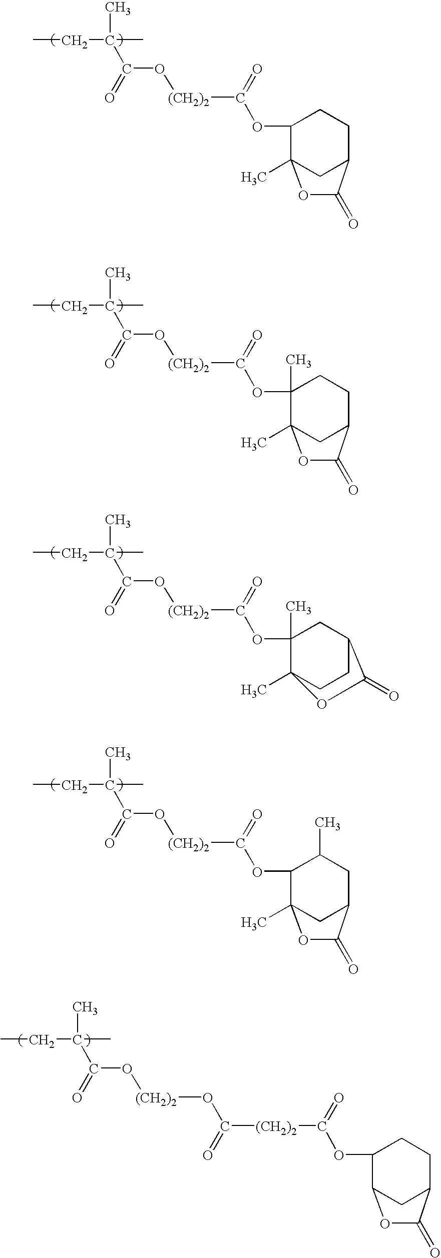

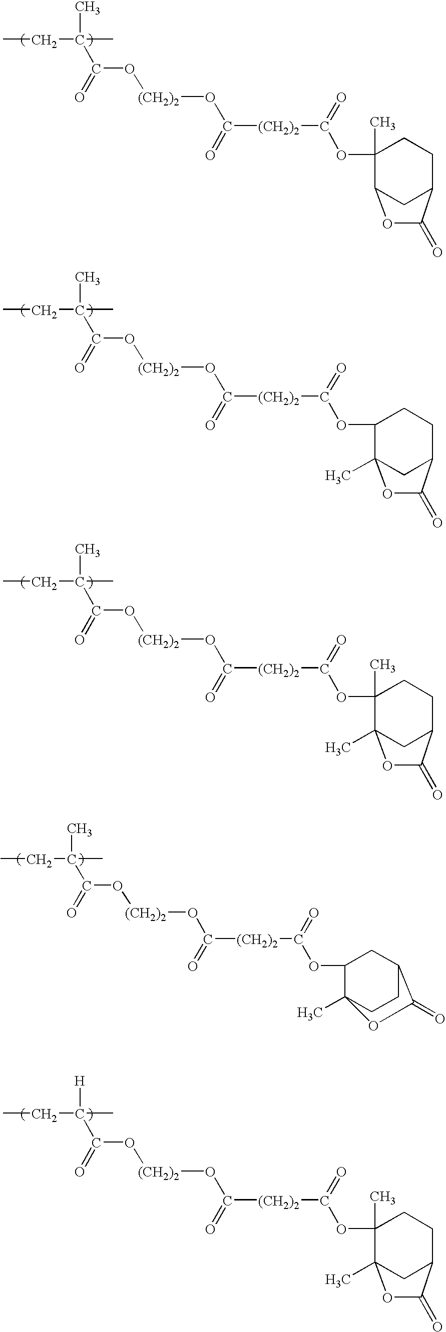

As the adamantane lactone (a4) is preferable a repeating unit represented by the following general formula (AL).

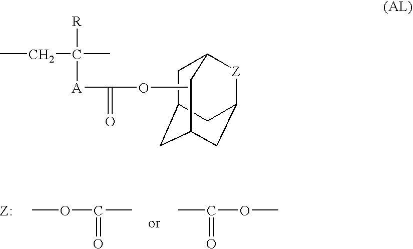

In the general formula (AL), A represents a single group or a combination of two or more groups selected from the group consisting of a simple bond, an alkylene group, a cycloalkylene group, an ether group, a thioether group, a carbonyl group, and an ester group; and R represents a hydrogen atom, an alkyl group having from 1 to 4 carbon atoms, a cyano group, or a halogen atom.

In the general formula (AL), as the alkylene group represented by A is enumerated a group represented by the following general formula.

—[C(Rnf)(Rng)]ᵣ—

In the formula, Rnf and Rng, which may be the same or different, each independently represents a hydrogen atom, an alkyl group, a substituted alkyl group, a halogen atom, a hydroxyl group, or an alkoxy group. As the alkyl group is preferable a lower alkyl group such as a methyl group, an ethyl group, a propyl group, an isopropyl group, and a butyl group, with a methyl group, an ethyl group, a propyl group, and an isopropyl group being more preferred. Examples of the substituent of the substituted alkyl group include a hydroxyl group, a halogen atom, and an alkoxy group. Examples of the alkoxy group include ones having from 1 to 4 carbon atoms, such as a methoxy group, an ethoxy group, a propoxy group, and a butoxy group. Examples of the halogen atom include a chlorine atom, a bromine atom, a fluorine atom, and an iodine atom. r represents an integer of from 1 to 10.

In the general formula (AL), examples of the cycloalkylene group represented by A include ones having from 3 to 10 carbon atoms, such as a cyclopentylene group, a cyclohexylene group, and a cyclooctylene group.

The bridged alicyclic ring containing Z may be substituted. Examples of the substituent include a halogen atom, an alkoxy group (preferably one having from 1 to 4 carbon atoms), an alkoxycarbonyl group (preferably one having from 1 to 5 carbon atoms), an acyl group (such as a formyl group and a benzoyl group), an acyloxy group (such as a propylcarbonyloxy group and a benzoyloxy group), an alkyl group (preferably one having from 1 to 4 carbon atoms), a carboxyl group, a hydroxyl group, and an alkylsulfonylsulfamoyl group (such as —CONHSO₂CH₃). The alkyl group as the substituent may be further substituted with, for example, a hydroxyl group, a halogen atom, or an alkoxy group (preferably one having from 1 to 4 carbon atoms).

In the general formula (AL), the oxygen atom of the ester group binding to A may be bound at any position of the carbon atoms constituting the bridged alicyclic ring structure containing Z.

Specific examples of the repeating unit represented by the general formula (AL) will be described below, but it should not be construed that the present invention is limited thereto.

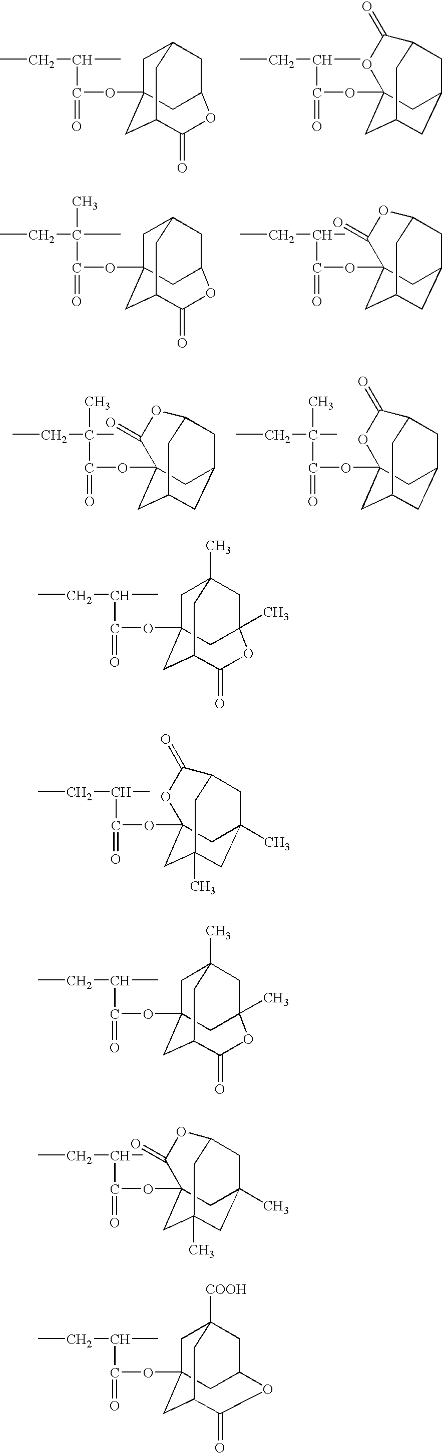

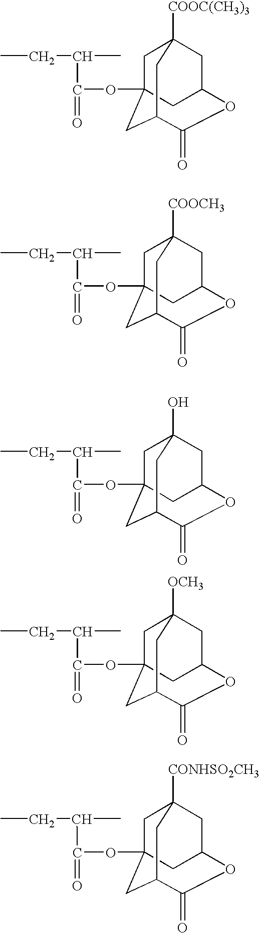

Further, in the acid-decomposable resin of the present invention, especially from the standpoint of improving the edge roughness, it is preferred to contain a repeating unit represented by the following general formula (III).

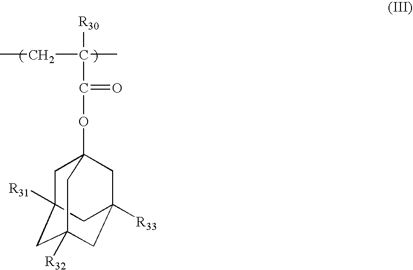

In the general formula (III), R₃₀ represents a hydrogen atom or a methyl group; and R₃₁ to R₃₃ each independently represents a hydrogen atom, a hydroxyl group, or an alkyl group, provided that at least one of R₃₁ to R₃₃ represents a hydroxyl group.

From the standpoint that a broad exposure margin is obtained during the formation of a hole pattern by under exposure, it is more preferred that in the repeating unit represented by the general formula (III), two of R₃₁ to R₃₃ represent a hydroxyl group.

Specific examples of the repeating unit represented by the general formula (III) will be described below, but it should not be construed that the present invention is limited thereto.

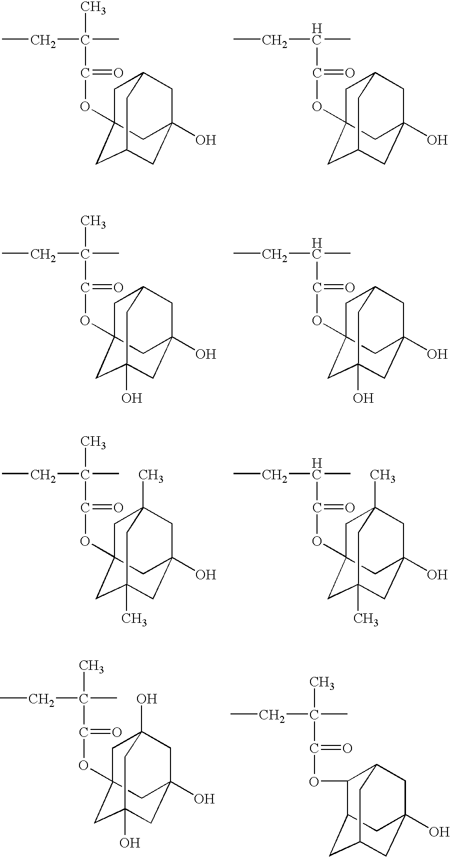

In addition, from the standpoint of enhancing the heat resistance and the etching resistance, it is preferred to contain a repeating unit represented by the following general formula (IV).

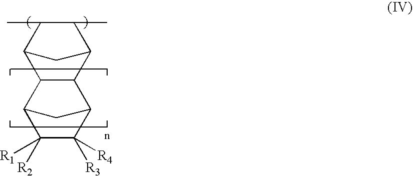

In the general formula (IV), R₁ to R₄ each independently represents a hydrogen atom, a halogen atom, a cyano group, —COOH, an optionally substituted hydrocarbon group, —COOR₅, —C(═O)—X-A-R₆, or a group that is decomposed by the action of an acid; at least two of R₁ to R₄ may be taken together to form a ring; R₅ represents an optionally substituted hydrocarbon group or a lactone residue; R₆ represents a hydrogen atom, —COOH, —COOR₅, —CN, a hydroxyl group, an optionally substituted alkoxy group, an optionally substituted hydrocarbon group, or a lactone residue; X represents an oxygen atom, a sulfur atom, —NHSO₂—, or —NHSO₂NH—; A represents a single group or a combination of two or more groups selected from the group consisting of a simple bond, an alkylene group, a cycloalkylene group, an ether group, a thioether group, a carbonyl group, an ester group, a sulfonamide group, and N-sulfonylamide group; and n represents 0 or 1.

The structure of the group that is decomposed by the action of an acid is represented by —C(═O)—X₁—Rₚ.

In the formula, examples of Rₚ include a tertiary alkyl group (such as a t-butyl group and a t-amyl group), an isobornyl group, a 1-alkoxyethyl group (such as a 1-ethoxyethyl group, a 1-butoxyethyl group, a 1-isobutoxyethyl group, and a 1-cyclohexyloxyethyl group), an alkoxymethyl group (such as a 1-methoxymethyl group and a 1-ethoxymethyl group), a 3-oxoalkyl group, a tetrapyranyl group, a tetrahydrofuranyl group, a trialkylsilyl ester group, a 3-oxocyclohexyl ester group, a 2-methyl-2-adamantyl group, a mevalonic lactone residue, and a 2-(γ-butyrolactonyloxycarbonyl)-2-propyl group; and X₁ represents an oxygen atom, a sulfur atom, —NH—, NHSO₂—, or —NHSO₂NH—.

Examples of the halogen atom represented by R₁ to R₄ include a chlorine atom, a bromine atom, a fluorine atom, and an iodine atom.

As the hydrocarbon group represented by R₁ to R₄, R₅, and R₆ are preferable a linear, branched or cyclic alkyl group and a bridged hydrocarbon group.

The linear or branched alkyl group is preferably a linear or branched alkyl group having from 1 to 10 carbon atoms, more preferably a linear or branched alkyl group having from 1 to 6 carbon atoms, and further preferably a methyl group, an ethyl group, a propyl group, an isopropyl group, an n-butyl group, an isobutyl group, a sec-butyl group, or a t-butyl group.

Examples of the cyclic alkyl group and the bridged hydrocarbon group include a cyclopropyl group, a cyclopentyl group, a cyclohexyl group, an adamantyl group, a 2-methyl-2-adamantyl group, a norbornyl group, a bornyl group, an isobornyl group, a tricyclodecanyl group, a dicyclopentenyl group, a norbornane epoxy group, a menthyl group, an isomenthyl group, a neomenthyl group, and a tetracyclodecanyl group.

Examples of the ring formed when at least two of R₁ to R₄ are taken together include ones having from 5 to 12 carbon atoms, such as a lactone ring, cyclopentene, cyclohexene, cycloheptane, and cyclooctane.

As the alkoxy group represented by R₆ are preferable ones having from 1 to 4 carbon atoms, such as a methoxy group, an ethoxy group, a propoxy group, and a butoxy group.

The foregoing hydrocarbon group and alkoxy group may be further substituted. Examples of the substituent include a hydroxyl group, a carboxyl group, a cyano group, a halogen atom (such as a chlorine atom, a bromine atom, a fluorine atom, and an iodine atom), an alkoxy group (preferably one having from 1 to 4 carbon atoms, such as a methoxy group, an ethoxy group, a propoxy group, and a butoxy group), an acyl group (such as a formyl group and an acetyl group), and an acyloxy group (such as an acetoxy group).

As the alkylene group represented by A is enumerated a group represented by the following general formula.

—[C(Rb)(Rc)]ᵣ—

In the formula, R_{b} and R_{c}, which may be the same or different, each independently represents a hydrogen atom, an alkyl group, a substituted alkyl group, a halogen atom, a hydroxyl group, or an alkoxy group. As the alkyl group is preferable a lower alkyl group such as a methyl group, an ethyl group, a propyl group, an isopropyl group, and a butyl group, with a methyl group, an ethyl group, a propyl group, and an isopropyl group being more preferred. Examples of the substituent of the substituted alkyl group include a hydroxyl group, a halogen atom, and an alkoxy group (preferably one having from 1 to 4 carbon atoms). Examples of the alkoxy group include ones having from 1 to 4 carbon atoms, such as a methoxy group, an ethoxy group, a propoxy group, and a butoxy group. Examples of the halogen atom include a chlorine atom, a bromine atom, a fluorine atom, and an iodine atom. r represents an integer of from 1 to 10.

As the lactone residue represented by R₅ and R₆ can be enumerated by a —Y group represented by any of the following formulae:

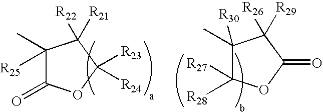

In the general formulae, R₂₁ to R₃₀ each independently represents a hydrogen atom or an alkyl group; and a and b each represents 1 or 2.

Examples of the alkyl group represented by R₂₁ to R₃₀ include a methyl group, an ethyl group, a propyl group, an isopropyl group, and a butyl group.

The alkyl group represented by R₂₁ to R₃₀ may be substituted. Examples of the substituent include a hydroxyl group, a carboxyl group, a cyano group, a halogen atom (such as a chlorine atom, a bromine atom, a fluorine atom, and an iodine atom), an alkoxy group (preferably one having from 1 to 4 carbon atoms, such as a methoxy group, an ethoxy group, a propoxy group, and a butoxy group), an acyl group (preferably one having from 2 to 5 carbon atoms, such as a formyl group and an acetyl group), an acyloxy group (preferably one having from 2 to 5 carbon atoms, such as an acetoxy group), and an aryl group (preferably from 6 to 14 carbon atoms, such as a phenyl group).

Specific examples of the repeating unit represented by the general formula (IV) will be described below, but it should not be construed that the present invention is limited thereto.

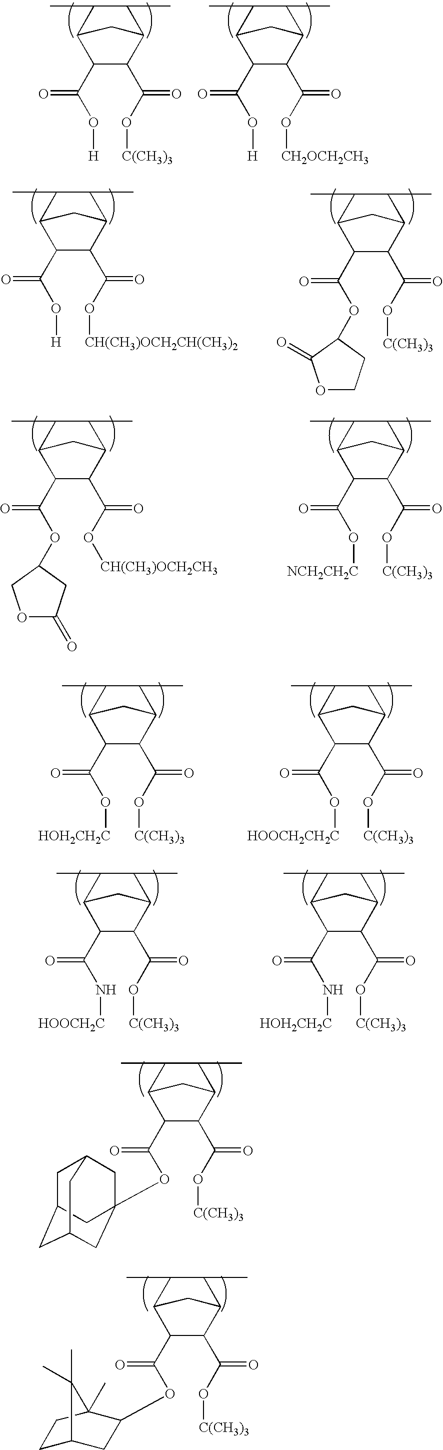

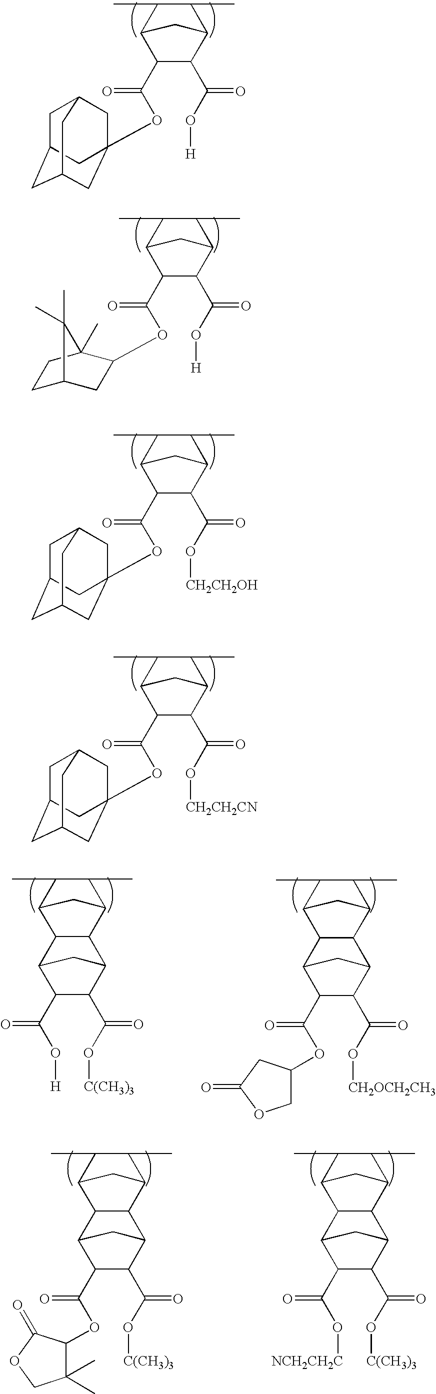

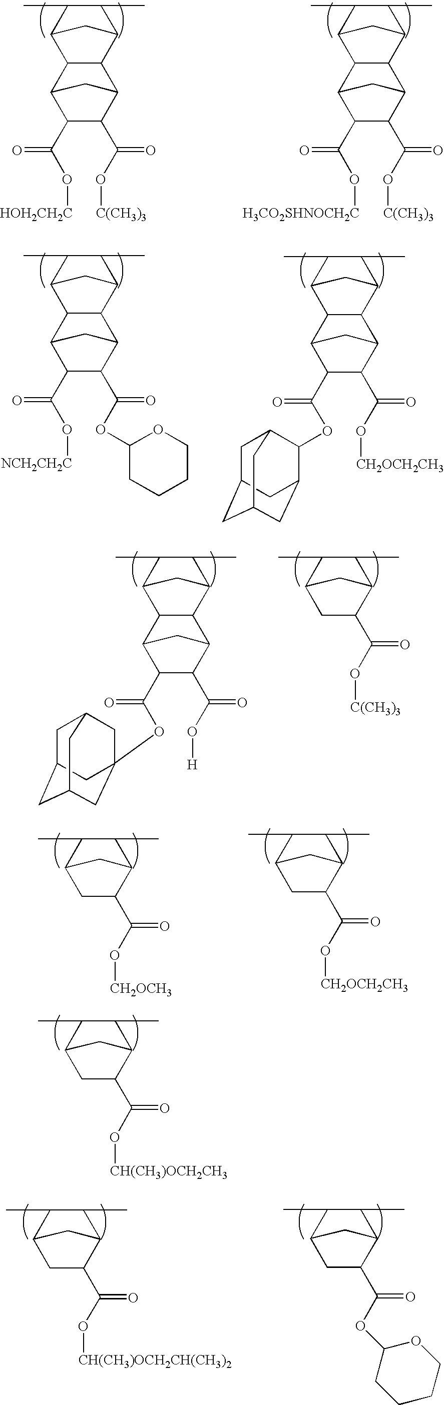

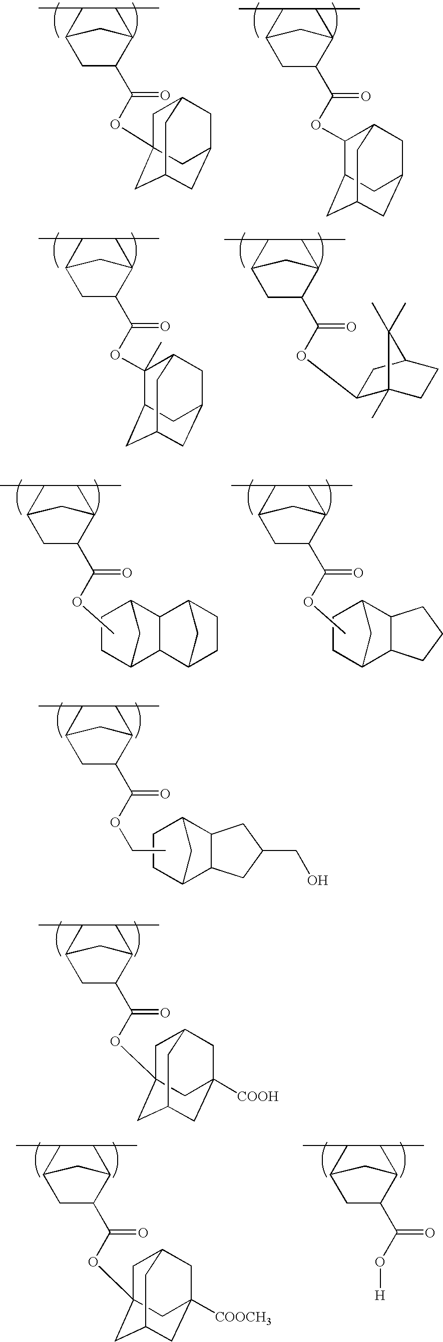

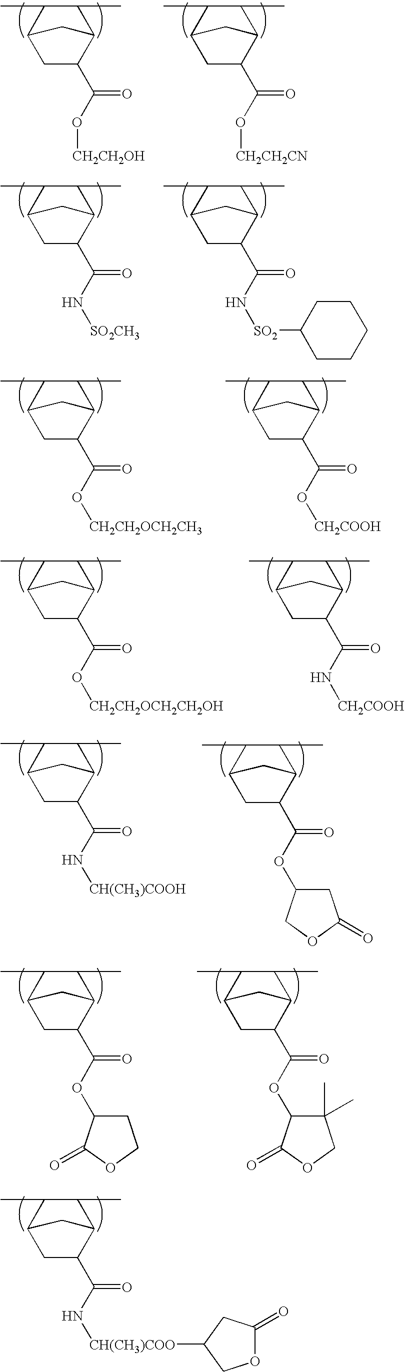

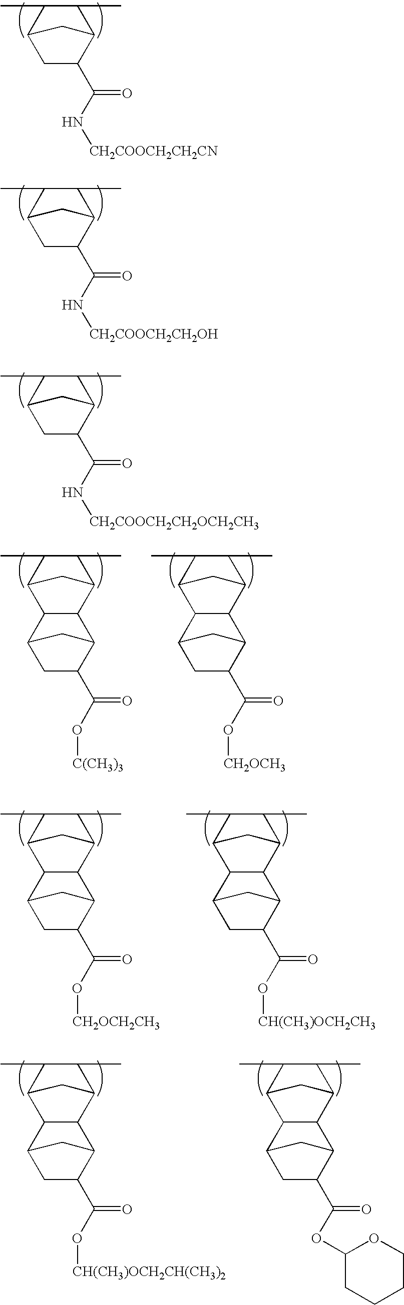

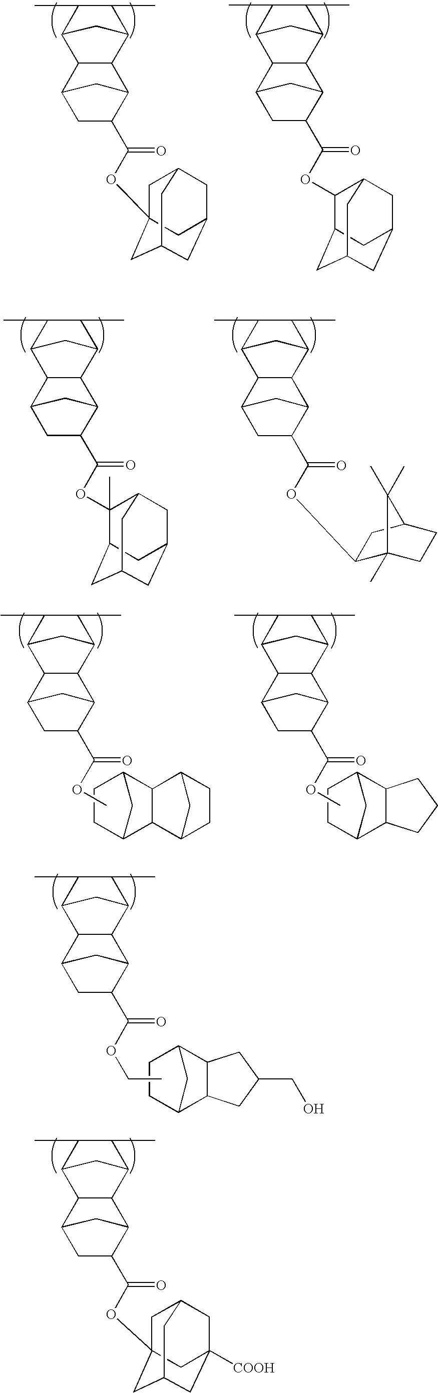

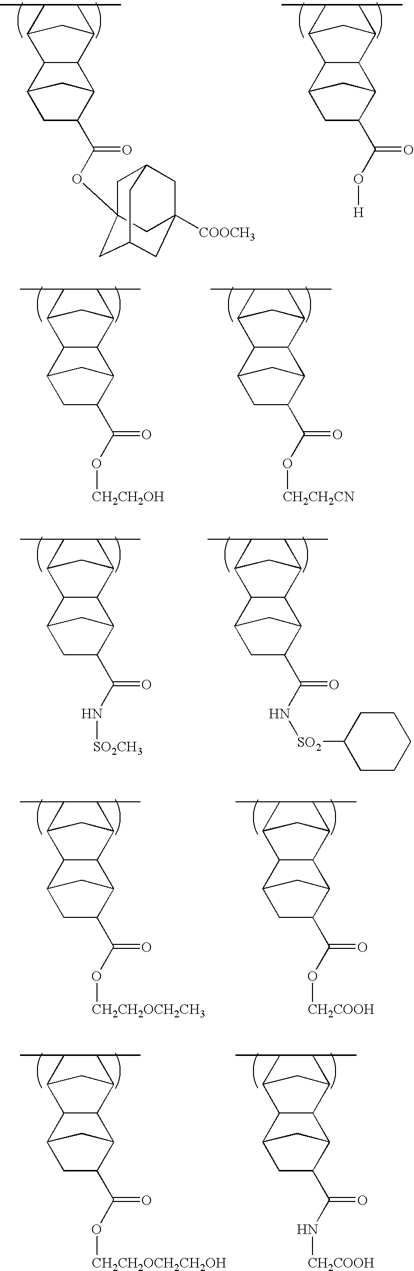

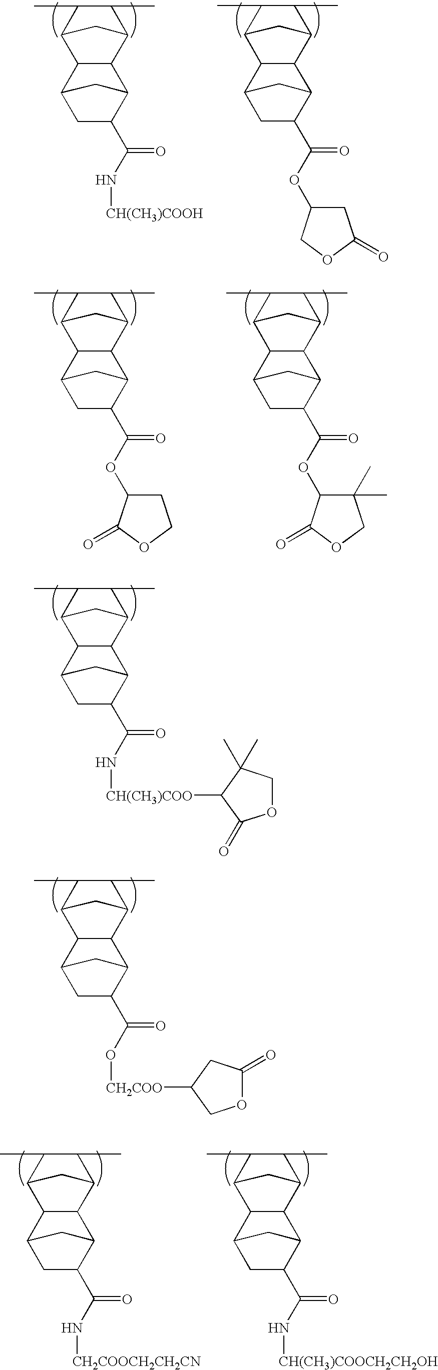

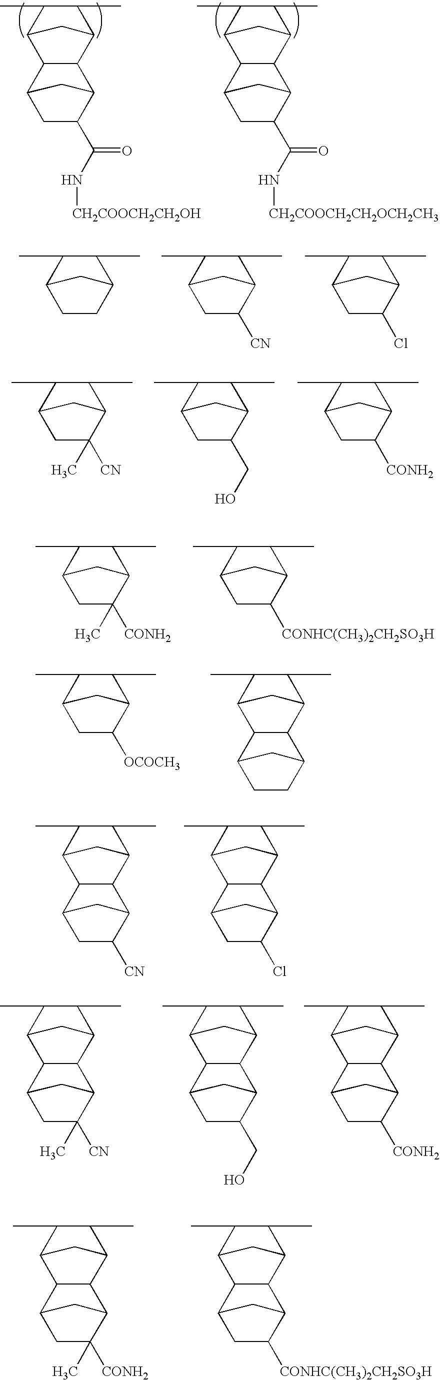

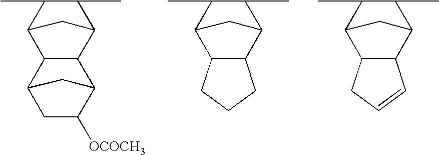

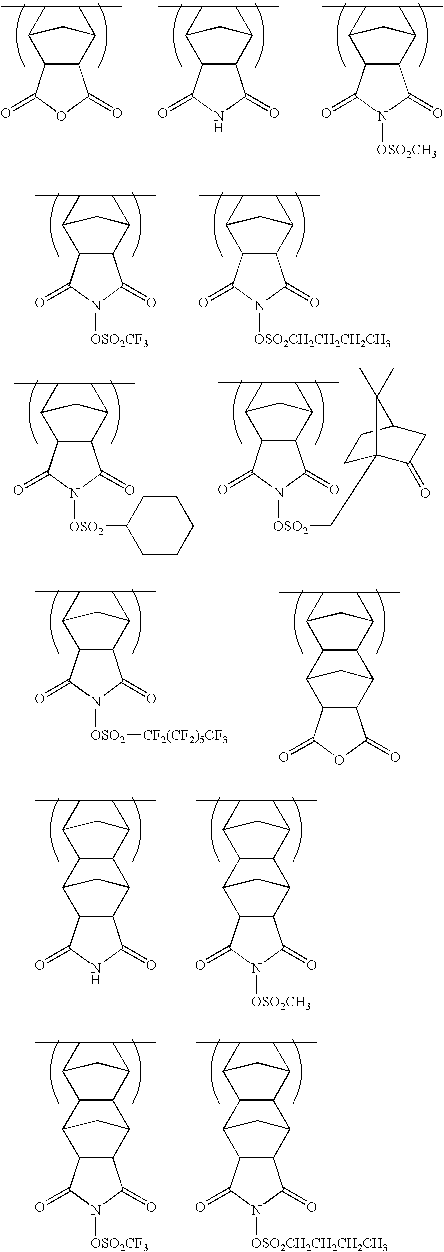

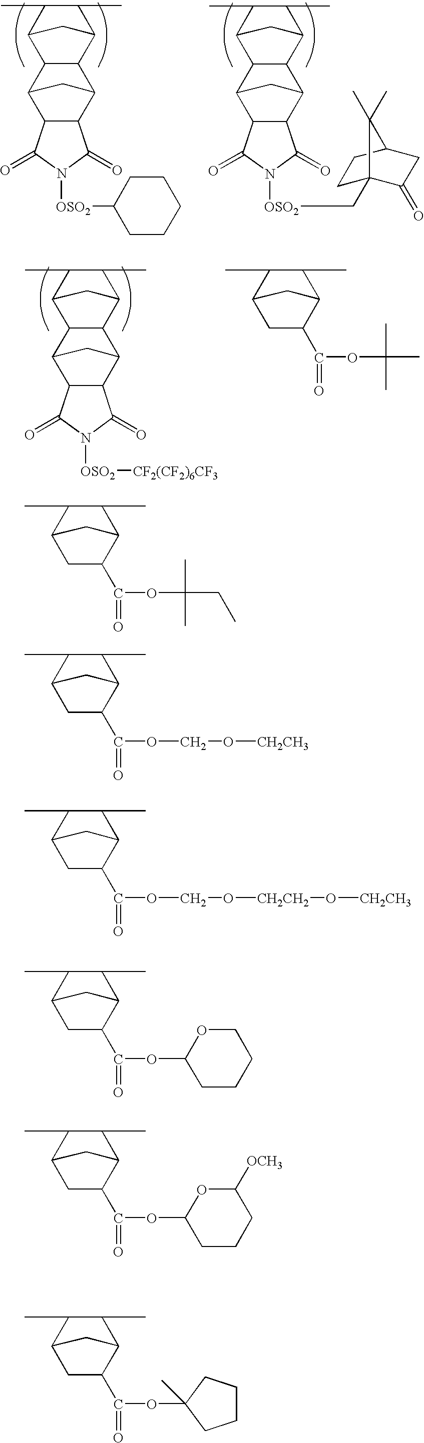

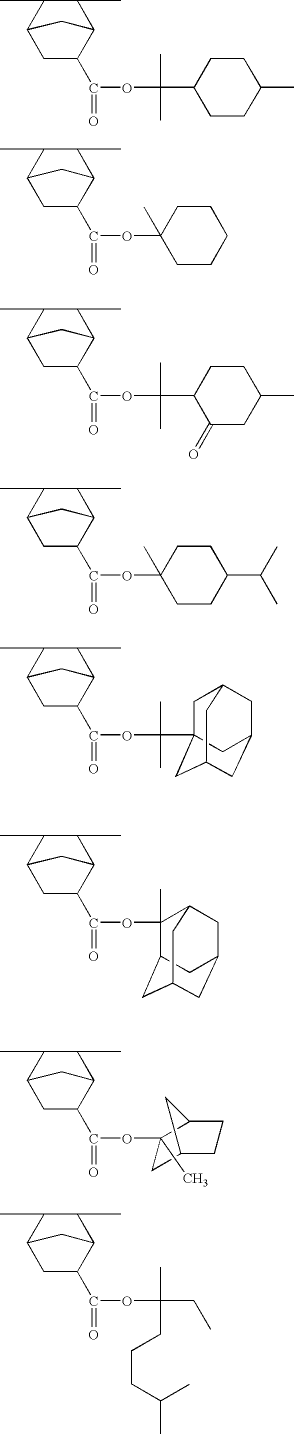

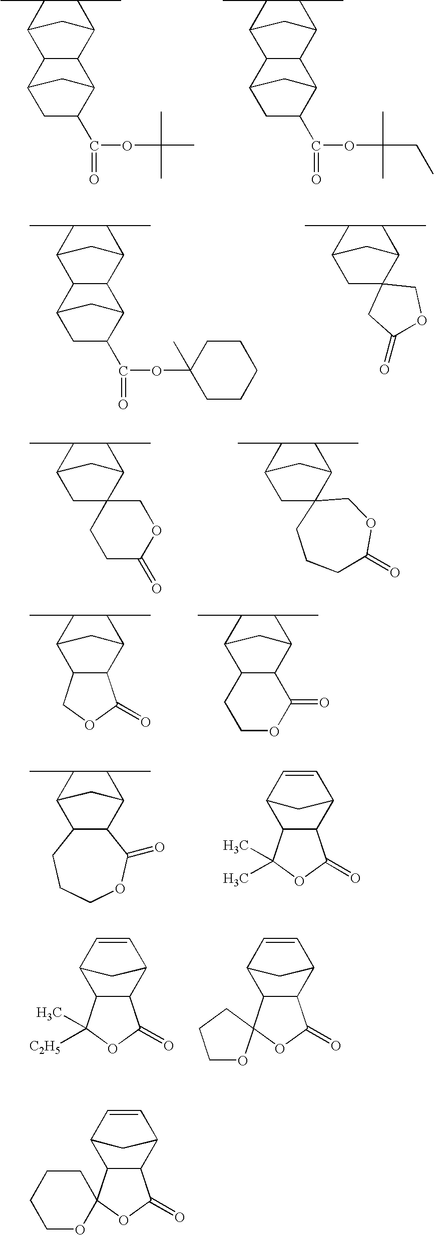

The acid-decomposable resin as the component (B) can contain various repeating structural units other than the foregoing repeating units, for the purposes of enhancing the resistance to dry etching and standard development aptitude, the adhesiveness to substrate and the resist profile, and regulating the general characteristics required for resists, such as resolving power, heat resistance, and sensitivity.

As these repeating structural units, repeating structural units corresponding to the monomers as described below can be enumerated, but it should not be construed that the present invention is limited thereto.

By this, it is possible to finely adjust the performance required for the acid-decomposable resin, especially

(1) solubility in coating solvent,

(2) film forming properties (glass transition point),

(3) alkali-development properties,

(4) film thickness reduction (hydrophilicity, hydrophobicity, and selection of alkali-soluble group),

(5) adhesiveness to substrate in unexposed area, and

(6) resistance to dry etching.

Examples of such monomers include compounds having one addition polymerizable unsaturated bond, selected from acrylic esters, methacrylic esters, acrylamides, methacrylamides, allyl compounds, vinyl ethers, and vinyl esters.

A content of the repeating unit represented by the general formula (I) in the acid-decomposable resin is preferably from 2 to 50% by mole, more preferably from 4 to 45% by mole, and most preferably from 6 to 40% by mole in the whole of the repeating structural units.

A content of the repeating unit represented by the general formula (II) is preferably from 15 to 60% by mole, more preferably from 20 to 55% by mole, and most preferably from 25 to 50% by mole in the whole of the repeating structural units.

The total sum of the repeating units having the acid-decomposable group is preferably from 20 to 70% by mole, more preferably from 25 to 65% by mole, and most preferably from 30 to 60% by mole in the whole of the repeating structural units.

A content of the repeating unit represented by any of the general formulae (pI) to (pVI) is preferably from 10 to 60% by mole, more preferably from 15 to 50% by mole, and most preferably from 20 to 40% by mole in the whole of the repeating structural units.

A content of the repeating unit represented by the general formula (III) is preferably from 3 to 40% by mole, more preferably from 5 to 35% by mole, and most preferably from 8 to 40% by mole in the whole of the repeating structural units.

A content of the repeating unit represented by the general formula (IV) is preferably from 3 to 40% by mole, more preferably from 5 to 35% by mole, and most preferably from 8 to 40% by mole in the whole of the repeating structural units.

A content of the repeating unit having a lactone residue or an alicyclic lactone is preferably from 5 to 50% by mole, more preferably from 10 to 40% by mole, and most preferably from 12 to 30% by mole in the whole of the repeating structural units.

When the composition according to the present invention is used for ArF exposure, it is preferred from the standpoint of transparency to ArF light that the resin does not have an aromatic group.

The acid-decomposable resin that is used in the present invention can be synthesized in a customary manner (such as radical polymerization). For example, as the general synthesis method, the monomer species are charged at once or on the way of the reaction into a reaction vessel; if desired, the monomers are dissolved in a reaction solvent such as ethers (e.g., tetrahydrofuran, 1,4-dioxane, diisoporpyl ether), ketones (e.g., methyl ethyl ketone, methyl isobutyl ketone), ester solvents (e.g., ethyl acetate), and solvents dissolving the composition according to the present invention therein as described later (e.g., propylene glycol monomethyl ether acetate), to form a uniform solution; and polymerization of the solution is initiated by heating, if desired in an inert gas atmosphere such as nitrogen and argon using a commercially available radical initiator (such as an azo-based initiator and a peroxide). If desired, the initiator is supplemented or dividedly added. After completion of the reaction, the reaction mixture is added to a solvent, and the desired polymer is recovered by a powder or solid recovery method. A reaction concentration is 20% by weight or more, preferably 30% by weight or more, and more preferably 40% by weight or more. A reaction temperature is from 10° C. to 150° C., preferably from 30° C. to 120° C., and more preferably from 50° C. to 100° C.

A weight average molecular weight of the acid-decomposable resin according to the present invention is from 1,000 to 200,000, preferably from 3,000 to 50, 000, and more preferably from 5,000 to 30, 000 in terms of a conversion value to polystyrene by the GPC method. When the weight average molecular weight is less than 1,000, deterioration in heat resistance and resistance to dry etching is found, and hence, such is not so desired. On the other hand, when the weight average molecular weight exceeds 200,000, there are generated undesired results such that the development properties are deteriorated and that the viscosity becomes extremely high, leading to deterioration in film forming properties.

In the positive-working photoresist composition for far ultraviolet exposure according to the present invention, a compounding amount of the acid-decomposable resin according to the present invention in the whole of the composition is preferably from 40 to 99.99% by weight, and more preferably from 50 to 99.97% by weight in the solids content of the total resists.

In the solvent are dissolved the solid components such as the photo acid generator (A) and the resin (B) are dissolved in an amount of preferably from 3 to 25% by weight, more preferably from 5 to 22% by weight, and most preferably from 7 to 20% by weight in terms of solid concentration.

[3] Mixed Solvent (Component (C)):

The positive-working photosensitive composition according to the present invention contains a mixed solvent as the component (C). As this mixed solvent is enumerated a mixed solvent containing at least one member selected from propylene glycol monoalkyl ether alkoxylates (sometimes referred to as “solvent group A”), at least one member selected from propylene glycol monoalkyl ethers, alkyl lactates, and alkyl alkoxypropionates (sometimes referred to as “solvent group B”), and/or at least one member selected from γ-butyrolactone, ethylene carbonate, and propylene carbonate (sometimes referred to as “solvent group C”). That is, as the component (C) can be used a combination of the solvent group A and the solvent group B, a combination of the solvent group A and the solvent group C, and a combination of the solvent group A, the solvent group B and the solvent group C.

Preferred examples of the propylene glycol monoalkyl ether alkoxylates include propylene glycol monomethyl ether acetate, propylene glycol monomethyl ether propionate, propylene glycol monoethyl ether acetate, and propylene glycol monoethyl ether propionate.

Preferred examples of the propylene glycol monoalkyl ethers include propylene glycol monomethyl ether and propylene glycol monoethyl ether. Preferred examples of the alkyl lactates include methyl lactate and ethyl lactate. Preferred examples of the alkyl alkoxypropionates include ethyl 3-ethoxypropionate, methyl 3-methoxypropionate, ethyl 3-methoxypropionate, and methyl 3-ethoxypropionate.

A weight ratio of the solvent group A to the solvent group B (A:B) to be used is preferably from 90:10 to 15:85, more preferably from 85:15 to 20:80, and most preferably from 80:20 to 25:75.

A weight ratio of the solvent group A to the solvent group C (A:C) to be used is preferably from 99.9:0.1 to 75:25, more preferably from 99:1 to 80:20, and most preferably from 97:3 to 85:15.

In the case where these three kinds of solvents are combined, a weight ratio of the solvent group C to be used is preferably from 0.1 to 25% by weight, more preferably from 1 to 20% by weight, and most preferably from 3 to 17% by weight of the whole of the solvents.

In the present invention, in the mixed solvent are dissolved the solid components of the composition containing the foregoing respective components are dissolved in an amount of preferably from 3 to 25% by weight, more preferably from 5 to 22% by weight, and most preferably from 7 to 20% by weight in terms of solid concentration.

In the present invention, preferred examples of the combination in the mixed solvent containing the propylene glycol monoalkyl ether carboxylate include:

Propylene glycol monomethyl ether acetate+propylene glycol monomethyl ether;

Propylene glycol monomethyl ether acetate+ethyl lactate;

Propylene glycol monomethyl ether acetate+3-ethoxyethyl propionate;

Propylene glycol monomethyl ether acetate+γ-butyrolactone;

Propylene glycol monomethyl ether acetate+ethylene carbonate;

Propylene glycol monomethyl ether acetate+propylene carbonate;

Propylene glycol monomethyl ether acetate+propylene glycol monomethyl ether+γ-butyrolactone;

Propylene glycol monomethyl ether acetate+ethyl lactate+γ-butyrolactone;

Propylene glycol monomethyl ether acetate+3-ethoxyethyl propionate+γ-butyrolactone;

Propylene glycol monomethyl ether acetate+propylene glycol monomethyl ether+ethylene carbonate;

Propylene glycol monomethyl ether acetate+ethyl lactate+ethylene carbonate;

Propylene glycol monomethyl ether acetate+3-ethoxyethyl propionate+ethylene carbonate;

Propylene glycol monomethyl ether acetate+propylene glycol monomethyl ether+propylene carbonate;

Propylene glycol monomethyl ether acetate+ethyl lactate +propylene carbonate; and

Propylene glycol monomethyl ether acetate+3-ethoxyethyl propionate +propylene carbonate.

Of these combinations of solvents are particularly preferable:

Propylene glycol monomethyl ether acetate+propylene glycol monomethyl ether+γ-butyrolactone;

Propylene glycol monomethyl ether acetate+ethyl lactate+γ-butyrolactone;

Propylene glycol monomethyl ether acetate+3-ethoxyethyl propionate+γ-butyrolactone;

Propylene glycol monomethyl ether acetate+propylene glycol monomethyl ether+ethylene carbonate;

Propylene glycol monomethyl ether acetate+ethyl lactate+ethylene carbonate;

Propylene glycol monomethyl ether acetate+3-ethoxyethyl propionate+ethylene carbonate;

Propylene glycol monomethyl ether acetate+propylene glycol monomethyl ether+propylene carbonate;

Propylene glycol monomethyl ether acetate+ethyl lactate+propylene carbonate; and

Propylene glycol monomethyl ether acetate+3-ethoxyethyl propionate+propylene carbonate.

To each of the foregoing mixed solvents of the present invention may be added other nonessential solvent so far as the effects of the present invention are not inhibited. An amount of such other solvent to be added is generally 30 parts by weight or less based on 100 parts by weight of each of the mixed solvents of the present invention. Examples of other solvents include ethylene dichloride, cyclohexanone, cyclopentanone, methyl ethyl ketone, toluene, N,N-dimethylformamide, dimethyl sulfoxide, N-methylpyrrolidone, tetrahydrofuran, and solvents described below, in addition to the solvents as enumerated above as essential solvents of the mixed solvent.

<Acid-Decomposable Dissolution Inhibiting Compound (Component (D))>

It is preferred that the positive-working photosensitive composition according to the present invention contains (D) a dissolution inhibiting low-molecular weight compound having a group that is decomposed by the action of an acid to increase its solubility in an alkaline developing solution and having a molecular weight of 3,000 or less (sometimes referred to as “acid-decomposable dissolution inhibiting compound (D)”).

Especially, in order that the transmission of 220 nm or less is not lowered, an alicyclic or aliphatic compound containing an acid-decomposable group, such as cholic acid derivatives containing an acid-decomposable group as described in Proceeding of SPIE, 2724, 355 (1996), is preferred as the acid-decomposable dissolution inhibiting compound (D). As the acid-decomposable group and the alicyclic structure, the same as in the acid-decomposable resin as described above can be applied.

An amount of the acid-decomposable dissolution inhibiting compound (D) to be added is preferably from 3 to 50% by weight, and more preferably from 5 to 40% by weight on a basis of the solids content of the whole of the composition of the positive-working photosensitive composition.

Specific examples of the acid-decomposable dissolution inhibiting compound (D) will be described below, but it should not be construed that the present invention is limited thereto.

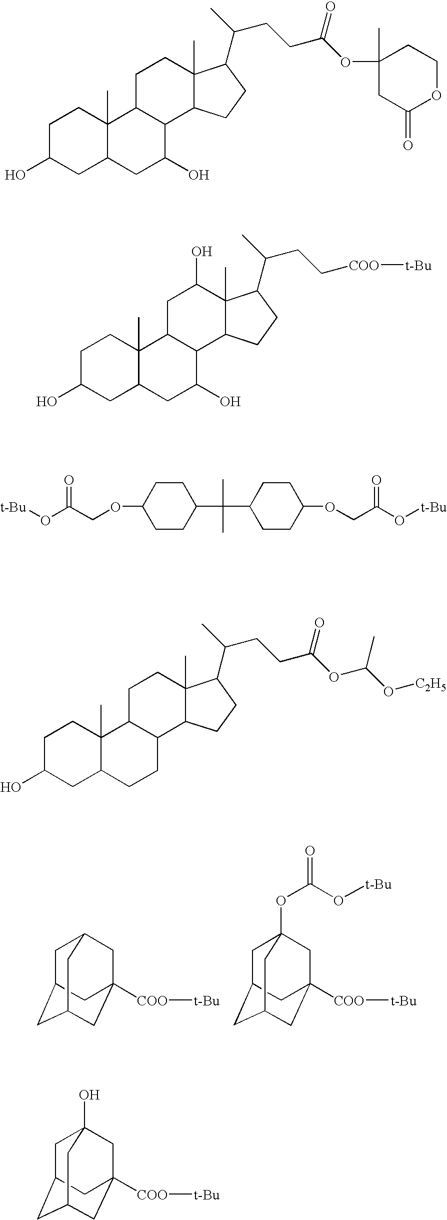

<Nitrogen-Containing Basic Compound (Component (E))>

In order to reduce the lapsing change in performance from the exposure to the heating, it is preferred that the positive-working photosensitive composition according to the present invention contains (E) a nitrogen-containing basic compound.

As the structure of the nitrogen-containing basic compound (E) are preferable structures as represented by the following general formulae (A) to (E).

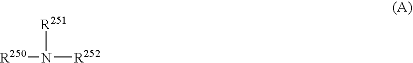

In the general formula, R²⁵⁰, R²⁵¹, and R²⁵² each independently represents a hydrogen atom, an alkyl group having from 1 to 6 carbon atoms, an aminoalkyl group having from 1 to 6 carbon atoms, a hydroxyalkyl group having from 1 to 6 carbon atoms, or a substituted or unsubstituted aryl group having from 6 to 20 carbon atoms; and R²⁵⁰ and R²⁵¹ may be taken together to form a ring.

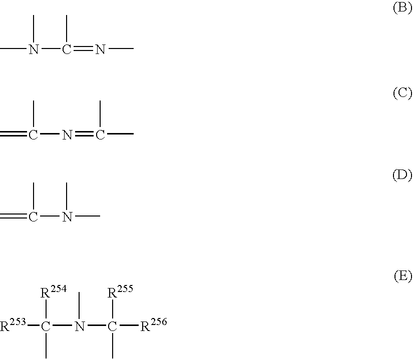

In the general formulae, R²⁵³, R²⁵⁴, R²⁵⁵ and R²⁵⁶ each independently represents an alkyl group having 1 to 6 carbon atoms.

Preferred specific examples include substituted or unsubstituted guanidines, substituted or unsubstituted aminopyridines, substituted or unsubstituted aminoalkylpyridines, substituted or unsubstituted aminopyrrolidines, substituted or unsubstituted indazoles, substituted or unsubstituted pyrazoles, substituted or unsubstituted pyrazines, substituted or unsubstituted pyrimidines, substituted or unsubstituted purines, substituted or unsubstituted imidazolines, substituted or unsubstituted pyrazolines, substituted or unsubstituted piperazines, substituted or unsubstituted aminomorpholines, substituted or unsubstituted aminoalkylmorpholines, mono-, di- and trialkylamines, substituted or unsubstituted anilines, substituted or unsubstituted piperidines, and mono- or diethanolamine. Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Especially preferred compounds are guanidine, 1,1-dimethylguanidine, 1,1,3,3-tetramethylguanidine, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl) piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydropyrimidine, 2-pyrazoline, 3-pyrazoline, N-aminomorpholine, N-(2-aminoethyl)morpholine, 1,5-diazabicyclo[4.3.0]nonan-5-ene, 1,8-diazabicyclo-[5.4.0]undecan-7-ene, 2,4,5-triphenylimidazole, tri-(n-butyl)amine, tri(n-octyl)amine, N-phenyldiethanolamine, N-hydroxyethylpiperidine, 2,6-diisopropylaniline, and N-cyclohexyl-N′-morpholinoethylthiourea. However, it should not be construed that the present invention is limited thereto.

The nitrogen-containing basic compound (E) may be used singly or in admixture of two or more thereof. An amount of the nitrogen-containing basic compound (E) to be used is usually from 0.001 to 10% by weight, and preferably from 0.01 to 5% by weight on a basis of the solids content of the photosensitive resin composition. When the amount of the nitrogen-containing basic compound (E) is less than 0.001% by weight, the effect by the nitrogen-containing basic compound (E) is not obtained. On the other hand, when it exceeds 10% by weight, the sensitivity is liable to be lowered, or the development properties in unexposed areas are liable to become worse.

<Fluorine-Based and/or Silicon-Based Surfactant (Component (F))>

It is preferred that the positive-working photosensitive resin composition according to the present invention contains any one of fluorine-based and/or silicon-based surfactants (such as fluorine-based surfactants, silicon-based surfactants, and surfactants containing both a fluorine atom and a silicon atom), or two or more thereof.

When the positive-working photosensitive composition according to the present invention contains the. surfactant (F) it is possible to give a resist pattern having good sensitivity and resolution and good adhesiveness, which is less in development defect, during using an exposure light source of 250 nm or less, especially 220 nm or less.

As the surfactant (F) can be enumerated the surfactants disclosed in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, and U.S. Pat. Nos. 5,405,720, 5,360,692, 5,529,881, 5,296,330, 5,436,098, 5,576,143, 5,294,511 and 5,824,451. Further, the following commercially available surfactants can also be used as they stand.

Examples of the commercially available surfactants that can be used include fluorine-based surfactants or silicon-based surfactants, such as Eftop EF301 and EF303 (produced by Shin Akita Kasei Co., Ltd.), Fluorad FC430 and FC431 (produced by Sumitomo 3M Limited), Megafac F171, F173, F176, F189 and R08 (produced by Dainippon Ink and Chemicals, Inc.), Surflon S-382, SC101, SC102, SC103, SC104, SC105 and SC106 (produced by Asahi Glass Co., Ltd.), and Troy Sol S-366 (produced by Troy Chemical Co., Ltd.). Further, a polysiloxane polymer, KP-341 (produced by Shin-Etsu Chemical Co., Ltd.) can also be used as the silicon-based surfactant.

An amount of the surfactant to be used is preferably from 0.0001 to 2% by weight, and more preferably from 0.001-to 1% by weight on a basis of the whole amount (excluding the solvent) of the positive-working photosensitive composition.

<Alkali-Soluble Resin (Component (G))>

The positive-working photoresist composition according to the present invention can contain a resin (G) an acid-decomposable group-free resin that is insoluble in water and soluble in an alkaline developing solution. The addition of the resin (G) enhances the sensitivity.

In the present invention, novolak resins having a molecular weight of from about 1,000 to 20,000 and polyhydroxystyrene derivatives having a molecular weight of from about 3,000 to 50,000 can be used as the resin (G). Since these resins have a large absorption to light of 250 nm or less, it is preferred to use them after partial hydrogenation or in an amount of 30% by weight or less of the whole amount of the resins.

Further, resins containing a carboxyl group as the alkali-soluble group can be used. It is preferred that in order to enhance the resistance to dry etching, the carboxyl group-containing resin has a monocyclic or polycyclic alicyclic hydrocarbon group. Concretely, there can be enumerated copolymers of a methacrylic ester and (meth)acrylic acid having an alicyclic hydrocarbon structure that does not exhibit acid decomposability, and resins of a (meth)acrylic ester of an alicyclic hydrocarbon group having a terminal carboxyl group.

<Other Substances>

If desired, the positive-working photosensitive composition according to the present invention can further contain a dye, a plasticizer, other surfactant than the component (F), a photosensitizer, and a compound to promote the dissolution in the developing solution.

A dissolution promoting compound to the developing solution, which can be used in the present invention, is a low-molecular weight compound having two or more phenolic OH groups or one or more carboxyl groups and having a molecular weight of 1,000 or less. In the case where the compound has a carboxyl group, the compound is preferably an alicyclic or aliphatic compound for the same reason as described above.

An amount of the dissolution promoting compound to be added is preferably from 2 to 50% by weight, and more preferably from 5 to 30% by weight to the resin (B) that is decomposed by the action of an acid to increase its solubility in the alkaline developing solution. When the addition amount of the dissolution promoting compound exceeds 50% by weight, the development residue becomes worse, and there is generated a new defect that the pattern deforms during the development. Thus, such is not preferred.

Such a phenol compound having a molecular weight of 1,000 or less can be readily synthesized by those skilled in the art while referring to the methods disclosed in, for example, JP-A-4-122938, JP-A-2-28531, U.S. Pat. No. 4,916,210, and European Patent No. 219,294.

Specific examples of the carboxyl group-containing alicyclic or aliphatic compound include carboxylic acid derivatives having a steroid structure (such as cholic acid, deoxycholic acid, and lithocholic acid), adamantane carboxylic acid derivatives, adamantane dicarbxoylic acid, cylclohexane carboxylic acid, and cyclohexane dicarboxylic acid. However, it should not be construed that the present invention is limited thereto.

In the present invention, other surfactant than the fluorine-based and/or silicon-based surfactant (F) can be added. Concretely, examples include nonionic surfactants such as polyoxyethylene alkyl ethers (such as polyoxyethylene lauryl ether, polyoxyethylene stearyl ether, polyoxyethylene cetyl ether, and polyoxyethylene oleyl ether), polyoxyethylene alkylaryl ethers (such as polyoxyethylene octylphenyl ether and polyoxyethylene nonylphenyl ether), polyoxyethylene/polyoxypropylene block copolymers, sorbitan fatty acid esters (such as sorbitan monolaurate, sorbitan monopalmitate, sorbitan monostearate, sorbitan monooleate, sorbitan triolate, and sorbitan tristearate), and polyoxyethylene sorbitan fatty acid esters (such as polyoxyethylene sorbitan monolaurate, polyoxyethylene sorbitan monopalmitate, polyoxyethylene sorbitan monostearate, polyoxyethylene sorbitan triolate, and polyoxyethylene sorbitan tristearate).

These surfactants may be used singly or in admixture of two or more thereof.

<Using Method>

The photosensitive composition according to the present invention is a mixture of the foregoing components dissolved in a predetermined solvent and is applied on a predetermined support. As the solvent to be used are preferable ethylene dichloride, cyclohexanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, methyl lactate, ethyl lactate, methyl methoxypropionate, ethyl ethoxypropionate, methylpyruvate, ethyl pyruvate, propyl pyruvate, N,N-dimethylformamide, dimethyl sulfoxide, N-methylpyrrolidone, and tetrahydrofuran. These solvents may be used singly or in admixture.

Of these are more preferable cyclohexanone, 2-heptanone, propylene glycol monomethyl ether acetate, propylene glycol monomethyl ether, ethyl lactate, and ethyl ethoxypropionate. These solvents are used singly or as a mixture of two in a weight ratio of from 1/9 to 9/1.

The positive-working photosensitive composition dissolved in a solvent is applied on a predetermined support in the following manner.

That is, the foregoing photosensitive composition is applied on a substrate such as ones used for the production of precision integrated circuit elements (e.g., silicon/silicon dioxide coating films) by a proper coating method using, a spinner, a coater, etc.

After the application, the photosensitive composition is exposed with light through a predetermined mask, baked, and then developed. Thus, there can be obtained a good resist pattern. The exposure light as referred to herein means far ultraviolet rays preferably having a wavelength of 250 nm or less, and more preferably 220 m or less. Specific examples include KrF excimer laser beams (248 nm), ArF excimer laser beams (193 nm), F₂ excimer laser beams (157 nm), X rays, and electron beams.

As the developing solution to be used in the development step can be used alkaline aqueous solutions such as inorganic alkalis (such as sodium hydroxide, potassium hydroxide, sodium carbonate, sodium silicate, sodium metasilicate, and ammonia water), primary amines (such as ethylamine and n-propylamide), secondary amines (such as diethylamine and di-n-butylamine), tertiary amines (such as triethylamine and methyldiethylamine), alcoholamines (such as dimethylethanolamine and triethanolamine), quaternary ammonium salts (such as tetramethylammonium hydroxide and tetraethylammonium hydroxide), and cyclic amines (such as pyrrole and piperidine).

In addition, proper amounts of alcohols and surfactants may be added to the alkaline aqueous solution.

### EXAMPLES

The present invention will be specifically described below with reference to the Examples, but it should not be construed that the present invention is limited thereto.

Synthesis of Resin (1):

In a reaction vessel were charged acetoxyethyl vinyl ether, maleic anhydride, and t-butyl norbornenecarboxylate in a molar ratio of 10/50/40, and the mixture was dissolved in tetrahydrofuran to prepare a solution having a solids content of 40%. This solution was heated at 65° C. under a nitrogen stream. When the reaction temperature became stable, 1 mole % of a radical initiator, V-601 (produced by Wako Pure Chemical Industries, Ltd.) was added to the mixture to start the reaction. Fourteen hours after the heating, the reaction mixture was diluted two times with tetrahydrofuran and added to a hexane/ethyl acetate (9/1) mixed solvent in an amount of 10 times by volume the reaction mixture, to deposit a white powder. The deposited powder was collected by filtration and dissolved in tetrahydrofuran, followed by re-precipitation in a hexane/ethyl acetate (9/1) mixed solvent in an amount of 10 times by volume. A deposited white powder was collected by filtration and dried to obtain the desired resin (1).

The obtained resin (1) was subjected to molecular weight analysis by GPC and found to have a weight average molecular weight of 9,200 in terms of a conversion value to polystyrene. Further, the NMR spectral analysis revealed that the resin (1) had a composition of acetoxyethyl vinyl ether/maleic anhydride/t-butyl norbornenecarboxylate of 12/51/37 in terms of a molar ratio.

Resins (2) to (12) as shown in Table 1 were synthesized in the same manner as in the synthesis of the resin (1). In Table I-1, the repeating unit is in the order from the left side of the structural formula.

TABLE I-1

| | | | | Fourth | |
|---|---|---|---|---|---|
| | | | Third repeating | repeating unit | |
| | Vinyl | Maleic | unit from the | from the left | |
| Resin | ether | anhydride | left side | side | Mw |
| 2 | 13 | 49 | 33 | 5 | 7,800 |
| 3 | 10 | 50 | 37 | 3 | 7,100 |
| 4 | 12 | 46 | 32 | 10 | 8,300 |
| 5 | 11 | 35 | 41 | 13 | 10,900 |
| 6 | 16 | 42 | 42 | | 9,700 |
| 7 | 13 | 35 | 34 | 12 | 9,300 |
| 8 | 9 | 37 | 46 | 8 | 8,800 |
| 9 | 15 | 36 | 19 | 30 | 7,600 |
| 10 | 16 | 40 | 34 | 10 | 10,200 |
| 11 | 11 | 31 | 42 | 16 | 10,800 |
| 12 | 14 | 32 | 44 | 10 | 10,900 |

The structures of the resins (1) to (12) are shown below.

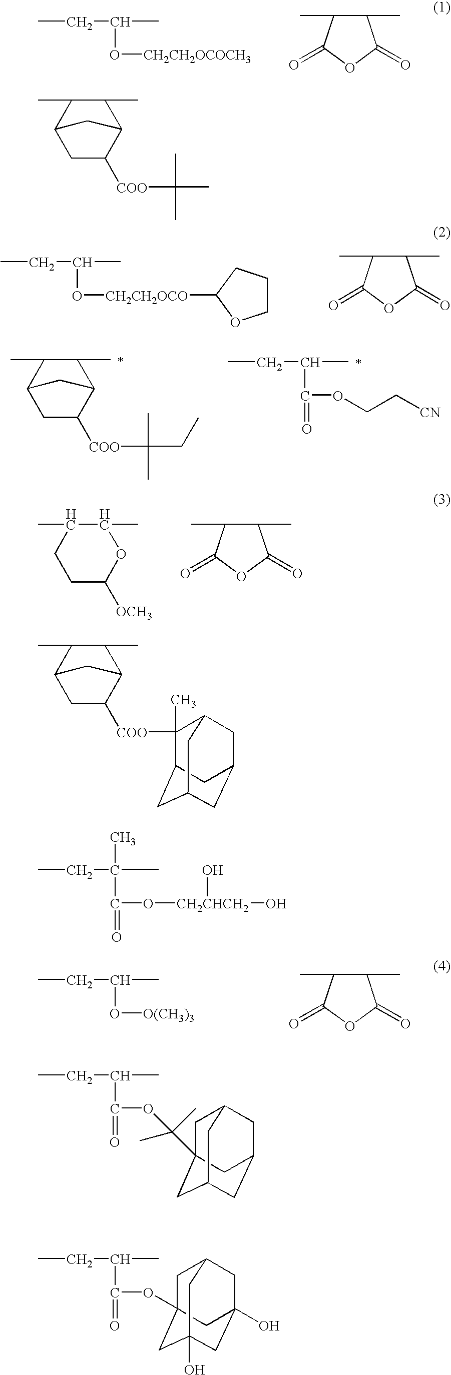

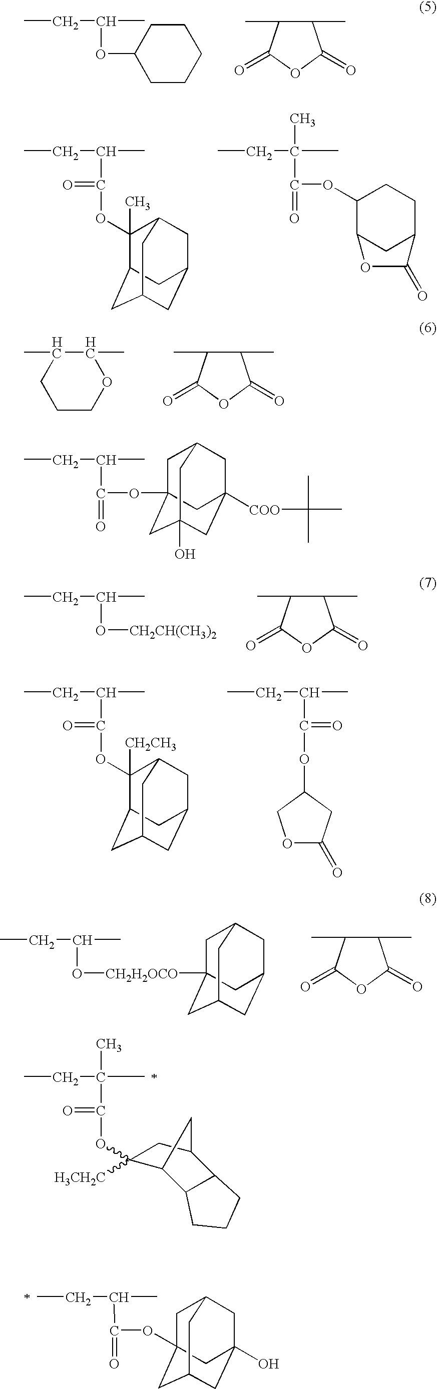

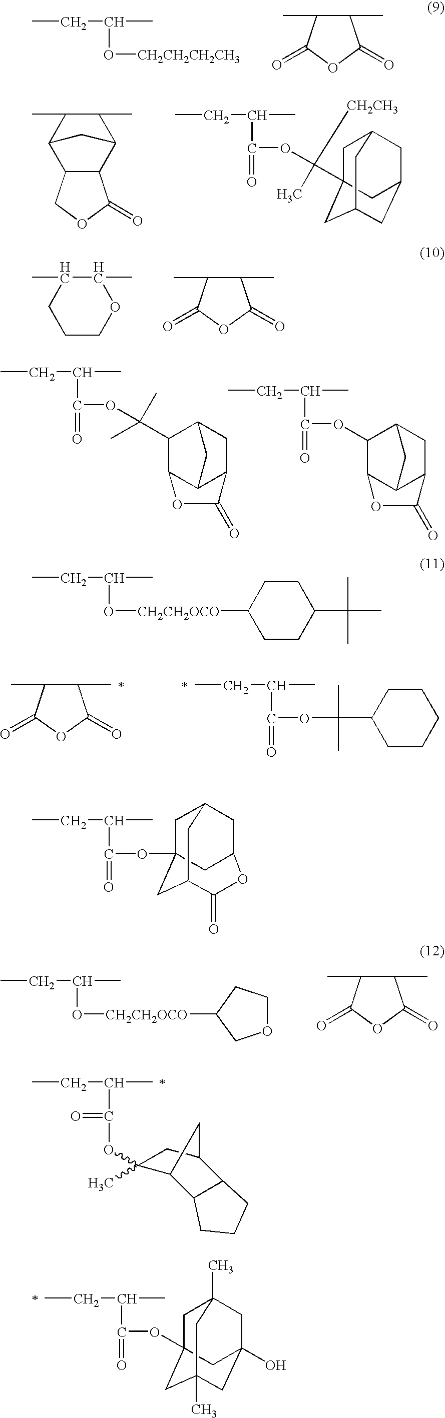

### Examples I-1 to I-12 and Comparative Examples I-1 and I-2

<Preparation of Resist>

(Preparation and Evaluation Of Positive-Working Resist Composition)

Each resin (2 g) as shown in Table I-2, which was synthesized in the foregoing synthesis example, a photo acid generator (in an amount as shown in Table I-2), an organic basic compound (4 mg), and optionally, a surfactant (5 mg) were compounded and dissolved in a solvent as shown in Table I-2 such that the solids content became 12% by weight. Thereafter, the solution was filtered by a 0.1 μm micro-filter to prepare positive-working resist compositions of Examples I-1 to I-12 and Comparative Examples I-1 and I-2. Incidentally, in Table I-2, when plural solvents were used, the ratio means a weight ratio.

TABLE I-2

| | | | Basic | | Solvent |
|---|---|---|---|---|---|
| | | Photo acid | com- | Surfac- | (weight |
| | Resin | generator (mg) | pound | tant | ratio) |
| Example | (1) 2 g | A2I-1/PAG4036 = | E3 | W3 | A2 |
| I-1 | | 20/30 | | | |
| Example | (2) 2 g | A2II-8/PAG4-39 = | E3 | W4 | A2 |
| I-2 | | 25/32 | | | |
| Example | (3) 2 g | A2I-8/PAC4-6 = | E3 | W5 | A2 |
| I-3 | | 5/45 | | | |
| Example | (4) 2 g | A2I-54/PAG4-48 = | E3 | W5 | A2 |
| I-4 | | 8/43 | | | |
| Example | (5) 2 g | A2II-12/PAC4-52 = | E3 | W5 | A1 |
| I-5 | | 25/30 | | | |
| Example | (6) 2 g | A2I-13/PAG4-50 = | E4 | W1 | A1 |
| I-6 | | 30/28 | | | |
| Example | (7) 2 g | A2II-20/PAC4-48 = | E5 | W2 | A1 |
| I-7 | | 20/33 | | | |
| Example | (8) 2 g | A2I-18/PAC4-41 = | E6 | W5 | A1 |
| I-8 | | 35/23 | | | |
| Example | (9) 2 g | A2II-10/PAG4-45 = | E1 | W5 | Al |
| I-9 | | 10/37 | | | |
| Example | (10) 2 g | A2I-23/PAG4-48 = | E2 | W5 | A2/A4 = |
| I-10 | | 23/34 | | | 80/20 |
| Example | (11) 2 g | A2I-50/PAG4-52 = | E4 | W5 | A1/A3 = |
| I-11 | | 6/45 | | | 92/8 |
| Example | (12) 2 g | A2I-49/PAG4-39 = | E5 | W5 | A2/A3/ |
| I-12 | | 5/42 | | | A4 = |
| | | | | | 80/3/17 |
| Com- | (1) 2 g | PAC4-5 = 20 | E7 | | A1 |
| parative | | | | | |
| Example | | | | | |
| I-1 | | | | | |
| Com- | R1 2 g | PAC4-36 = 20 | E8 | | A1 |
| parative | | | | | |
| Example | | | | | |
| I-2 | | | | | |

(Explanation of Table I-2)

The resin R1 is a resin having the following repeating unit, as prepared according to Synthesis Example 6 (Sample No. 2) of JP-A-2001-200016.

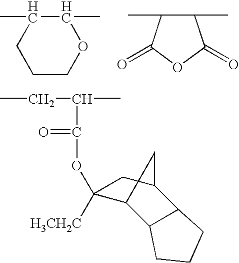

The symbols regarding the surfactant have the following meanings.

W1: Megafac F176 (produced by Dainippon Ink and Chemicals, Inc.) (fluorine-based)

W2: Megafac R08 (produced by Dainippon Ink and Chemicals, Inc.) (fluorine-based and silicon-based)

W3: Polysiloxane polymer, KP-341 (produced by Shin-Etsu Chemical Co., Ltd.)

W4: Polyoxyethylene nonylphenyl ether

W5: Troy Sol S-366 (produced by Troy Chemical Industries, Inc.)

The symbols regarding the basic compound have the following meanings.

E1: 1,5-Diazabicyclo[4.3.0]-5-nonene (DBN)

E2: Bis(1,2,2,6,6-pentamethyl-4-piperidyl)sebacate

E3: Trioctylamine

E4: Triphenyl imidazole

E5: Antipyrine

E6: 2,6-Diisopropylaniline

E7: Triisobutylamine

E8: Triisodecylamine

The symbols regarding the solvent have the following meanings.

A1: Propylene glycol methyl ether acetate

A2: 2-Heptanone

A3: γ-Butyrolatone

A4: Butyl acetate

(Evaluation Test)

[Line Edge Roughness]

First of all, ARC-29 (produced by Brewer Science Limited) was applied in a thickness of 85 nm on a silicon wafer utilizing a spin coater and then dried. The obtained positive-working photoresist composition was applied on the silicon wafer and baked at 130° C. for 90 seconds to form a coating film having a film thickness of 0.30 μm.

The thus obtained wafer was exposed using an ArF excimer laser stepper (ArF Exposure Unit 9300, produced by ISI) having a resolution mask installed therein, while changing the exposure amount. Thereafter, the wafer was heated in a clean room at 130° C. for 90 seconds, developed with a tetramethylammonium hydroxide developing solution (2.38% by weight) for 60 seconds, rinsed with distilled water, and then dried to obtain a pattern.

With respect to a range of an edge of 5 μm in the longitudinal direction of a line pattern of 125 nm obtained from a minimum exposure amount necessary for reproducing a line pattern of 125 nm (line/space=1/1) in the mask, a distance from the standard line at which the edge should be present was measured at 50 points using S9220 (produced by Hitachi, Ltd.), to determine a standard deviation, from which was calculated a 3σ value. The smaller the 3σ value, the better the performance is.

[Development Defect A]

First of all, ARC-29 (produced by Brewer Science Limited) was applied in a thickness of 85 nm on a silicon wafer utilizing a spin coater and then dried. The obtained positive-working photoresist composition was applied on the silicon wafer and baked at 130° C. for 90 seconds to form a coating film having a film thickness of 0.30 μm.

Next, the thus obtained wafer was exposed using an ArF excimer laser stepper (ArF Exposure Unit 9300, produced by ISI) through a test mask of a 20 μm contact hole pattern (hole duty ratio=1:3) and heated at 130° C. for 90 seconds. Subsequently, the wafer was subjected to paddle development with 2.38% by weight TMAH (tetramethylammonium hydroxide aqueous solution) for 60 seconds, rinsed with pure water for 30 seconds, and then spin dried. The obtained sample was measured for the number of development defects by KLA-2112 (produced by KLA-Tencor Corporation), and the obtained primary data value was made the number of development defects.

[Development Defect B]

First of all, ARC-29 (produced by Brewer Science Limited) was applied in a thickness of 85 nm on a silicon wafer utilizing a spin coater and then dried. The obtained positive-working photoresist composition was applied on the silicon wafer and baked at 130° C. for 90 seconds to form a coating film having a film thickness of 0.30 μm.

The thus obtained wafer was exposed with ArF excimer laser beams (wavelength: 193 nm, an ArF stepper produced by ISI) and heated at 130° C. for 90 seconds. Subsequently, the wafer was developed with a 2.38% by weight tetramethylammonium hydroxide aqueous solution and rinsed with distilled water to form a 0.20 μm contact hole pattern (pitch: 1/3). The obtained resist pattern was measured for the number of development defects by KLA-2112 (produced by KLA-Tencor Corporation), and the obtained primary data value was made the number of development defects. On the basis of the data, the defects were observed by SEM, and the number of defects which will become extreme obstacles in the formation of the contact hole (defects clogging the holes: killer defects) was counted.

TABLE 1-3

| | Line edge | Development | Development |
|---|---|---|---|
| | roughness | defect A | defect B |
| | (nm) | (number) | (number) |
| Example | 7 | 42 | 0 |
| I-1 | | | |
| Example | 7 | 51 | 0 |
| I-2 | | | |
| Example | 8 | 92 | 2 |
| I-3 | | | |
| Example | 8 | 74 | 1 |
| I-4 | | | |
| Example | 6 | 32 | 0 |
| I-5 | | | |
| Example | 6 | 30 | 0 |
| I-6 | | | |
| Example | 6 | 31 | 0 |
| I-7 | | | |
| Example | 6 | 29 | 0 |
| I-8 | | | |
| Example | 7 | 69 | 1 |
| I-9 | | | |
| Example | 6 | 28 | 0 |
| I-10 | | | |
| Example | 7 | 104 | 3 |
| I-11 | | | |
| Example | 7 | 89 | 2 |
| I-12 | | | |
| Compara- | 17 | 1220 | 23 |
| tive | | | |
| Example | | | |
| I-1 | | | |
| Compara- | 18 | 1360 | 32 |
| tive | | | |
| Example | | | |
| I-2 | | | |

It can be understood from the results shown in Table 1-3 that the compositions according to the present invention are superior in various characteristics.

The present invention can provide a positive-working photosensitive composition having improved line edge roughness and development defect. Accordingly, the positive-working photosensitive composition according to the present invention is suitably used for micro photo-fabrication using far ultraviolet rays, especially ArF excimer laser beams.

### Examples II-1 to II-12 and Comparative Examples II-1 and II-2

<Preparation of Resist>

(Preparation and Evaluation of Positive-Working Resist Composition)

Each resin (in an amount as shown in Table II-2) as shown in Table II-2, which was synthesized in the foregoing synthesis example, a photo acid generator (in an amount as shown in Table II-2), an organic basic compound (4 mg), and optionally, a surfactant (5 mg) were compounded and dissolved in a solvent as shown in Table II-2 such that the solids content became 12% by weight. Thereafter, the solution was filtered by a 0.1 μm micro-filter to prepare positive-working resist compositions of Examples II-1 to II-12 and Comparative Examples II-1 and II-2. Incidentally, in Table II-2, when plural solvents were used, the ratio means a weight ratio.

TABLE II-2

| | | Photo acid | Basic | | Other | |
|---|---|---|---|---|---|---|
| | | generator | com- | Surfac- | addi- | |
| | Resin | (mg) | pound | tant | tive | Solvent |
| Example | (1) | A1I-7 = 45 | E3 | W5 | | A1 |
| II-1 | 2 g | | | | | |
| Example | (2) | A1I-26/ | E3 | W2 | C1 | A2 |
| II-2 | 1.7 g | PAG4-39 = | | | 330 mg | |
| | | 11/39 | | | | |
| Example | (3) | A1VIII-3/ | E4 | W3 | C3 | A1 |
| II-3 | 1.7 g | PAG4-6 = 8/40 | | | 300 mg | |
| Example | (4) | A1I-9 = 43 | E5 | W5 | | A2 |
| II-4 | 2 g | | | | | |
| Example | (5) | A1II-5/ | E1 | W5 | | A1/ |
| II-5 | 2 g | PAG4-41 = | | | | A3 = |
| | | 13/32 | | | | 9/1 |
| Example | (6) | A1I-14/ | E2 | W1 | | A1/ |
| II-6 | 2 g | PAG4-52 = | | | | A4 = |
| | | 12/40 | | | | 95/5 |
| Example | (7) | A1I-22/ | E6 | W2 | | A1 |
| II-7 | 2 g | PAG4-48 = | | | | |
| | | 9/36 | | | | |
| Example | (8) | A1I-8/ | E5 | W1 | | A1/ |
| II-8 | 2 g | PAG4-52/ | | | A5 = | |
| | | PAG-7-3 = | | | | 80/20 |
| | | 10/32/4 | | | | |
| Example | (9) | A1I-17 = 44 | E3 | W4 | C2 | A1 |
| II-9 | 1.7 g | | | | 300 mg | |
| Example | (10) | A1III-1/ | E3 | W5 | | A2 |
| II-10 | 2 g | PAG4-52/ | | | | |
| | | A2I-65 = | | | | |
| | | 4/36/10 | | | | |
| Example | (11) | A1I-25/ | E3 | W5 | | A1 |
| II-11 | 2 g | PAG4-45 = | | | | |
| | | 12/36 | | | | |
| Example | (12) | A1I-20/ | E3 | W5 | | A1 |
| II-12 | 2 g | PAG4-48 = | | | | |
| | | 10/32 | | | | |
| Compara- | R1 | PAG4-5 = 20 | E7 | | | A1 |
| tive | 2 g | | | | | |
| Example | | | | | | |
| II-1 | | | | | | |
| Compara- | (1) | PAG4-36 = 20 | E8 | | | A1 |
| tive | 2 g | | | | | |
| Example | | | | | | |
| II-2 | | | | | | |

(Explanation of Table II-2)

The resin R1 is a resin having the following repeating unit, as prepared according to Synthesis Example 6 (Sample No. 2) of JP-A-2001-200016.

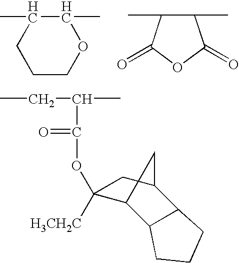

The symbols regarding the surfactant have the following meanings.

W1: Megafac F176 (produced by Dainippon Ink and Chemicals, Inc.) (fluorine-based)

W2: Megafac R08 (produced by Dainippon Ink and Chemicals, Inc.) (fluorine-based and silicon-based)

W3: Polysiloxane polymer, KP-341 (produced by Shin-Etsu Chemical Co., Ltd.)

W4: Polyoxyethylene nonylphenyl ether

W5: Troy Sol S-366 (produced by Troy Chemical Industries, Inc.)

The symbols regarding the basic compound have the following meanings.

E1: 1,5-Diazabicyclo[4.3.0]-5-nonene (DBN)

E2: Bis(1,2,2,6,6-pentamethyl-4-piperidyl)sebacate

E3: Trioctylamine

E4: Triphenyl imidazole

E5: Antipyrine

E6: 2,6-Diisopropylaniline

E7: Triisobutylamine

E8: Triisodecylamine

The symbols regarding the solvent have the following meanings.

A1: Propylene glycol methyl ether acetate

A2: 2-Heptanone

A3: Ethylethoxy propionate

A4: γ-Butyrolatone

A5: Butyl acetate

The symbols regarding other additive have the following meanings.

C1: t-Butyl lithocholate

C2: t-Butyl cholate

C3: t-Butyl hydroxyadamantanecarboxylate

(Evaluation Test)

[Pitch Dependency(i.e., Defocus Latitude Depended on Line Pitch)]

First of all, ARC-29 (produced by Brewer Science Limited) was applied in a thickness of 85 nm on a silicon wafer utilizing a spin coater and then dried. The obtained positive-working photoresist composition was applied on the silicon wafer and dried at 130° C. for 90 seconds to prepare a positive-working photoresist film having a film thickness of 300 nm. The thus obtained wafer was exposed with ArF excimer laser beams (wavelength: 193 nm, NA=0.6, an ArF stepper produced by ISI) and then heated at 130° C. for 90 seconds. Subsequently, the wafer was developed with a 2.38% by weight tetramethylammonium hydroxide aqueous solution and rinsed with distilled water to obtain a resist pattern profile.

The obtained resist pattern was observed by a scanning electron microscope to obtain the following evaluation.

At the same exposure amount as the exposure amount necessary for reproducing a mask pattern of 0.125 μm (line/space =1/1), a coefficient of fluctuation from 0.125 μm {(0.125−L1)×100/0.125 (%)} wherein L1 (side chain) represents a line width of a 0.125 μm isolated pattern was made an index of pitch dependency. The smaller the value, the smaller the pitch dependency is, that is, the pitch dependency becomes better.

[Evaluation Method of Resistance to Side Lobe Light by Halftone Mask Exposure]

ARC-29 (produced by Brewer Science Limited) was applied in a thickness of 85 nm on a silicon wafer utilizing a spin coater and then dried. The obtained positive-working photoresist composition was applied on the silicon wafer and dried at 130° C. for 90 seconds to prepare a positive-working photoresist film having a film thickness of 300 nm. Next, the thus obtained wafer was exposed by an ArF stepper (produced by ISI) through a halftone mask (transmission: 80%) of a 0.165 μm contact hole pattern (hole duty ratio=1:3) and then heated at 130° C. for 60 seconds. Subsequently, the wafer was subjected to paddle development with 2.38% by weight TMAH for 60 seconds, rinsed with pure water for 30 seconds, and then spin dried to obtain an image. During this operation, a ratio of Elimit/Eopt wherein Eopt represents an optimum exposure amount necessary for reproducing an isolated contact hole (mask) having a diameter of 0.165 μm to 0.140 μm, and Elimit represents a minimum exposure amount necessary for transferring the side lobe light onto the resist substrate was made an index of resistance to side lobe light. The value of Comparative Example II-1 was standardized to be 1, and the resistance to side lobe light of each of Examples II-1 to II-12 and Comparative Example II-2 was relatively evaluated. As the value increases, the resistance to side lobe light is superior, whereas as the value decreases, the resistance to side lobe light is inferior.

TABLE II-3

| | Pitch dependency (%) | Side lobe margin |
|---|---|---|
| Example II-1 | 32 | 1.9 |
| Example II-2 | 33 | 1.9 |
| Example II-3 | 34 | 1.8 |
| Example II-4 | 33 | 2.1 |
| Example II-5 | 28 | 1.9 |
| Example II-6 | 26 | 1.9 |
| Example II-7 | 29 | 1.8 |
| Example II-8 | 30 | 1.9 |
| Example II-9 | 45 | 2.0 |
| Example II-10 | 30 | 2.1 |
| Example II-11 | 28 | 1.9 |
| Example II-12 | 27 | 1.9 |
| Comparative | 90 | 1.0 |
| Example II-1 | | |
| Comparative | 73 | 1.2 |
| Example II-2 | | |

It can be understood from the results shown in Table II-3 that the compositions according to the present invention are superior in various characteristics.

The present invention can provide a positive-working photosensitive composition that is small in pitch dependency and has an improved broad side lobe margin. Accordingly, the positive-working photosensitive composition according to the present invention is suitably used for micro photo-fabrication using far ultraviolet rays, especially ArF excimer laser beams.

### Examples III-1 to III-12 and Comparative Examples III-1 and III-2

<Preparation of Resist>

(Preparation and Evaluation of Positive-Working Resist Composition)

Each resin (2 g) as shown in Table III-2, which was synthesized in the foregoing synthesis example, a photo acid generator (in an amount as shown in Table III-2), an organic basic compound (4 mg), and optionally, a surfactant (5 mg) were compounded and dissolved in a solvent as shown in Table III-2 such that the solids content became 12% by weight. Thereafter, the solution was filtered by a 0.1 μm micro-filter to prepare positive-working resist compositions of Examples III-1 to III-12 and Comparative Examples III-1 and III-2. Incidentally, in Table III-2, when plural solvents were used, the ratio means a weight ratio.

TABLE III-2

| | | | Basic | | |
|---|---|---|---|---|---|
| | | Photo acid | com- | Surfac- | |
| | Resin | generator | pound | tant | Solvent |
| Example | (1) | SI-8 = 42 mg | E7 | W5 | S1/S5 = 8/2 |
| III-1 | | | | | |
| Example | (2) | SI-33/A2I-65 = | E2 | W3 | S1/S6 = 8/2 |
| III-2 | | 20 mg/50 mg | | | |
| Example | (3) | SI-11 = 50 mg | E1 | W4 | S1/S5 = 7/3 |
| III-3 | | | | | |
| Example | (4) | SI-9 = 50 mg | E3 | W1 | S1/S7 = 85/15 |
| III-4 | | | | | |
| Example | (5) | SI-35/A2I-13 = | E4 | W2 | S1/58 = 9/1 |
| III-5 | | 22 mg/49 mg | | | |
| Example | (6) | SI-9/A2I1-9 = | E5 | W5 | S1/S2 = 85/15 |
| III-6 | | 26 mg/56 mg | | | |
| Example | (7) | SI-33 = 41 mg | E6 | W5 | S1/S6/S9 = |
| III-7 | | | | | 70/25/5 |
| Example | (8) | SI-4 = 45 mg | E8 | W5 | S1/S6/S7 = |
| III-B | | | | | 68/26/6 |
| Example | (9) | SI-35 = 43 mg | E2 | W5 | S1/S4/S6 = 8/1/1 |
| III-9 | | | | | |
| Example | (10) | SI-9/A2II-11 = | E2 | W5 | S1/S4/S7 = 5/4/1 |
| III-10 | | 30 mg/36 mg | | | |
| Example | (11) | SI-35/A2I-13 = | E2 | W5 | S1/S3/S8 = 7/2/1 |
| III-11 | | 30 mg/22 mg | | | |
| Example | (12) | SI-32 = 42 mg | E2/E5 = | W5 | S1/S5/S7 = |
| III-12 | | | 1/1 | | 80/15/5 |
| Compara- | (1) | PAG1 = 40 mg | E7 | Nil | S1 |
| tive | | | | | |
| Example | | | | | |
| III-1 | | | | | |
| Compara- | R1 | PAG2 = 40 mg | E8 | Nil | S1 |
| tive | | | | | |
| Example | | | | | |
| III-2 | | | | | |

(Explanation of Table III-2)

The resin R1 is a resin having the following repeating unit, as prepared according to Synthesis Example 6 (Sample No. 2) of JP-A-2001-200016.

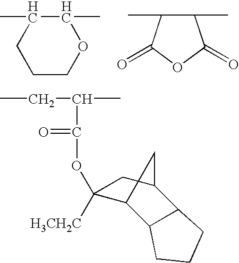

The photo acid generators are those illustrated previously. However, PAG1 and PAG2 used in Comparative Examples III-1 and III-2 are as follows.

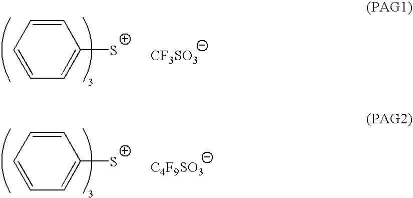

The symbols regarding the surfactant have the following meanings.

W1: Megafac F176 (produced by Dainippon Ink and Chemicals, Inc.) (fluorine-based)

W2: Megafac R08 (produced by Dainippon Ink and Chemicals, Inc.) (fluorine-based and silicon-based)

W3: Polysiloxane polymer, KP-341 (produced by Shin-Etsu Chemical Co., Ltd.)

W4: Polyoxyethylene nonylphenyl ether

W5: Troy Sol S-366 (produced by Troy Chemical Industries, Inc.)

The symbols regarding the basic compound have the following meanings.

E1: 1,5-Diazabicyclo[4.3.0]-5-nonene (DBN)

E2: N,N-Bis(2-hydroxyethyl)aniline

E3: Trioctylamine

E4: Triphenyl imidazole

E5: Antipyrine

E6: 2,6-Diisopropylaniline

E7: Triisobutylamine

E8: Triisodecylamine

The symbols regarding the solvent have the following meanings.

S1: Propylene glycol methyl ether acetate

S2: Ethyl lactate

S3: Butyl acetate

S4: 2-Heptanone

S5: Propylene glycol monomethyl ether

S6: Ethyl ethoxypropionate

S7: γ-Butyrolatone

S8: Ethylene carbonate

S9: Propylene carbonate

(Evaluation Test)

[Development Defect]

First of all, ARC-29 (produced by Brewer Science Limited) was applied in a thickness of 85 nm as an antireflection film on a silicon wafer utilizing a spin coater and then dried. The obtained positive-working photoresist composition was applied on the silicon wafer and baked at 130° C. for 90 seconds to form a coating film having a film thickness of 0.40 μm.

Next, the thus obtained wafer was exposed using an ArF excimer laser stepper (ArF Exposure Unit 9300, produced by ISI) through a test mask of a 20 μm contact hole pattern (hole duty ratio=1:3) and heated at 130° C. for 90 seconds. Subsequently, the wafer was subjected to paddle development with 2.38% by weight TMAH (tetramethylammonium hydroxide aqueous solution) for 45 seconds, rinsed with pure water for 20 seconds, and then spin dried. The number of development defects remaining on the antireflection film of the thus obtained sample was measured by KLA-2112 (produced by KLA-Tencor Corporation), and the obtained primary data value was made the number of development defects.

[Resistance to Side Lobe Light]

ARC-29 (produced by Brewer Science Limited) was applied in a thickness of 85 nm as an antireflection film on a Bare Si substrate utilizing a spin coater. Thereafter, each resist film was applied in a film thickness of 0.40 μm and dried at 130° C. for 60 seconds by a vacuum adsorption type hot plate. Next, the resist film was exposed by an ArF stepper (produced by ISI) through a halftone mask (transmission: 80%) of a 0.180 μm contact hole pattern (hole duty ratio=1:3) and then heated at 130° C. for 60 seconds. Subsequently, the resist film was subjected to paddle development with 2.38% by weight TMAH for 60 seconds, rinsed with pure water for 30 seconds, and then spin dried to obtain an image. During this operation, a ratio of Elimit/Eopt wherein Eopt represents an optimum exposure amount necessary for reproducing an isolated contact hole (mask) having a diameter of 0.18 μm to 0.14 μm, and Elimit represents a minimum exposure amount necessary for transferring the side lobe light onto the resist substrate was made an index of resistance to side lobe light. The value of Comparative Example III-1 was standardized to be 1, and the resistance to side lobe light of each of Examples III-1 to III-12 and Comparative Example III-2 was relatively evaluated. As the value increases, the resistance to side lobe light is superior, whereas as the value decreases, the resistance to side lobe light is inferior.

[Profile]

ARC-29 (produced by Brewer Science Limited) was applied in a thickness of 85 nm as an antireflection film on a Bare Si substrate utilizing a spin coater. Thereafter, each resist film was applied in a film thickness of 0.30 μm and dried at 130° C. for 60 seconds by a vacuum adsorption type hot plate. Next, the resist film was exposed by an ArF stepper (produced by ISI) through a mask of 0.130 μm line-and-space (line/space=1/10) and then heated at 130° C. for 60 seconds. Subsequently, the resist film was subjected to paddle development with 2.38% by weight TMAH for 60 seconds, rinsed with pure water for 30 seconds, and then spin dried to obtain an image. A cross-section of the obtained pattern was observed and evaluated by an scanning electron microscope (SEM).

[Pattern Collapse]

ARC-29 (produced by Brewer Science Limited) was applied in a thickness of 85 nm as an antireflection film on a Bare Si substrate utilizing a spin coater. Thereafter, each resist film was applied in a film thickness of 0.30 μm and dried at 130° C. for 60 seconds by a vacuum adsorption type hot plate. Next, the resist film was exposed by an ArF stepper (produced by ISI) through a mask of 0.130 μm line-and-space (line/space=1/10) and then heated at 130° C. for 60 seconds. Subsequently, the resist film was subjected to paddle development with 2.38% by weight TMAH for 60 seconds, rinsed with pure water for 30 seconds, and then spin dried to obtain an image. A maximum line width at which pattern collapse was generated during the overexposure was made an index of pattern collapse.

The results obtained are shown in Table III-3.

TABLE III-3

| | | | | Pattern |
|---|---|---|---|---|
| | Development | Side lobe | | collapse |
| | defect | margin | Profile | (nm) |
| Example | 35 | 1.21 | Rectangle | 90 |
| III-1 | | | | |
| Example | 33 | 1.20 | Rectangle | 90 |
| III-2 | | | | |
| Example | 48 | 1.19 | Rectangle | 95 |
| III-3 | | | | |
| Example | 36 | 1.20 | Rectangle | 90 |
| III-4 | | | | |
| Example | 32 | 1.21 | Rectangle | 90 |
| III-5 | | | | |
| Example | 34 | 1.21 | Rectangle | 90 |
| III-6 | | | | |
| Example | 28 | 1.24 | Rectangle | 85 |
| III-7 | | | | |
| Example | 28 | 1.25 | Rectangle | 85 |
| III-8 | | | | |
| Example | 32 | 1.21 | Rectangle | 90 |
| III-9 | | | | |
| Example | 31 | 1.20 | Rectangle | 90 |
| III-10 | | | | |
| Example | 27 | 1.25 | Rectangle | 85 |
| III-11 | | | | |
| Example | 26 | 1.25 | Rectangle | 85 |
| III-12 | | | | |
| Comparative | 280 | 1.06 | Film | 120 |
| Example | | | thickness | |
| III-1 | | | reduction | |
| Comparative | 470 | 1.03 | Film | 122.5 |
| Example | | | thickness | |
| III-2 | | | reduction | |

It can be understood from the results shown in Table III-3 that the compositions according to the present invention are superior in various characteristics.

The present invention can provide a positive-working photosensitive composition that is remarkably improved in development defect and resistance to side lobe light and a positive-working photosensitive composition that can form a good profile without causing pattern collapse. Accordingly, the positive-working photosensitive composition according to the present invention is suitably used for micro photo-fabrication using far ultraviolet rays, especially ArF excimer laser beams.

The entitle disclosure of each and every foreign patent application from which the benefit of foreign priority has been claimed in the present application is incorporated herein by reference, as if fully set forth herein.

While the invention has been described in detail and with reference to specific embodiments thereof, it will be apparent to one skilled in the art that various changes and modifications can be made therein without departing from the spirit and scope thereof.

What is claimed is:

1. A positive-working photosensitive composition comprising:
(A) at least one compound of:
a compound to generate an acid upon irradiation with actinic rays or radiations, which is selected from a compound represented by the following general formula (A2I) and a compound represented by the following general formula (A2II), a compound to generate an aromatic sulfonic acid substituted with at least one fluorine atom and/or a group having at least one fluorine atom, upon irradiation with actinic rays or radiations, and
a compound to generate an acid upon irradiation with actinic rays or radiations, which is represented by the following general formula (SI); and
(B) a resin having a repeating unit represented by the following general formula (I) and a repeating unit represented by the following general formula (II), which is decomposed by the action of an acid to increase its solubility in an alkaline developing solution: 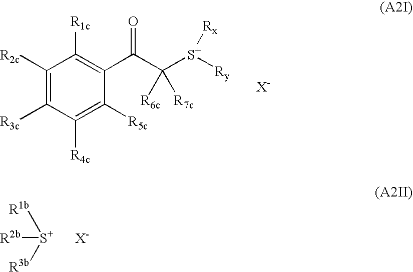
wherein in the general formula (A2I), R_{1c} to R_{5c} each independently represents a hydrogen atom, an alkyl group, an alkoxy group, or a halogen atom; R_{6c} and R_{7c} each independently represents a hydrogen atom, an alkyl group, or an aryl group; Rₓ and R_{y} each independently represents an alkyl group, a 2-oxoalkyl group, an alkoxycarbonylmethyl group, an allyl group, or a vinyl group; and any two or more of R1c to R_{7c}, and Rₓ and R_{y} may be taken together to form a ring structure, and the ring structure may contain an oxygen atom, a sulfur atom, an ester bond, or an amide group;
in the general formula (A2II), R^{1b} to R^{3b} each independently represents an alkyl group, and the alkyl group may be a 2-oxoalkyl group having >C═O at the 2-position thereof; and two of R^{1b} to R^{3b} may be taken together to form a ring structure;
in the general formulae (A2I) and (A2II), X⁻ represents an anion; 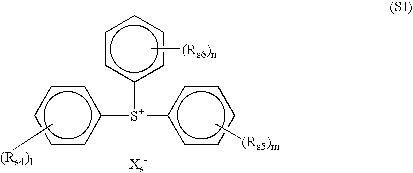
wherein in the general formula (SI), Rₛ₄ to Rₛ₆ each independently represents an alkyl group, a cycloalkyl group, an alkoxy group, an alkoxycarbonyl group, an acyl group, an acyloxy group, a nitro group, a halogen atom, a hydroxyl group, or a carboxyl group; 1 represents from 1 to 5, m represents from 0 to 5, n represents from 0 to 5, and when (1+m+n)=1, then Rₛ₄ represents an alkyl group, a cycloalkyl group, an alkoxy group, an alkoxycarbonyl group, an acyl group, or an acyloxy group; Xₛ⁻ represents R—SO₃⁻; and R represents an aliphatic hydrocarbon group or an aromatic hydrocarbon group; 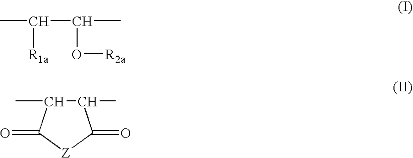
wherein in the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring; and
in the general formula (II), Z represents —O— or —N(R₃ₐ)—; R₃ₐ represents a hydrogen atom, a hydroxyl group, an alkyl group, a haloalkyl group, or OSO₂—R₄ₐ; and R₄ₐ represents an alkyl group, a haloalkyl group, a cycloalkyl group, or a camphor residue.

2. The positive-working photosensitive composition as in claim 1, further comprising (C) a mixed solvent containing at least one member selected from a solvent group A: propylene glycol monoalkyl ether alkoxylates and at least one member selected from a solvent group B: propylene glycol monoalkyl ethers, alkyl lactates, and alkyl alkoxypropionates, or a mixed solvent containing at least one member selected from the solvent group A and at least one member selected from a solvent group C: γ-butyrolactone, ethylene carbonate, and propylene carbonate.

3. A positive-working photosensitive composition comprising (A) at least one compound to generate an acid upon irradiation with actinic rays or radiations, which is selected from a compound represented by the following general formula (A2I) and a compound represented by the following general formula (A2II); and (B) a resin having a repeating unit represented by the following general formula (I) and a repeating unit represented by the following general formula (II), which is decomposed by the action of an acid to increase its solubility in an alkaline developing solution: 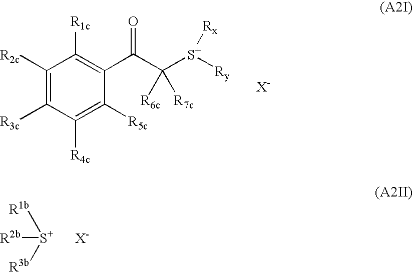
wherein in the general formula (A2I), R_{1c} to R_{5c} each independently represents a hydrogen atom, an alkyl group, an alkoxy group, or a halogen atom; R_{6c} and R_{7c} each independently represents a hydrogen atom, an alkyl group, or an aryl group; Rₓ and R_{y} each independently represents an alkyl group, a 2-oxoalkyl group, an alkoxycarbonylmethyl group, an allyl group, or a vinyl group; and any two or more of R_{1c} to R_{7c}, and Rₓ and R_{y} may be taken together to form a ring structure, and the ring structure may contain an oxygen atom, a sulfur atom, an ester bond, or an amide group;
in the general formula (A2II), R_{1b} to R^{3b} each independently represents an alkyl group, and the alkyl group may be a 2-oxoalkyl group having >C═O at the 2-position thereof; and two of R^{1b} to R^{3b} may be taken together to form a ring structure;
in the general formulae (A2I) and (A2II), X⁻ represents an anion; 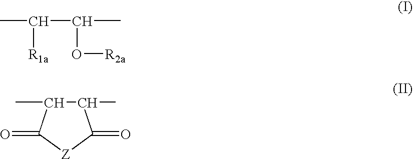
wherein in the general formula (I), R^{1a} represents a hydrogen atom or an optionally substituted hydrocarbon group; R₂ₐ represents an optionally substituted hydrocarbon group; and R^{1a} and R^{2a} may be taken together to form a ring; and
in the general formula (II), Z represents —O— or —N(R₃ₐ)—; R₃ₐ represents a hydrogen atom, a hydroxyl group, an alkyl group, a haloalkyl group, or —OSO₂—R₄ₐ; and R₄ₐ represents an alkyl group, a haloalkyl group, a cycloalkyl group, or a camphor residue.

4. A positive-working photosensitive composition comprising (A) a compound to generate an aromatic sulfonic acid substituted with at least one fluorine atom and/or a group having at least one fluorine atom, upon irradiation with actinic rays or radiations; and (B) a resin (acid-decomposable resin) having a repeating unit represented by the following general formula (I) and a repeating unit represented by the following general formula (II), which is decomposed by the action of an acid to increase its solubility in an alkaline developing solution: 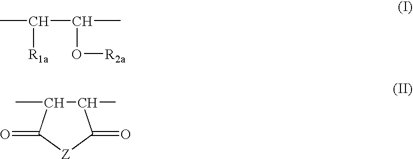
wherein the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring; and
in the general formula (II), Z represents —O— or —N(R₃ₐ)—; R₃ₐ represents a hydrogen atom, a hydroxyl group, an alkyl group, a haloalkyl group, or —OSO₂—R₄ₐ; and R₄ₐ represents an alkyl group, a haloalkyl group, a cycloalkyl group, or a camphor residue.

5. A positive-working photosensitive composition comprising (A) a compound to generate an acid upon irradiation with actinic rays or radiations, which is represented by the following general formula (SI); (B) a resin having a repeating unit represented by the following general formula (I) and a repeating unit represented by the following general formula (II), which is decomposed by the action of an acid to increase its solubility in an alkaline developing solution; and (C) a mixed solvent containing at least one member selected from a solvent group A: propylene glycol monoalkyl ether alkoxylates and at least one member selected from a solvent group B: propylene glycol monoalkyl ethers, alkyl lactates, and alkyl alkoxypropionates, or a mixed solvent containing at least one member selected from the solvent group A and at least one member selected from a solvent group C: γ-butyrolactone, ethylene carbonate, and propylene carbonate: 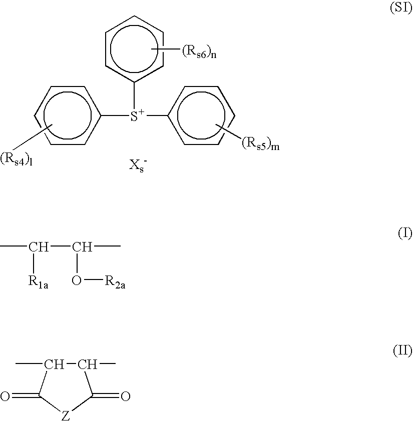
wherein in the general formula (SI), Rₛ₄ to Rₛ₆ each independently represents an alkyl group, a cycloalkyl group, an alkoxy group, an alkoxycarbonyl group, an acyl group, an acyloxy group, a nitro group, a halogen atom, a hydroxyl group, or a carboxyl group; 1 represents from 1 to 5, m represents from 0 to 5, n represents from 0 to 5, and when (1+m+n)=1, then Rₛ₄ represents an alkyl group, a cycloalkyl group, an alkoxy group, an alkoxycarbonyl group, an acyl group, or an acyloxy group; Xₛ⁻ represents R—SO₃⁻; and R represents an aliphatic hydrocarbon group or an aromatic hydrocarbon group;
in the general formula (I), R₁ₐ represents a hydrogen atom or an optionally substituted hydrocarbon group; R₂ₐ represents an optionally substituted hydrocarbon group; and R₁ₐ and R₂ₐ may be taken together to form a ring; and
in the general formula (II), Z represents —O— or —N(R₃ₐ)—; R₃ₐ represents a hydrogen atom, a hydroxyl group, an alkyl group, a haloalkyl group, or OSO₂—R₄ₐ; and R₄ₐ represents an alkyl group, a haloalkyl group, a cycloalkyl group, or a camphor residue.

6. The positive-working photosensitive composition as in claim 1, wherein the acid-decomposable resin contains a repeating unit having a group that is decomposed by the action of an acid, represented by any one of the following general formulae (pI) to (pV). 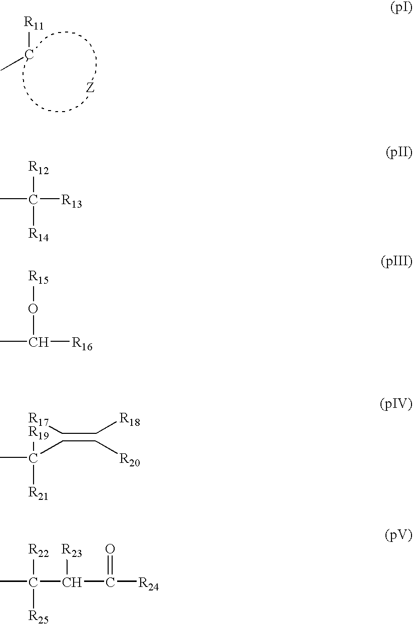
wherein in the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a hydrogen atom or a linear or branched alkyl group or an alicyclic hydrocarbon group, each having from 1 to 4 carbon atoms, provided that at least one of R₁₇ to R₂₁ represents an alicyclic hydrocarbon atom and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

7. The positive-working photosensitive composition as in claim 3, wherein the resin (B) further contains a repeating unit having a lactone residue or an alicyclic lactone reside.

8. The positive-working photosensitive composition as in claim 4, wherein the acid-decomposable resin contains a repeating unit having a group that is decomposed by the action of an acid, represented by any one of the following general formulae (pI) to (pV): 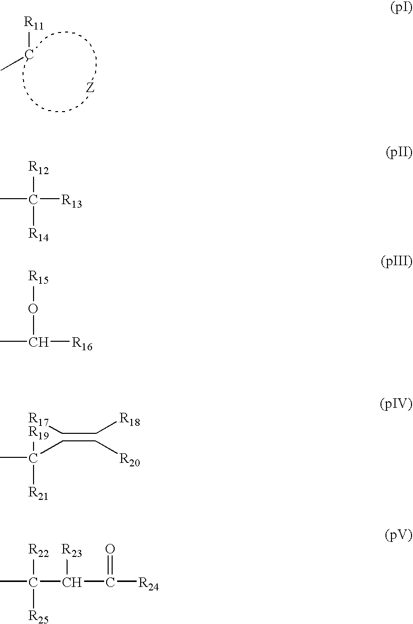
wherein in the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a hydrogen atom or a linear or branched alkyl group or an alicyclic hydrocarbon group, each having from 1 to 4 carbon atoms, provided that at least one of R₁₇ to R₂₁ represents an alicyclic hydrocarbon group and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

9. The positive-working photosensitive composition as in claim 4, wherein the resin (B) further contains a repeating unit having a lactone residue or an alicyclic lactone reside.

10. The positive-working photosensitive composition as in claim 4, wherein the compound (A) is a compound represented by any one of the following general formulae (A1I) to (A1III): 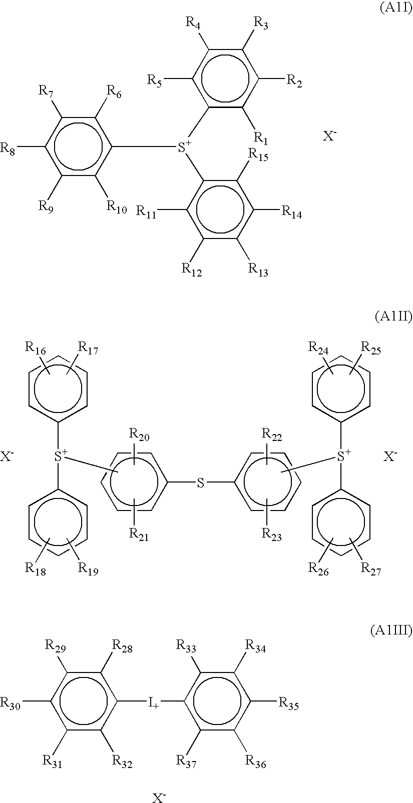
wherein in the foregoing formulae, R₁ to R₃₇, which may be the same or different, each independently represents a hydrogen atom, a linear, branched or cyclic alkyl group, a linear, branched or cyclic alkoxy group, a hydroxyl group, a halogen atom, or an —S—R₃₈ group; R₃₈ represents a linear, branched or cyclic alkyl group or an aryl group; two or more of R₁ to R₁₅, R₁₆ to R₂₇, or R₂₈ to R₃₇ may be taken together to form a ring containing one or two or more members selected from a simple bond, carbon, oxygen, sulfur, and nitrogen; and X⁻ represents an anion of an aromatic sulfonic acid such as benzenesulfonic acid, naphthalenesulfonic acid, and anthracenesulfonic acid, having at least one member selected from at least one fluorine atom, a linear, branched or cyclic alkyl group substituted with at least one fluorine atom, a linear, branched or cyclic alkoxy group substituted with at least one fluorine atom, an acyl group substituted with at least one fluorine atom, an acyloxy group substituted with at least one fluorine atom, an alkyl- or arylsulfonyl group containing at least one fluorine atom, an alkyl- or arylsulfonyloxy group containing at least one fluorine atom, an alkyl- or arylsulfonylamino group containing at least one fluorine atom, an aryl group substituted with at least one fluorine atom, an aralkyl group substituted with at least one fluorine atom, and an alkoxycarbonyl group substituted with at least one fluorine atom.

11. The positive-working photosensitive composition as in claim 5, further comprising (F) a fluorine-based surfactant and/or a silicon-based surfactant.

12. The positive-working photosensitive composition as in claim 5, wherein the acid-decomposable resin contains a repeating unit having a group that is decomposed by the action of an acid, represented by any one of the following general formulae (pI) to (pV): 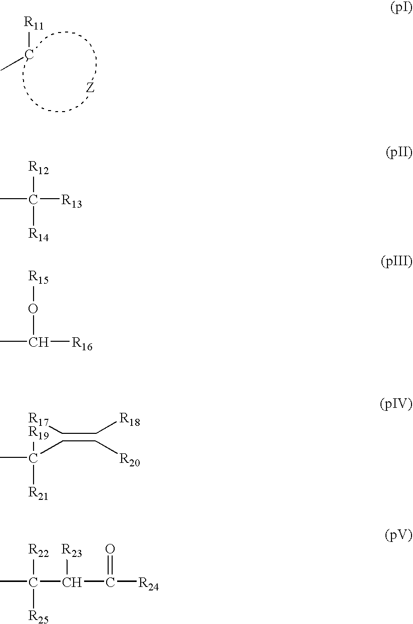
wherein in the foregoing formulae, R₁₁ represents a methyl group, an ethyl group, an n-propyl group, an isopropyl group, an n-butyl group, an isobutyl group, or a sec-butyl group; Z represents an atomic group necessary for forming an alicyclic hydrocarbon group together with the carbon atoms; R₁₂ to R₁₆ each independently represents a linear or branched alkyl group or an alicyclic hydrocarbon group, each having from 1 to 4 carbon atoms, provided that at least one of R₁₂ to R₁₄, and any one of R₁₅ and R₁₆ each represents an alicyclic hydrocarbon group; R₁₇ to R₂₁ each independently represents a hydrogen atom or a linear or branched alkyl group or an alicyclic hydrocarbon group, each having from 1 to 4 carbon atoms, provided that at least one of R₁₇ to R₂₁ represents an alicyclic hydrocarbon atom and that any one of R₁₉ and R₂₁ represents a linear or branched alkyl group or an alicyclic hydrocarbon group, each having from 1 to 4 carbon atoms; R₂₂ to R₂₅ each independently represents a linear or branched alkyl group or an alicyclic hydrocarbon group, each having from 1 to 4 carbon atoms, provided that at least one of R₂₂ to R₂₅ represents an alicyclic hydrocarbon atom and that R₂₃ and R₂₄ may be taken together to form a ring.

13. The positive-working photosensitive composition as in claim 5, wherein the resin (B) further contains a repeating unit having a lactone residue or an alicyclic lactone reside.

14. The positive-working photosensitive composition as in claim 5, wherein the mixed solvent (C) is a mixed solvent containing at least one member selected from the solvent group A, at least one member selected from the solvent group B, and at least one member selected from the solvent group C.
